(19) United States
(12) Patent Application Publication
(10) Pub. No.: US 2025/0098194 A1
(43) Pub. Date: Mar. 20, 2025

(54) SEMICONDUCTOR DEVICE AND METHODS OF FORMATION

(71) Applicant: Taiwan Semiconductor Manufacturing Company, Ltd., Hsinchu (TW)

(72) Inventors: Tzu-Ging LIN, Kaohsiung City (TW); Ya-Yi TSAI, Hsinchu City (TW); Yun-Chen WU, Hsinchu (TW); Shu-Yuan KU, Zhubei City (TW)

(21) Appl. No.: 18/469,153

(22) Filed: Sep. 18, 2023

(51) Int. Cl. H01L 29/66; H01L 29/06; H01L 29/423; H01L 29/775

(52) U.S. Cl. CPC H10D 30/014; H10D 30/43; H10D 30/6735; H10D 62/121; H10D 64/017

(57) ABSTRACT

Continuous polysilicon on oxide diffusion edge (CPODE) processes are described herein in which one or more semiconductor device parameters are tuned to reduce the likelihood of etching of source/drain regions on opposing sides of CPODE structures formed in a semiconductor device, to reduce the likelihood of depth loading in the semiconductor device, and/or to reduce the likelihood of gate deformation in the semiconductor device, among other examples. Thus, the CPODE processes described herein may reduce the likelihood of epitaxial damage to the source/drain regions, may reduce current leakage between the source/drain regions, and/or may reduce the likelihood of threshold voltage shifting for transistors of the semiconductor device. The reduced likelihood of threshold voltage shifting may provide more uniform and/or faster switching speeds for the transistors, more uniform and/or lower power consumption for the transistors, and/or increased device performance for the transistors, among other examples.

### BACKGROUND

As semiconductor device manufacturing advances and technology processing nodes decrease in size, transistors may become affected by short channel effects (SCEs) such as hot carrier degradation, barrier lowering, and quantum confinement, among other examples. In addition, as the gate length of a transistor is reduced for smaller technology nodes, source/drain (S/D) electron tunneling increases, which increases the off current for the transistor (the current that flows through the channel of the transistor when the transistor is in an off configuration). Silicon (Si)/silicon germanium (SiGe) nanostructure transistors such as nanowires, nanosheets, and gate-all-around (GAA) devices are potential candidates to overcome short channel effects at smaller technology nodes. Nanostructure transistors are efficient structures that may experience reduced SCEs and enhanced carrier mobility relative to other types of transistors.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example environment in which systems and/or methods described herein may be implemented.

FIG. 2 is a diagram of an example semiconductor device described herein.

FIGS. 3A and 3B are diagrams of an example implementation of a fin formation process described herein.

FIGS. 4A and 4B are diagrams of an example implementation of a shallow trench isolation (STI) process described herein.

FIGS. 5A-5C are diagrams of an example implementation of a cladding sidewall formation process described herein.

FIGS. 6A-6C are diagrams of an example implementation of a hybrid fin structure formation process described herein.

FIGS. 7A and 7B are diagrams of an example dummy gate structure formation process described herein.

FIGS. 8A-8E are diagrams of an example implementation of a source/drain region formation process described herein.

FIGS. 9A-9I are diagrams of an example implementation of an active region isolation structure formation process described herein.

FIGS. 10A-10D are diagrams of an example implementation of a replacement gate process described herein.

FIGS. 11A-11I are diagrams of an example implementation of an active region isolation structure formation process described herein.

FIG. 12 is a diagram of an example implementation of a semiconductor device described herein.

FIG. 13 is a diagram of an example implementation of a semiconductor device described herein.

FIG. 14 is a diagram of example components of one or more devices described herein.

FIG. 15 is a flowchart of an example process associated with forming a semiconductor device described herein.

FIG. 16 is a flowchart of an example process associated with forming a semiconductor device described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A continuous polysilicon on diffusion edge (CPODE) process may be performed to remove a portion of a polysilicon dummy gate structure, and replace the portion of the polysilicon dummy gate structure with a CPODE structure. The CPODE structure includes an isolation structure that is formed in a recess after removal of the portion of the polysilicon dummy gate structure. The CPODE structure may extend into a silicon fin under the polysilicon dummy gate structure. The CPODE structure may be formed to provide isolation (e.g., electrical isolation and/or physical isolation) between regions of a semiconductor device, such as between device regions of the semiconductor device, between active regions of the semiconductor device, and/or between transistors of the semiconductor device, among other examples.

In some cases, the CPODE process may cause one or more layout dependent effects (LDEs) to occur in the semiconductor device. For example, the portion of the polysilicon dummy gate structure that is removed for the CPODE structure may be adjacent to one or more source/drain regions of transistors of the semiconductor device. The etch process to remove the portion of the polysilicon dummy gate structure may result critical dimension (CD) loading and epitaxial damage (EPI damage) to these source/drain regions. As another example, depth loading may occur in the etch process, where an insufficient amount of the silicon fin is removed to form the CPODE structure to an adequate depth to provide electrical isolation between the source/drain regions. This can lead to an increased likelihood of current leakage between the source/drain regions (e.g., through the silicon fin and/or through the underlying substrate). As another example, the CPODE structure may cause gate deformation of the polysilicon dummy gate structure and/or of other polysilicon dummy gate structures, which may result in threshold voltage (Vₜ) shifting and threshold voltage variation for the transistors of the semiconductor device. The threshold voltage variation may cause variations in transistor switching speed, variations in power consumption, and/or reduced device performance for the transistors of the semiconductor device.

Some implementations described herein provide CPODE processes in which one or more parameters of hybrid fin structures and/or shallow trench isolation (STI) regions of a semiconductor device are tuned to reduce the likelihood of epitaxial damage to source/drain regions of the semiconductor device. For example, the heights of the hybrid fin structures and/or STI regions, and/or etching of the hybrid fin structures and/or STI regions, may be tuned to reduce the likelihood of epitaxial damage to source/drain regions of the semiconductor device.

As another example, the STI regions may be fully removed when forming the recess for a CPODE structure, which may reduce the likelihood of epitaxial damage to source/drain regions of the semiconductor device. The STI regions may be removed in a middle end of line (MEOL) CPODE process in which a CPODE structure is formed in a semiconductor device after a replacement gate process (RPG) that is performed to replace the polysilicon dummy gate structures of the semiconductor device with metal gate structures.

The CPODE processes described herein may reduce the likelihood of etching the source/drain regions on opposing sides of the CPODE structures, may reduce the likelihood of depth loading in the semiconductor, and/or may reduce the likelihood of gate deformation in the semiconductor device, among other examples. Thus, the CPODE processes described herein may reduce the likelihood of epitaxial damage to the source/drain regions, may reduce current leakage between the source/drain regions, and/or may reduce the likelihood of threshold voltage shifting for the transistors of the semiconductor device. The reduced likelihood of threshold voltage shifting may provide more uniform and/or faster switching speeds for the transistors, more uniform and/or lower power consumption for the transistors, and/or increased device performance for the transistors, among other examples.

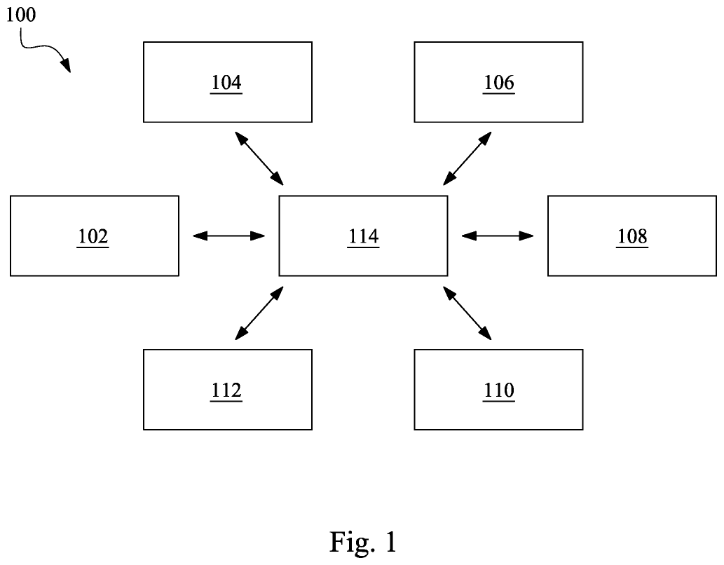

FIG. 1 is a diagram of an example environment 100 in which systems and/or methods described herein may be implemented. As shown in FIG. 1, the example environment 100 may include a plurality of semiconductor processing tools 102-112 and a wafer/die transport tool 114. The plurality of semiconductor processing tools 102-112 may include a deposition tool 102, an exposure tool 104, a developer tool 106, an etch tool 108, a planarization tool 110, a plating tool 112, and/or another type of semiconductor processing tool. The tools included in example environment 100 may be included in a semiconductor clean room, a semiconductor foundry, a semiconductor processing facility, and/or manufacturing facility, among other examples.

The deposition tool 102 is a semiconductor processing tool that includes a semiconductor processing chamber and one or more devices capable of depositing various types of materials onto a substrate. In some implementations, the deposition tool 102 includes a spin coating tool that is capable of depositing a photoresist layer on a substrate such as a wafer. In some implementations, the deposition tool 102 includes a chemical vapor deposition (CVD) tool such as a plasma-enhanced CVD (PECVD) tool, a high-density plasma CVD (HDP-CVD) tool, a sub-atmospheric CVD (SACVD) tool, a low-pressure CVD (LPCVD) tool, an atomic layer deposition (ALD) tool, a plasma-enhanced atomic layer deposition (PEALD) tool, or another type of CVD tool. In some implementations, the deposition tool 102 includes a physical vapor deposition (PVD) tool, such as a sputtering tool or another type of PVD tool. In some implementations, the deposition tool 102 includes an epitaxial tool that is configured to form layers and/or regions of a device by epitaxial growth. In some implementations, the example environment 100 includes a plurality of types of deposition tools 102.

The exposure tool 104 is a semiconductor processing tool that is capable of exposing a photoresist layer to a radiation source, such as an ultraviolet light (UV) source (e.g., a deep UV light source, an extreme UV light (EUV) source, and/or the like), an x-ray source, an electron beam (e-beam) source, and/or the like. The exposure tool 104 may expose a photoresist layer to the radiation source to transfer a pattern from a photomask to the photoresist layer. The pattern may include one or more semiconductor device layer patterns for forming one or more semiconductor devices, may include a pattern for forming one or more structures of a semiconductor device, may include a pattern for etching various portions of a semiconductor device, and/or the like. In some implementations, the exposure tool 104 includes a scanner, a stepper, or a similar type of exposure tool.

The developer tool 106 is a semiconductor processing tool that is capable of developing a photoresist layer that has been exposed to a radiation source to develop a pattern transferred to the photoresist layer from the exposure tool 104. In some implementations, the developer tool 106 develops a pattern by removing unexposed portions of a photoresist layer. In some implementations, the developer tool 106 develops a pattern by removing exposed portions of a photoresist layer. In some implementations, the developer tool 106 develops a pattern by dissolving exposed or unexposed portions of a photoresist layer through the use of a chemical developer.

The etch tool 108 is a semiconductor processing tool that is capable of etching various types of materials of a substrate, wafer, or semiconductor device. For example, the etch tool 108 may include a wet etch tool, a dry etch tool, and/or the like. In some implementations, the etch tool 108 includes a chamber that can be filled with an etchant, and the substrate is placed in the chamber for a particular time period to remove particular amounts of one or more portions of the substrate. In some implementations, the etch tool 108 etches one or more portions of the substrate using a plasma etch or a plasma-assisted etch, which may involve using an ionized gas to isotropically or directionally etch the one or more portions. In some implementations, the etch tool 108 includes a plasma-based asher to remove a photoresist material and/or another material.

The planarization tool 110 is a semiconductor processing tool that is capable of polishing or planarizing various layers of a wafer or semiconductor device. For example, a planarization tool 110 may include a chemical mechanical planarization (CMP) tool and/or another type of planarization tool that polishes or planarizes a layer or surface of deposited or plated material. The planarization tool 110 may polish or planarize a surface of a semiconductor device with a combination of chemical and mechanical forces (e.g., chemical etching and free abrasive polishing). The planarization tool 110 may utilize an abrasive and corrosive chemical slurry in conjunction with a polishing pad and retaining ring (e.g., typically of a greater diameter than the semiconductor device). The polishing pad and the semiconductor device may be pressed together by a dynamic polishing head and held in place by the retaining ring. The dynamic polishing head may rotate with different axes of rotation to remove material and even out any irregular topography of the semiconductor device, making the semiconductor device flat or planar.

The plating tool 112 is a semiconductor processing tool that is capable of plating a substrate (e.g., a wafer, a semiconductor device, and/or the like) or a portion thereof with one or more metals. For example, the plating tool 112 may include a copper electroplating device, an aluminum electroplating device, a nickel electroplating device, a tin electroplating device, a compound material or alloy (e.g., tin-silver, tin-lead, and/or the like) electroplating device, and/or an electroplating device for one or more other types of conductive materials, metals, and/or similar types of materials.

Wafer/die transport tool 114 includes a mobile robot, a robot arm, a tram or rail car, an overhead hoist transport (OHT) system, an automated material handling system (AMHS), and/or another type of device that is configured to transport substrates and/or semiconductor devices between semiconductor processing tools 102-112, that is configured to transport substrates and/or semiconductor devices between processing chambers of the same semiconductor processing tool, and/or that is configured to transport substrates and/or semiconductor devices to and from other locations such as a wafer rack, a storage room, and/or the like. In some implementations, wafer/die transport tool 114 may be a programmed device that is configured to travel a particular path and/or may operate semi-autonomously or autonomously. In some implementations, the example environment 100 includes a plurality of wafer/die transport tools 114.

For example, the wafer/die transport tool 114 may be included in a cluster tool or another type of tool that includes a plurality of processing chambers, and may be configured to transport substrates and/or semiconductor devices between the plurality of processing chambers, to transport substrates and/or semiconductor devices between a processing chamber and a buffer area, to transport substrates and/or semiconductor devices between a processing chamber and an interface tool such as an equipment front end module (EFEM), and/or to transport substrates and/or semiconductor devices between a processing chamber and a transport carrier (e.g., a front opening unified pod (FOUP)), among other examples. In some implementations, a wafer/die transport tool 114 may be included in a multi-chamber (or cluster) deposition tool 102, which may include a pre-clean processing chamber (e.g., for cleaning or removing oxides, oxidation, and/or other types of contamination or byproducts from a substrate and/or semiconductor device) and a plurality of types of deposition processing chambers (e.g., processing chambers for depositing different types of materials, processing chambers for performing different types of deposition operations). In these implementations, the wafer/die transport tool 114 is configured to transport substrates and/or semiconductor devices between the processing chambers of the deposition tool 102 without breaking or removing a vacuum (or an at least partial vacuum) between the processing chambers and/or between processing operations in the deposition tool 102, as described herein.

As described herein, the semiconductor processing tools 102-112 may be used to perform a combination of operations to form one or more portions of a nanostructure transistor. In some implementations, the combination of operations may include forming, over a semiconductor substrate of a semiconductor device, a plurality of nanostructure layers in a direction that is perpendicular to the semiconductor substrate, where the plurality of nanostructure layers includes a plurality of sacrificial layers alternating with a plurality of channel layers; may include etching the plurality of nanostructure layers and the semiconductor substrate to form a plurality of mesa regions and a plurality of layer stacks on the plurality of mesa regions, where the plurality of layer stacks include respective portions of the plurality of sacrificial layers and respective portions of the plurality of channel layers; may include forming, between adjacent layer stacks of the plurality of layer stacks, STI regions, and hybrid fin structures over the STI regions; may include forming, over the plurality of layer stacks and over the hybrid fin structures, a dummy gate structure; may include removing portions of the plurality of nanostructure layers to form one or more recesses adjacent to one or more sides of the dummy gate structure; and/or may include forming one or more source/drain regions in the one or more recesses, where a top surface of a hybrid fin structure of the hybrid fin structures is located at a greater height in the semiconductor device than a top surface of a source/drain region of the one or more source/drain regions, among other examples.

In some implementations, the combination of operations may include forming, over a semiconductor substrate, a plurality of nanostructure layers in a direction that is perpendicular to the semiconductor substrate, where the plurality of nanostructure layers includes a plurality of sacrificial layers alternating with a plurality of channel layers; may include forming, over the plurality of nanostructure layers, a dummy gate structure; may include removing portions of the plurality of nanostructure layers to form one or more recesses adjacent to one or more sides of the dummy gate structure; may include forming one or more source/drain regions in the one or more recesses; may include replacing, after forming the one or more source/drain regions, the dummy gate structure and portions of the sacrificial layers under the dummy gate structure with a metal gate structure, where the metal gate structure wraps around at least four sides of the channel layers; may include removing, to form an active region isolation recess after replacing the dummy gate structure and the portions of the sacrificial layers under the dummy gate structure with the metal gate structure, a portion of the metal gate structure, portions of the channel layers around which the metal gate structure wraps, a plurality of mesa regions, under the portions of the channel layers, that extend above the semiconductor substrate, and an STI region between the plurality of mesa regions; and/or may include forming an active region isolation structure in the active region isolation recess.

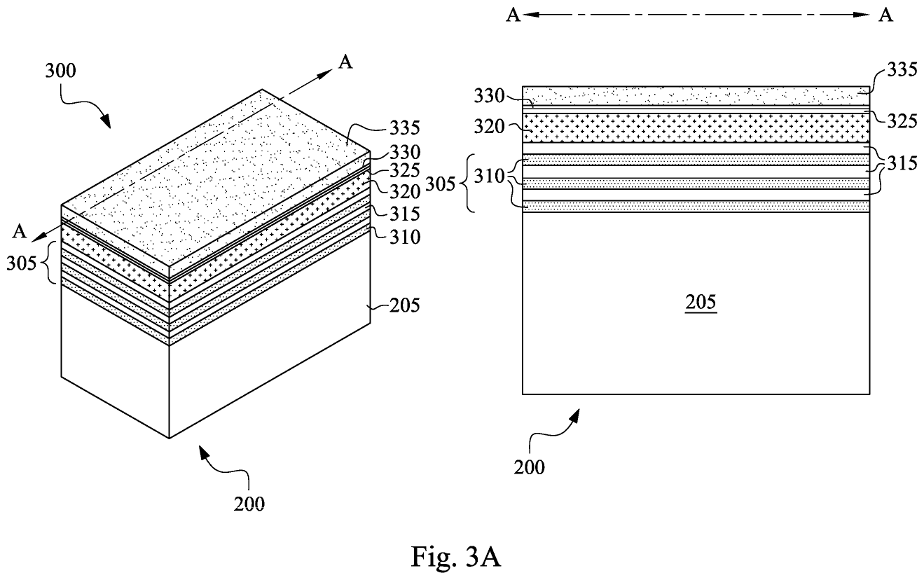

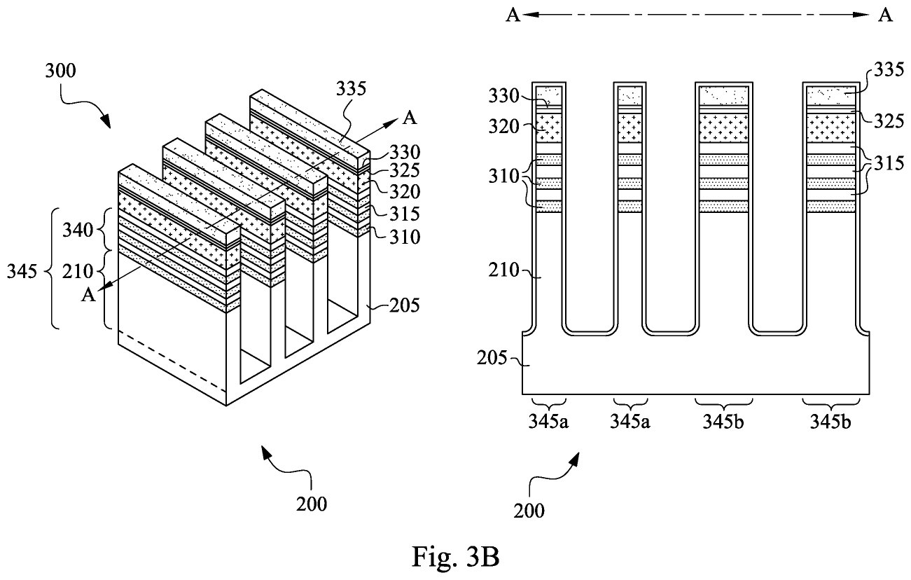

In some implementations, the combination of operations includes one or more operations described in connection with one or more of FIGS. 3A-11I.

The number and arrangement of devices shown in FIG. 1 are provided as one or more examples. In practice, there may be additional devices, fewer devices, different devices, or differently arranged devices than those shown in FIG. 1. Furthermore, two or more devices shown in FIG. 1 may be implemented within a single device, or a single device shown in FIG. 1 may be implemented as multiple, distributed devices. Additionally, or alternatively, a set of devices (e.g., one or more devices) of the example environment 100 may perform one or more functions described as being performed by another set of devices of the example environment 100.

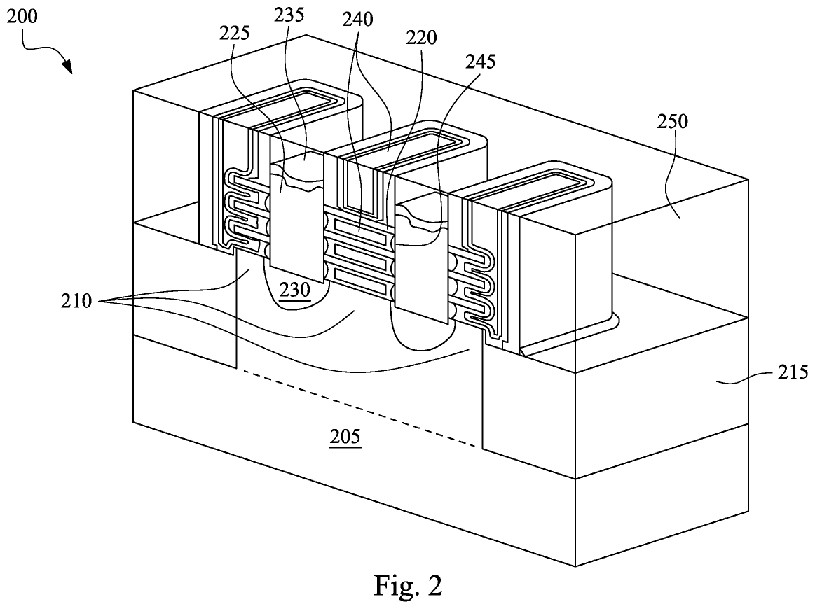

FIG. 2 is a diagram of an example semiconductor device 200 described herein. The semiconductor device 200 includes one or more transistors. The one or more transistors may include nanostructure transistor(s) such as nanowire transistors, nanosheet transistors, gate-all-around (GAA) transistors, multi-bridge channel transistors, nanoribbon transistors, and/or other types of nanostructure transistors. The semiconductor device 200 may include one or more additional devices, structures, and/or layers not shown in FIG. 2. For example, the semiconductor device 200 may include additional layers and/or dies formed on layers above and/or below the portion of the semiconductor device 200 shown in FIG. 2. Additionally, or alternatively, one or more additional semiconductor structures and/or semiconductor devices may be formed in a same layer of an electronic device or integrated circuit (IC) that includes the semiconductor device as the semiconductor device 200 shown in FIG. 2. One or more of FIGS. 3A-12B may include schematic cross-sectional views of various portions of the semiconductor device 200 illustrated in FIG. 2, and correspond to various processing stages of forming nanostructure transistors of the semiconductor device 200.

The semiconductor device 200 includes a semiconductor substrate 205. The semiconductor substrate 205 includes a silicon (Si) substrate, a substrate formed of a material including silicon, a III-V compound semiconductor material substrate such as gallium arsenide (GaAs), a silicon on insulator (SOI) substrate, a germanium (Ge) substrate, a silicon germanium (SiGe) substrate, a silicon carbide (SiC) substrate, or another type of semiconductor substrate. The semiconductor substrate 205 may include various layers, including conductive or insulating layers formed on a semiconductor substrate. The semiconductor substrate 205 may include a compound semiconductor and/or an alloy semiconductor. The semiconductor substrate 205 may include various doping configurations to satisfy one or more design parameters. For example, different doping profiles (e.g., n-wells, p-wells) may be formed on the semiconductor substrate 205 in regions designed for different device types (e.g., p-type metal-oxide semiconductor (PMOS) nanostructure transistors, n-type metal-oxide semiconductor (NMOS) nanostructure transistors). The suitable doping may include ion implantation of dopants and/or diffusion processes. Further, the semiconductor substrate 205 may include an epitaxial layer (EPI layer), may be strained for performance enhancement, and/or may have other suitable enhancement features. The semiconductor substrate 205 may include a portion of a semiconductor wafer on which other semiconductor devices are formed.

Mesa regions 210 are included above (and/or extend above) the semiconductor substrate 205. A mesa region 210 provides a structure on which nanostructures of the semiconductor device 200 are formed, such as nanostructure channels, nanostructure gate portions that wrap around each of the nanostructure channels, and/or sacrificial nanostructures, among other examples. In some implementations, one or more mesa regions 210 are formed in and/or from a fin structure (e.g., a silicon fin structure) that is formed in the semiconductor substrate 205. The mesa regions 210 may include the same material as the semiconductor substrate 205 and are formed from the semiconductor substrate 205. In some implementations, the mesa regions 210 are doped to form different types of nanostructure transistors, such as p-type nanostructure transistors and/or n-type nanostructure transistors. In some implementations, the mesa regions 210 include silicon (Si) materials or another elementary semiconductor material such as germanium (Ge). In some implementations, the mesa regions 210 include an alloy semiconductor material such as silicon germanium (SiGe), gallium arsenide phosphide (GaAsP), aluminum indium arsenide (AlInAs), aluminum gallium arsenide (AlGaAs), gallium indium arsenide (GaInAs), gallium indium phosphide (GaInP), gallium indium arsenide phosphide (GaInAsP), or a combination thereof.

The mesa regions 210 are fabricated by suitable semiconductor process techniques, such as masking, photolithography, and/or etch processes, among other examples. As an example, fin structures may be formed by etching a portion of the semiconductor substrate 205 away to form recesses in the semiconductor substrate 205. The recesses may then be filled with isolating material that is recessed or etched back to form shallow trench isolation (STI) regions 215 above the semiconductor substrate 205 and between the fin structures. Source/drain recesses may be formed in the fin structures, which results in formation of the mesa regions 210 between the source/drain recesses. However, other fabrication techniques for the STI regions 215 and/or for the mesa regions 210 may be used.

The STI regions 215 may electrically isolate adjacent fin structures and may provide a layer on which other layers and/or structures of the semiconductor device 200 are formed. The STI regions 215 may include a dielectric material such as a silicon oxide (SiOₓ), a silicon nitride (SiₓN_{y}), a silicon oxynitride (SiON), fluoride-doped silicate glass (FSG), a low-k dielectric material, and/or another suitable insulating material. The STI regions 215 may include a multi-layer structure, for example, having one or more liner layers.

The semiconductor device 200 includes a plurality of nanostructure channels 220 that extend between, and are electrically coupled with, source/drain regions 225. Source/drain region(s) may refer to a source or a drain, individually or collectively dependent upon the context. The nanostructure channels 220 are arranged in a direction that is approximately perpendicular to the semiconductor substrate 205. In other words, the nanostructure channels 220 are vertically arranged or stacked above the semiconductor substrate 205.

The nanostructure channels 220 include silicon-based nanostructures (e.g., nanosheets or nanowires, among other examples) that function as the semiconductive channels of the nanostructure transistor(s) of the semiconductor device 200. In some implementations, the nanostructure channels 220 may include silicon germanium (SiGe) or another silicon-based material. The source/drain regions 225 include silicon (Si) with one or more dopants, such as a p-type material (e.g., boron (B) or germanium (Ge), among other examples), an n-type material (e.g., phosphorous (P) or arsenic (As), among other examples), and/or another type of dopant. Accordingly, the semiconductor device 200 may include p-type metal-oxide semiconductor (PMOS) nanostructure transistors that include p-type source/drain regions 225, n-type metal-oxide semiconductor (NMOS) nanostructure transistors that include n-type source/drain regions 225, and/or other types of nanostructure transistors.

In some implementations, a buffer region 230 is included under a source/drain region 225 between the source/drain region 225 and a fin structure above the semiconductor substrate 205. A buffer region 230 may provide isolation between a source/drain region 225 and adjacent mesa regions 210. A buffer region 230 may be included to reduce, minimize, and/or prevent electrons from traversing into the mesa regions 210 (e.g., instead of through the nanostructure channels 220, thereby reducing current leakage), and/or may be included to reduce, minimize and/or prevent dopants from the source/drain region 225 into the mesa regions 210 (which reduces short channel effects).

A capping layer 235 may be included over and/or on the source/drain region 225. The capping layer 235 may include silicon, silicon germanium, doped silicon, doped silicon germanium, and/or another material. The capping layer 235 may be included to reduce dopant diffusion and to protect the source/drain regions 225 in semiconductor processing operations for the semiconductor device 200 prior to contact formation. Moreover, the capping layer 235 may contribute to metal-semiconductor (e.g., silicide) alloy formation.

At least a subset of the nanostructure channels 220 extend through one or more gate structures 240. The gate structures 240 may be formed of one or more metal materials, one or more high dielectric constant (high-k) materials, and/or one or more other types of materials. In some implementations, dummy gate structures (e.g., polysilicon (PO) gate structures or another type of gate structures) are formed in the place of (e.g., prior to formation of) the gate structures 240 so that one or more other layers and/or structures of the semiconductor device 200 may be formed prior to formation of the gate structures 240. This reduces and/or prevents damage to the gate structures 240 that would otherwise be caused by the formation of the one or more layers and/or structures. A replacement gate process (RGP) is then performed to remove the dummy gate structures and replace the dummy gate structures with the gate structures 240 (e.g., replacement gate structures).

As further shown in FIG. 2, portions of a gate structure 240 are formed in between pairs of nanostructure channels 220 in an alternating vertical arrangement. In other words, the semiconductor device 200 includes one or more vertical stacks of alternating nanostructure channels 220 and portions of a gate structure 240, as shown in FIG. 2. In this way, a gate structure 240 wraps around an associated nanostructure channel 220 on all sides of the nanostructure channel 220 which increases control of the nanostructure channel 220, increases drive current for the nanostructure transistor(s) of the semiconductor device 200, and reduces short channel effects (SCEs) for the nanostructure transistor(s) of the semiconductor device 200.

Some source/drain regions 225 and gate structures 240 may be shared between two or more nanoscale transistors of the semiconductor device 200. In these implementations, one or more source/drain regions 225 and a gate structure 240 may be connected or coupled to a plurality of nanostructure channels 220, as shown in the example in FIG. 2. This enables the plurality of nanostructure channels 220 to be controlled by a single gate structure 240 and a pair of source/drain regions 225.

Inner spacers (InSP) 245 may be included between a source/drain region 225 and an adjacent gate structure 240. In particular, inner spacers 245 may be included between a source/drain region 225 and portions of a gate structure 240 that wrap around a plurality of nanostructure channels 220. The inner spacers 245 are included on ends of the portions of the gate structure 240 that wrap around the plurality of nanostructure channels 220. The inner spacers 245 are included in cavities that are formed in between end portions of adjacent nanostructure channels 220. The inner spacer 245 are included to reduce parasitic capacitance and to protect the source/drain regions 225 from being etched in a nanosheet release operation to remove sacrificial nanosheets between the nanostructure channels 220. The inner spacers 245 include a silicon nitride (SiₓN_{y}), a silicon oxide (SiOₓ), a silicon oxynitride (SiON), a silicon oxycarbide (SiOC), a silicon carbon nitride (SiCN), a silicon oxycarbonnitride (SiOCN), and/or another dielectric material.

In some implementations, the semiconductor device 200 includes hybrid fin structures (not shown). The hybrid fin structures may also be referred to as dummy fins, H-fins, or non-active fins, among other examples. Hybrid fin structures may be included between adjacent source/drain regions 225, between portions of a gate structure 240, and/or between adjacent stacks of nanostructure channels 220, among other examples. The hybrid fins extend in a direction that is approximately perpendicular to the gate structures 240.

Hybrid fin structures are configured to provide electrical isolation between two or more structures and/or components included in the semiconductor device 200. In some implementations, a hybrid fin structure is configured to provide electrical isolation between two or more stacks of nanostructure channels 220. In some implementations, a hybrid fin structure is configured to provide electrical isolation between two or more source/drain regions 225. In some implementations, a hybrid fin structure is configured to provide electrical isolation between two or more gates structures or two or more portions of a gate structure. In some implementations, a hybrid fin structure is configured to provide electrical isolation between a source/drain region 225 and a gate structure 240.

A hybrid fin structure may include a plurality of types of dielectric materials. A hybrid fin structure may include a combination of one or more low dielectric constant (low-k) dielectric materials (e.g., a silicon oxide (SiOₓ) and/or a silicon nitride (SiₓN_{y}), among other examples) and one or more high dielectric constant (high-k) dielectric materials (e.g., a hafnium oxide (HfOₓ) and/or other high-k dielectric material).

The semiconductor device 200 may also include an inter-layer dielectric (ILD) layer 250 above the STI regions 215. The ILD layer 250 may be referred to as an ILD0 layer. The ILD layer 250 surrounds the gate structures 240 to provide electrical isolation and/or insulation between the gate structures 240 and/or the source/drain regions 225, among other examples. Conductive structures such as contacts and/or interconnects may be formed through the ILD layer 250 to the source/drain regions 225 and the gate structures 240 to provide control of the source/drain regions 225 and the gate structures 240.

As indicated above, FIG. 2 is provided as an example. Other examples may differ from what is described with regard to FIG. 2.

FIGS. 3A and 3B are diagrams of an example implementation 300 of a fin formation process described herein. The example implementation 300 includes an example of forming fin structures for the semiconductor device 200 or a portion thereof. The semiconductor device 200 may include one or more additional devices, structures, and/or layers not shown in FIGS. 3A and 3B. The semiconductor device 200 may include additional layers and/or dies formed on layers above and/or below the portion of the semiconductor device 200 shown in FIGS. 3A and 3B. Additionally, or alternatively, one or more additional semiconductor structures and/or semiconductor devices may be formed in a same layer of an electronic device that includes the semiconductor device 200.

FIG. 3A illustrates a perspective view of the semiconductor device 200 and a cross-sectional view along the line A-A in the perspective view. As shown in FIGS. 3A, processing of the semiconductor device 200 is performed in connection with the semiconductor substrate 205. A layer stack 305 is formed on the semiconductor substrate 205. The layer stack 305 may be referred to as a superlattice. In some implementations, one or more operations are performed in connection with the semiconductor substrate 205 prior to formation of the layer stack 305. For example, an anti-punch through (APT) implant operation may be performed. The APT implant operation may be performed in one or more regions of the semiconductor substrate 205 above which the nanostructure channels 220 are to be formed. The APT implant operation is performed, for example, to reduce and/or prevent punch-through or unwanted diffusion into the semiconductor substrate 205.

The layer stack 305 includes a plurality of alternating layers that are arranged in a direction that is approximately perpendicular to the semiconductor substrate 205. For example, the layer stack 305 includes vertically alternating layers of first layers 310 and second layers 315 above the semiconductor substrate 205. The quantity of the first layers 310 and the quantity of the second layers 315 illustrated in FIG. 3A are examples, and other quantities of the first layers 310 and the second layers 315 are within the scope of the present disclosure. In some implementations, the first layers 310 and the second layers 315 are formed to different thicknesses. For example, the second layers 315 may be formed to a thickness that is greater relative to a thickness of the first layers 310. In some implementations, the first layers 310 (or a subset thereof) are formed to a thickness in a range of approximately 4 nanometers to approximately 7 nanometers. In some implementations, the second layers 315 (or a subset thereof) are formed to a thickness in a range of approximately 8 nanometers to approximately 12 nanometers. However, other values for the thickness of the first layers 310 and for the thickness of the second layers 315 are within the scope of the present disclosure.

The first layers 310 include a first material composition, and the second layers 315 include a second material composition. In some implementations, the first material composition and the second material composition are the same material composition. In some implementations, the first material composition and the second material composition are different material compositions. As an example, the first layers 310 may include silicon germanium (SiGe) and the second layers 315 may include silicon (Si). In some implementations, the first material composition and the second material composition have different oxidation rates and/or etch selectivity.

As described herein, the second layers 315 may be processed to form the nanostructure channel 220 for subsequently-formed nanostructure transistors of the semiconductor device 200. The first layers 310 are sacrificial nanostructures that are eventually removed and serve to define a vertical distance between adjacent nanostructure channels 220 for a subsequently-formed gate structure 240 of the semiconductor device 200. Accordingly, the first layers 310 are referred to herein as sacrificial layers, and the second layers 315 may be referred to as channel layers.

The deposition tool 102 deposits and/or grows the alternating layers of the layer stack 305 to include nanostructures (e.g., nanosheets) on the semiconductor substrate 205. For example, the deposition tool 102 grows the alternating layers by epitaxial growth. However, other processes may be used to form the alternating layers of the layer stack 305. Epitaxial growth of the alternating layers of the layer stack 305 may be performed by a molecular beam epitaxy (MBE) process, a metalorganic chemical vapor deposition (MOCVD) process, and/or another suitable epitaxial growth process. In some implementations, the epitaxially grown layers such as the second layers 315 include the same material as the material of the semiconductor substrate 205. In some implementations, the first layers 310 and/or the second layers 315 include a material that is different from the material of the semiconductor substrate 205. As described above, in some implementations, the first layers 310 include epitaxially grown silicon germanium (SiGe) layers and the second layers 315 include epitaxially grown silicon (Si) layers. Alternatively, the first layers 310 and/or the second layers 315 may include other materials such as germanium (Ge), a compound semiconductor material such as silicon carbide (SiC), gallium arsenide (GaAs), gallium phosphide (GaP), indium phosphide (InP), indium arsenide (IAs), indium antimonide (InSb), an alloy semiconductor such as silicon germanium (SiGe), gallium arsenide phosphide (GaAsP), aluminum indium arsenide (AlInAs), aluminum gallium arsenide (AlGaAs), indium gallium arsenide (InGaAs), gallium indium phosphide (GaInP), gallium indium arsenide phosphide (GaInAsP), and/or a combination thereof. The material(s) of the first layers 310 and/or the material(s) of the second layers 315 may be chosen based on providing different oxidation properties, different etching selectivity properties, and/or other different properties.

As further shown in FIG. 3A, the deposition tool 102 may form one or more additional layers over and/or on the layer stack 305. For example, a hard mask (HM) layer 320 may be formed over and/or on the layer stack 305 (e.g., on the top-most second layer 315 of the layer stack 305). As another example, a capping layer 325 may be formed over and/or on the hard mask layer 320. As another example, another hard mask layer including an oxide layer 330 and a nitride layer 335 may be formed over and/or on the capping layer 325. The one or more hard mask (HM) layers 320, 325, and 330 may be used to form one or more structures of the semiconductor device 200. The oxide layer 330 may function as an adhesion layer between the layer stack 305 and the nitride layer 335, and may act as an etch stop layer for etching the nitride layer 335. The one or more hard mask layers 320, 325, and 330 may include silicon germanium (SiGe), a silicon nitride (SiₓN_{y}), a silicon oxide (SiOₓ), and/or another material. The capping layer 325 may include silicon (Si) and/or another material. In some implementations, the capping layer 325 is formed of the same material as the semiconductor substrate 205. In some implementations, the one or more additional layers are thermally grown, deposited by CVD, PVD, ALD, and/or are formed using another deposition technique.

FIG. 3B illustrates a perspective view of the semiconductor device 200 and a cross-sectional view along the line A-A. As shown in FIG. 3B, the layer stack 305 and the semiconductor substrate 205 are etched to remove portions of the layer stack 305 and portions of the semiconductor substrate 205. The portions 340 of the layer stack 305, and mesa regions 210 (also referred to as silicon mesas or mesa portions), remaining after the etch operation are referred to a fin structures 345 above the semiconductor substrate 205 of the semiconductor device 200. A fin structure 345 includes a portion 340 of the layer stack 305 over and/or on a mesa region 210 formed in and/or above the semiconductor substrate 205. The fin structures 345 may be formed by any suitable semiconductor processing technique. For example, the deposition tool 102, the exposure tool 104, the developer tool 106, and/or the etch tool 108 may form the fin structures 345 using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, a sacrificial layer may be formed over a substrate and patterned using a photolithography process. Spacers are formed alongside the patterned sacrificial layer using a self-aligned process. The sacrificial layer is then removed, and the remaining spacers may then be used to pattern the fin structures.

In some implementations, the deposition tool 102 forms a photoresist layer over and/or on the hard mask layer including the oxide layer 330 and the nitride layer 335, the exposure tool 104 exposes the photoresist layer to radiation (e.g., deep ultraviolet (UV) radiation, extreme UV (EUV) radiation), a post-exposure bake process is performed (e.g., to remove residual solvents from the photoresist layer), and the developer tool 106 develops the photoresist layer to form a masking element (or pattern) in the photoresist layer. In some implementations, patterning the photoresist layer to form the masking element is performed using an electron beam (e-beam) lithography process. The masking element may then be used to protect portions of the semiconductor substrate 205 and portions the layer stack 305 in an etch operation such that the portions of the semiconductor substrate 205 and portions the layer stack 305 remain non-etched to form the fin structures 345. Unprotected portions of the substrate and unprotected portions of the layer stack 305 are etched (e.g., by the etch tool 108) to form trenches in the semiconductor substrate 205. The etch tool may etch the unprotected portions of the substrate and unprotected portions of the layer stack 305 using a dry etch technique (e.g., reactive ion etching), a wet etch technique, and/or a combination thereof.

In some implementations, another fin formation technique is used to form the fin structures 345. For example, a fin region may be defined (e.g., by mask or isolation regions), and the portions 340 may be epitaxially grown in the form of the fin structures 345. In some implementations, forming the fin structures 345 includes a trim process to decrease the width of the fin structures 345. The trim process may include wet and/or dry etching processes, among other examples.

As further shown in FIG. 3B, fin structures 345 may be formed for different types of nanostructure transistors for the semiconductor device 200. In particular, a first subset of fin structures 345a may be formed for p-type nanostructure transistors (e.g., p-type metal oxide semiconductor (PMOS) nanostructure transistors), and a second subset of fin structures 345b may be formed for n-type nanostructure transistors (e.g., n-type metal oxide semiconductor (NMOS) nanostructure transistors). The second subset of fin structures 345b may be doped with a p-type dopant (e.g., boron (B) and/or germanium (Ge), among other examples) and the first subset of fin structures 345a may be doped with an n-type dopant (e.g., phosphorous (P) and/or arsenic (As), among other examples). Additionally or alternatively, p-type source/drain regions 225 may be subsequently formed for the p-type nanostructure transistors that include the first subset of fin structures 345a, and n-type source/drain regions 225 may be subsequently formed for the n-type nanostructure transistors that include the second subset of fin structures 345b.

The first subset of fin structures 345a (e.g., PMOS fin structures) and the second subset of fin structures 345b (e.g., NMOS fin structures) may be formed to include similar properties and/or different properties. For example, the first subset of fin structures 345a may be formed to a first height and the second subset of fin structures 345b may be formed to a second height, where the first height and the second height are different heights. As another example, the first subset of fin structures 345a may be formed to a first width and the second subset of fin structures 345b may be formed to a second width, where the first width and the second width are different widths. In the example shown in FIG. 3B, the second width of the second subset of fin structures 345b (e.g., for the NMOS nanostructure transistors) is greater relative to the first width of the first subset of fin structures 345b (e.g., for the PMOS nanostructure transistors). However, other examples are within the scope of the present disclosure.

As indicated above, FIGS. 3A and 3B are provided as an example. Other examples may differ from what is described with regard to FIGS. 3A and 3B. Example implementation 300 may include additional operations, fewer operations, different operations, and/or a different order of operations than those described in connection with FIGS. 3A and 3B.

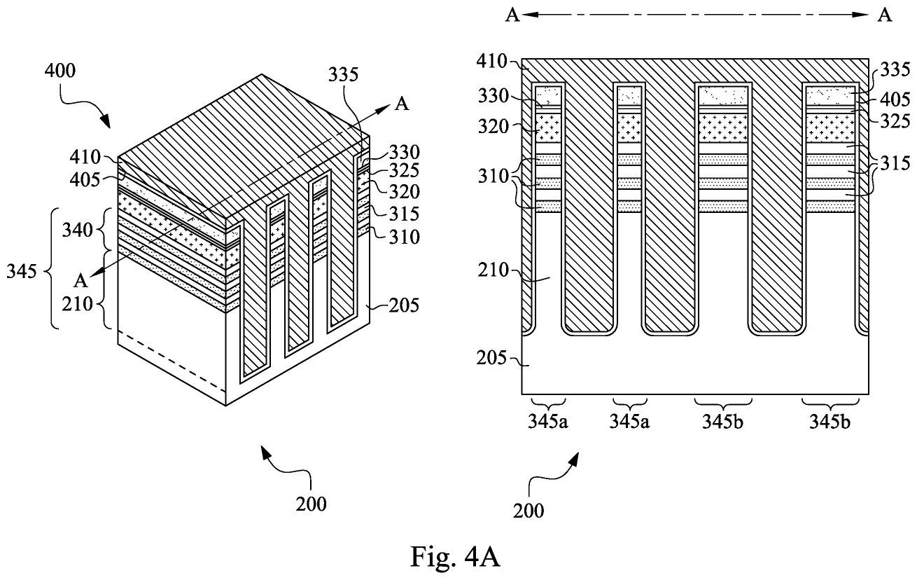

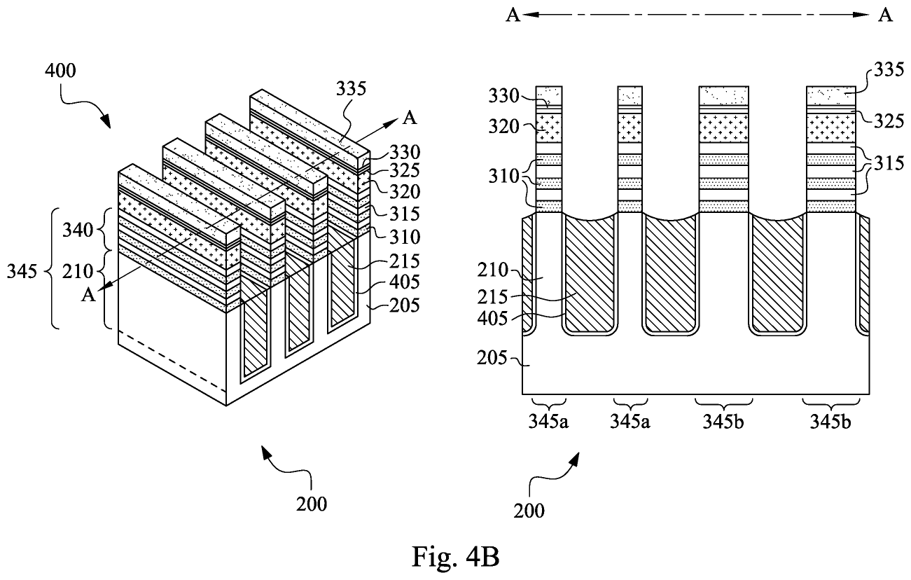

FIGS. 4A and 4B are diagrams of an example implementation 400 of an STI formation process described herein. The example implementation 400 includes an example of forming STI regions 215 between the fin structures 345 for the semiconductor device 200 or a portion thereof. The semiconductor device 200 may include one or more additional devices, structures, and/or layers not shown in FIGS. 4A and/or 4B. The semiconductor device 200 may include additional layers and/or dies formed on layers above and/or below the portion of the semiconductor device 200 shown in FIGS. 4A and 4B. Additionally, or alternatively, one or more additional semiconductor structures and/or semiconductor devices may be formed in a same layer of an electronic device that includes the semiconductor device 200. In some implementations, the operations described in connection with the example implementation 400 are performed after the processes described in connection with FIGS. 3A and 3B.

FIG. 4A illustrates a perspective view of the semiconductor device 200 and a cross-sectional view along the line A-A. As shown in FIG. 4A, a liner 405 and a dielectric layer 410 are formed above the semiconductor substrate 205 and interposing (e.g., in between) the fin structures 345. The deposition tool 102 may deposit the liner 405 and the dielectric layer 410 over the semiconductor substrate 205 and in the trenches between the fin structures 345. The deposition tool 102 may form the dielectric layer 410 such that a height of a top surface of the dielectric layer 410 and a height of a top surface of the nitride layer 335 are approximately a same height.

Alternatively, the deposition tool 102 may form the dielectric layer 410 such that the height of the top surface of the dielectric layer 410 is greater relative to the height of the top surface of the nitride layer 335, as shown in FIG. 4A. In this way, the trenches between the fin structures 345 are overfilled with the dielectric layer 410 to ensure the trenches are fully filled with the dielectric layer 410. Subsequently, the planarization tool 110 may perform a planarization or polishing operation (e.g., a CMP operation) to planarize the dielectric layer 410. The nitride layer 335 of the hard mask layer may function as a CMP stop layer in the operation. In other words, the planarization tool 110 planarizes the dielectric layer 410 until reaching the nitride layer 335 of the hard mask layer. Accordingly, a height of top surfaces of the dielectric layer 410 and a height of top surfaces of the nitride layer 335 are approximately equal after the operation.

The deposition tool 102 may deposit the liner 405 using a conformal deposition technique. The deposition tool 102 may deposit the dielectric layer using a CVD technique (e.g., a flowable CVD (FCVD) technique or another CVD technique), a PVD technique, an ALD technique, and/or another deposition technique. In some implementations, after deposition of the liner 405, the semiconductor device 200 is annealed, for example, to increase the quality of the liner 405.

The liner 405 and the dielectric layer 410 each includes a dielectric material such as a silicon oxide (SiOₓ), a silicon nitride (SiₓN_{y}), a silicon oxynitride (SiON), fluoride-doped silicate glass (FSG), a low-k dielectric material, and/or another suitable insulating material. In some implementations, the dielectric layer 410 may include a multi-layer structure, for example, having one or more liner layers.

FIG. 4B illustrates a perspective view of the semiconductor device 200 and a cross-sectional view along the line A-A. As shown in FIG. 4B, an etch back operation is performed to remove portions of the liner 405 and portions of the dielectric layer 410 to form the STI regions 215. The etch tool 108 may etch the liner 405 and the dielectric layer 410 in the etch back operation to form the STI regions 215. The etch tool 108 etches the liner 405 and the dielectric layer 410 based on the hard mask layer (e.g., the hard mask layer including the oxide layer 330 and the nitride layer 335). The etch tool 108 etches the liner 405 and the dielectric layer 410 such that the height of the STI regions 215 are less than or approximately a same height as the bottom of the portions 340 of the layer stack 305. Accordingly, the portions 340 of the layer stack 305 extend above the STI regions 215. In some implementations, the liner 405 and the dielectric layer 410 are etched such that the heights of the STI regions 215 are less than heights of top surfaces of the mesa regions 210.

In some implementations, the etch tool 108 uses a plasma-based dry etch technique to etch the liner 405 and the dielectric layer 410. Ammonia (NH₃), hydrofluoric acid (HF), and/or another etchant may be used. The plasma-based dry etch technique may result in a reaction between the etchant(s) and the material of the liner 405 and the dielectric layer 410, including:

SiO₂+4HF→SiF₄+2H₂O

where silicon dioxide (SiO₂) of the liner 405 and the dielectric layer 410 react with hydrofluoric acid to form byproducts including silicon tetrafluoride (SiF₄) and water (H₂O). The silicon tetrafluoride is further broken down by the hydrofluoric acid and ammonia to form an ammonium fluorosilicate ((NH₄)₂SiF₆) byproduct:

SiF₄+2HF+2NH₃→(NH₄)₂SiF₆

The ammonium fluorosilicate byproduct is removed from a processing chamber of the etch tool 108. After removal of the ammonium fluorosilicate, a post-process temperature in a range of approximately 200 degrees Celsius to approximately 250 degrees Celsius is used to sublimate the ammonium fluorosilicate into constituents of silicon tetrafluoride ammonia and hydrofluoric acid.

In some implementations, the etch tool 108 etches the liner 405 and the dielectric layer 410 such that a height of the STI regions 215 between the first subset of fin structures 345a (e.g., for the PMOS nanostructure transistors) is greater relative to a height of the STI regions 215 between the second subset of fin structures 345b (e.g., for the NMOS nanostructure transistors). This primarily occurs due to the greater width the fin structures 345b relative to the width of the fin structures 345a. Moreover, this results in a top surface of an STI region 215 between a fin structure 345a and a fin structure 345b being sloped or slanted (e.g., downward sloped from the fin structure 345a to the fin structure 345b, as shown in the example in FIG. 4A). The etchants used to etch the liner 405 and the dielectric layer 410 first experience physisorption (e.g., a physical bonding to the liner 405 and the dielectric layer 410) as a result of a Van der Waals force between the etchants and the surfaces of the liner 405 and the dielectric layer 410. The etchants become trapped by dipole movement force. The etchants then attach to dangling bonds of the liner 405 and the dielectric layer 410, and chemisorption begins. Here, the chemisorption of the etchant on the surface of the liner 405 and the dielectric layer 410 results in etching of the liner 405 and the dielectric layer 410. The greater width of the trenches between the second subset of fin structures 345a provides a greater surface area for chemisorption to occur, which results in a greater etch rate between the second subset of fin structures 345b. The greater etch rate results in the height of the STI regions 215 between the second subset of fin structures 345b being lesser relative to the height of the STI regions 215 between the first subset of fin structures 345a.

As indicated above, FIGS. 4A and 4B are provided as an example. Other examples may differ from what is described with regard to FIGS. 4A and 4B. Example implementation 400 may include additional operations, fewer operations, different operations, and/or a different order of operations than those described in connection with FIGS. 4A and 4B.

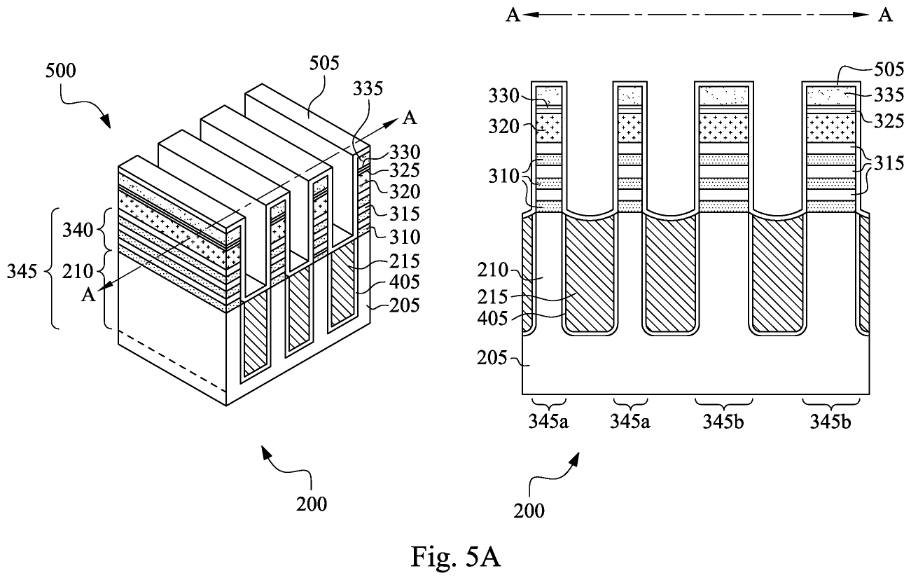

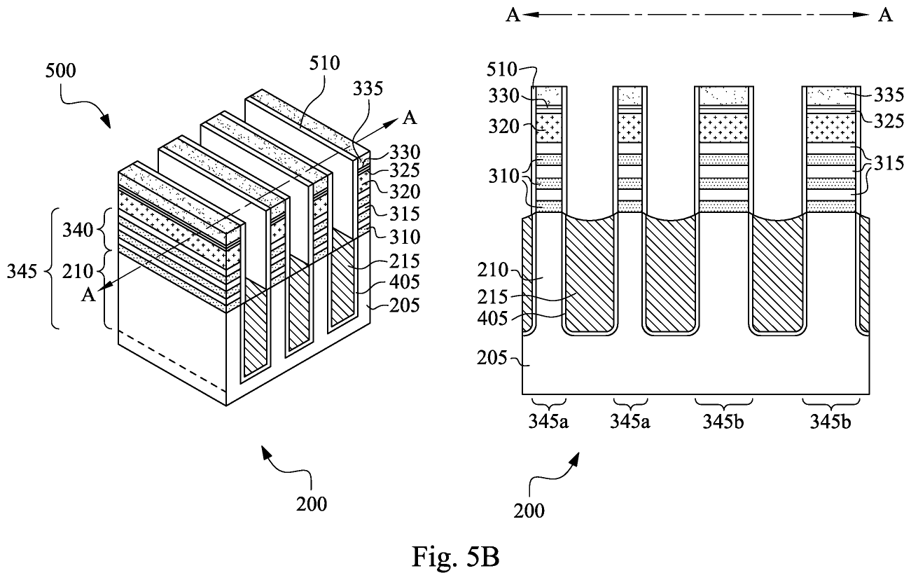

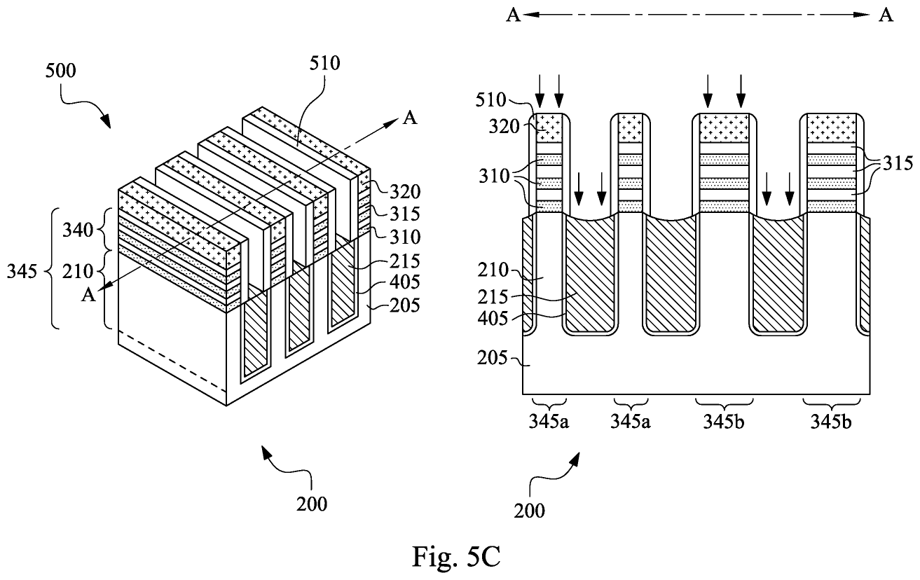

FIGS. 5A-5C are diagrams of an example implementation 500 of a cladding sidewall process described herein. The example implementation 400 includes an example of forming cladding sidewalls over sides of the portions 340 of the layer stacks 305 for the semiconductor device 200 or a portion thereof. The semiconductor device 200 may include one or more additional devices, structures, and/or layers not shown in FIGS. 5A-5C. The semiconductor device 200 may include additional layers and/or dies formed on layers above and/or below the portion of the semiconductor device 200 shown in FIGS. 5A-5C. Additionally, or alternatively, one or more additional semiconductor structures and/or semiconductor devices may be formed in a same layer of an electronic device that includes the semiconductor device 200. In some implementations, the operations described in connection with the example implementation 500 are performed after the processes described in connection with FIGS. 3A-4B.

FIG. 5A illustrates a perspective view of the semiconductor device 200 and a cross-sectional view along the line A-A. As shown in FIG. 5A, a cladding layer 505 is formed over the fin structures 345 (e.g., over the top surfaces and over the sidewalls of the fin structures 345) and over the STI regions 215 between the fin structures 345. The cladding layer 505 includes silicon germanium (SiGe) or another material. The cladding layer 505 may be formed of the same material as the first layers 310 to enable the cladding sidewalls (that are to be formed from the cladding layer 505) and the first layers 310 to be removed in the same etch operation (a nanostructure release operation) so that a replacement gate (e.g., a gate structure 240) may be formed in the areas occupied by the cladding sidewalls and the first layers 310. This enables the replacement gate to fully surround the nanostructure channels of the nanostructure transistors of the semiconductor device 200.

The deposition tool 102 may deposit the cladding layer 505. In some implementations, the deposition tool 102 deposits a seed layer (e.g., a silicon (Si) seed layer or another type of seed layer) over the fin structures 345 (e.g., over the top surfaces and over the sidewalls of the fin structures 345) and over the STI regions 215 between the fin structures 345. Then, the deposition tool 102 deposits silicon germanium on the seed layer to form the cladding layer 505. The seed layer promotes growth and adhesion of the cladding layer 505.

Deposition of the seed layer may include providing a silicon precursor to a processing chamber of the deposition tool 102 using a carrier gas such as nitrogen (N₂) or hydrogen (H₂), among other examples. In some implementations, a pre-clean operation is performed prior to deposition of the seed layer to reduce the formation of germanium oxide (GeOₓ). The silicon precursor may include disilane (Si₂H₆) or another silicon precursor. The use of disilane may enable formation of a seed layer to a thickness that is in a range of approximately 0.5 nanometers to approximately 1.5 nanometers to provide sufficient cladding sidewall thickness while achieving a controllable and uniform thickness for the cladding layer 505. However, other ranges and values for the thickness of the seed layer are within the scope of the present disclosure.

Deposition of the seed layer may be performed at a temperature in a range of approximately 450 degrees Celsius to approximately 500 degrees Celsius (or at a temperature in another range), at a pressure in a range of approximately 30 torr to approximately 100 torr (or at a pressure in another range), and/or for a time duration in a range of approximately 100 seconds to approximately 300 seconds (or for a time duration in another range), among other examples.

Deposition of the silicon germanium of the cladding layer 505 may include forming the cladding layer 505 to include an amorphous texture to promote conformal deposition of the cladding layer 505. The silicon germanium may include a germanium content in a range of approximately 15% germanium to approximately 25% germanium. However, other values for the germanium content are within the scope of the present disclosure. Deposition of the cladding layer 505 may include providing a silicon precursor (e.g., disilane (Si₂H₆) or silicon tetrahydride (SiH₄), among other examples) and a germanium precursor (e.g., germanium tetrahydride (GeH₄) or another germanium precursor) to a processing chamber of the deposition tool 102 using a carrier gas such as nitrogen (N₂) or hydrogen (H₂), among other examples. Deposition of the cladding layer 505 may be performed at a temperature in a range of approximately 500 degrees Celsius to approximately 550 degrees Celsius (or at a temperature in another range) and/or at a pressure in a range of approximately 5 torr to approximately 20 torr (or at a pressure in another range).

FIG. 5B illustrates a perspective view of the semiconductor device 200 and a cross-sectional view along the line A-A. As shown in FIG. 5B, an etch back operation is performed to etch the cladding layer 505 to form cladding sidewalls 510. The etch tool 108 may etch the cladding layer 505 using a plasma-based dry etch technique or another etch technique. The etch tool 108 may perform the etch back operation to remove portions of the cladding layer 505 from the tops of the fin structures 345 and from the tops of the STI regions 215. Removal of the cladding layer 505 from the tops of the STI regions 215 between the fin structures 345 ensures that the cladding sidewalls 510 do not include a footing on the STI regions 215 between the fin structures 345. This ensures that the cladding sidewalls 510 do not include a footing under hybrid fin structures that are to be formed over the STI regions 215 between the fin structures 345.

In some implementations, the etch tool 108 uses a fluorine-based etchant to etch the cladding layer 505. The fluorine-based etchant may include sulfur hexafluoride (SF₆), fluoromethane (CH₃F), and/or another fluorine-based etchant. Other reactants and/or carriers such as methane (CH₄), hydrogen (H2), argon (Ar), and/or helium (He) may be used in the etch back operation. In some implementations, the etch back operation is performed using a plasma bias in a range of approximately 500 volts to approximately 2000 volts. However, other values for the plasma bias are within the scope of the present disclosure. In some implementations, removing portions of the cladding layer 505 from the tops of the STI regions 215 includes performing a highly directional (e.g., anisotropic) etch to selectively remove (e.g., selectively etch) the cladding layer 505 on the tops of the STI regions 215 between the fin structures 345.

In some implementations, the cladding sidewalls 510 include asymmetric properties (e.g., different lengths, depths, and/or angles). The asymmetric properties may provide increased depth of gate structures 240 for different types of nanostructure transistors (e.g., for p-type nanostructure transistors, for n-type nanostructure transistors) while reducing and/or minimizing footing of the cladding sidewalls 510 (and thus, reducing and/or minimizing footing of the gate structures 240 that are formed in the areas that are occupied by the cladding sidewalls 510 after removal of the cladding sidewalls 510) on the STI region 215 under hybrid fin structures of the nanostructure transistors of the semiconductor device 200. The reduced and/or minimized footing further reduces a likelihood of electrical shorting and/or current leakage.

FIG. 5C illustrates a perspective view of the semiconductor device 200 and a cross-sectional view along the line A-A. As shown in FIG. 5C, the hard mask layer (including the oxide layer 330 and the nitride layer 335) and the capping layer 325 are removed to expose the hard mask layer 320. In some implementations, the capping layer 325, the oxide layer 330, and the nitride layer 335 are removed using an etch operation (e.g., performed by the etch tool 108), a planarization technique (e.g., performed by the planarization tool 110), and/or another semiconductor processing technique.

As indicated above, FIGS. 5A-5C are provided as an example. Other examples may differ from what is described with regard to FIGS. 5A-5C. Example implementation 500 may include additional operations, fewer operations, different operations, and/or a different order of operations than those described in connection with FIGS. 5A-5C.

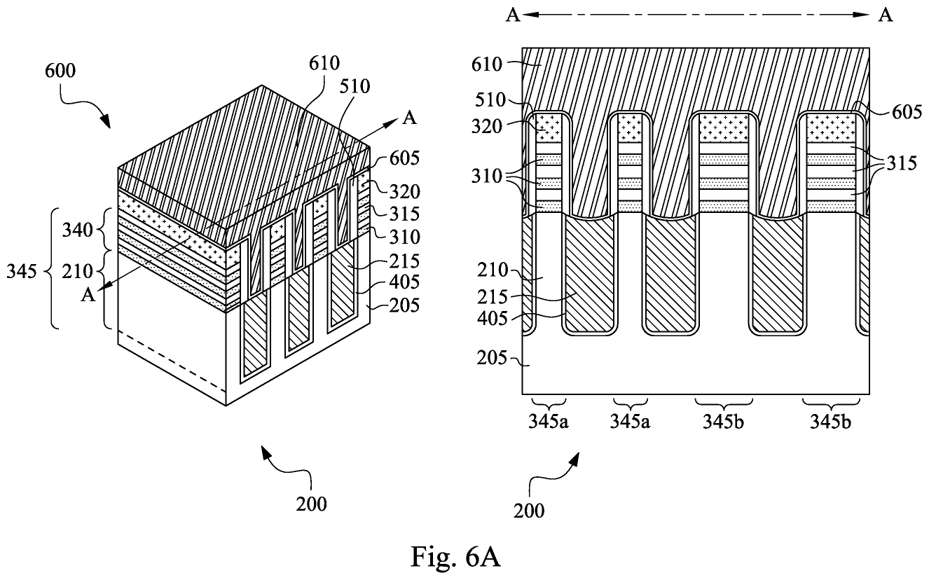

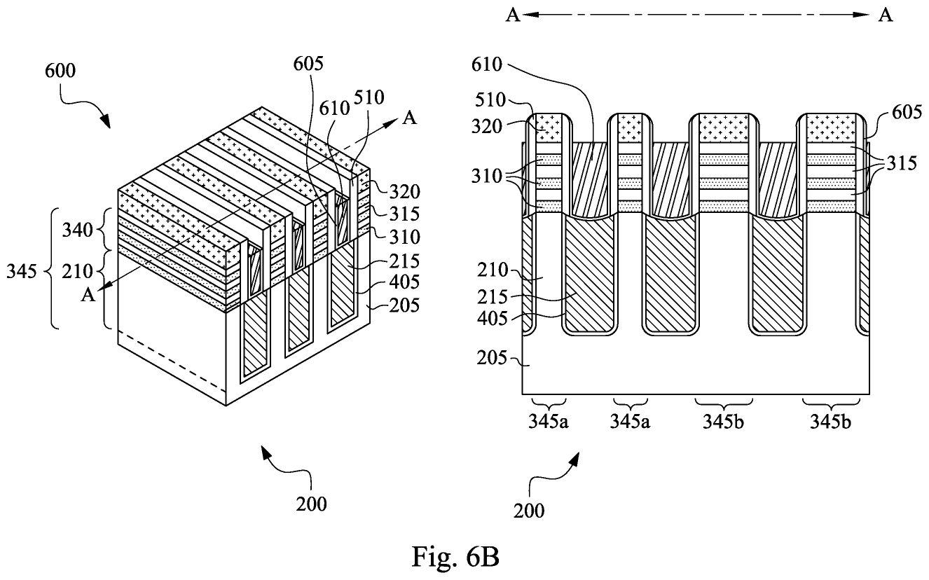

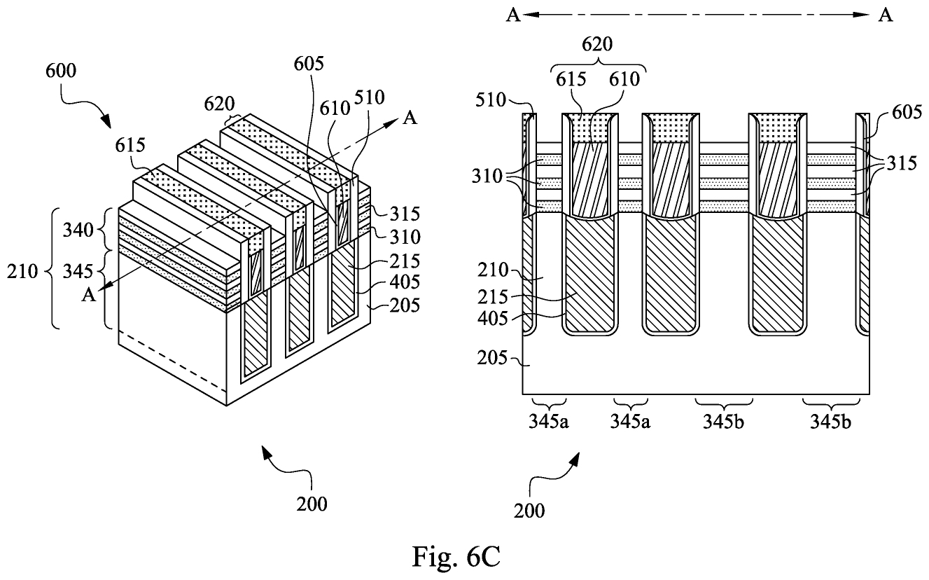

FIGS. 6A-6C are diagrams of an example implementation 600 of a hybrid fin structure process described herein. The example implementation 600 includes an example of forming hybrid fin structures between the fin structures 345 for the semiconductor device 200 or a portion thereof. The semiconductor device 200 may include one or more additional devices, structures, and/or layers not shown in FIGS. 6A-6C. The semiconductor device 200 may include additional layers and/or dies formed on layers above and/or below the portion of the semiconductor device 200 shown in FIGS. 6A-6C. Additionally, or alternatively, one or more additional semiconductor structures and/or semiconductor devices may be formed in a same layer of an electronic device that includes the semiconductor device 200. In some implementations, the operations described in connection with the example implementation 600 are performed after the processes described in connection with FIGS. 3A-5C.

FIG. 6A illustrates a perspective view of the semiconductor device 200 and a cross-sectional view along the line A-A. As shown in FIG. 6A, a liner 605 and a dielectric layer 610 are formed over the STI regions 215 interposing (e.g., in between) the fin structures 345, and over the fin structures 345. The deposition tool 102 may deposit the liner 605 and the dielectric layer 610. The deposition tool 102 may deposit the liner 605 using a conformal deposition technique. The deposition tool 102 may deposit the dielectric layer 610 using a CVD technique (e.g., a flowable CVD (FCVD) technique or another CVD technique), a PVD technique, an ALD technique, and/or another deposition technique. In some implementations, after deposition of the dielectric layer 610, the semiconductor device 200 is annealed, for example, to increase the quality of the dielectric layer 610.

The deposition tool 102 may form the dielectric layer 610 such that a height of a top surface of the dielectric layer 610 and a height of a top surface of the hard mask layer 320 are approximately a same height. Alternatively, the deposition tool 102 may form the dielectric layer 610 such that the height of the top surface of the dielectric layer 610 is greater relative to the height of the top surface of the hard mask layer 320, as shown in the example in FIG. 6A. In this way, the trenches between the fin structures 345 are overfilled with the dielectric layer 610 to ensure the trenches are fully filled with the dielectric layer 610. Subsequently, the planarization tool 110 may perform a planarization or polishing operation (e.g., a CMP operation) to planarize the dielectric layer 610.

The liner 605 and the dielectric layer 610 each includes a dielectric material such as a silicon oxide (SiOₓ), a silicon nitride (SiₓN_{y}), a silicon oxynitride (SiON), a silicon carbon nitride (SiCN), fluoride-doped silicate glass (FSG), a low-k dielectric material, and/or another suitable insulating material. In some implementations, the dielectric layer 610 may include a multi-layer structure, for example, having one or more liner layers.

FIG. 6B illustrates a perspective view of the semiconductor device 200 and a cross-sectional view along the line A-A. As shown in FIG. 6B, an etch back operation is performed to remove portions of the dielectric layer 610. The etch tool 108 may etch the dielectric layer 610 in the etch back operation to reduce a height of a top surface of the dielectric layer 610. In particular, the etch tool 108 etches the dielectric layer 610 such that the height of portions of the dielectric layer 610 between the fin structures 345 is less than the height of the top surface of the hard mask layer 320. In some implementations, the etch tool 108 etches the dielectric layer 610 such that the height of portions of the dielectric layer 610 between the fin structures 345 is approximately equal to a height of top surfaces of the top-most of the second layers 315 of the portions 340.

FIG. 6C illustrates a perspective view of the semiconductor device 200 and a cross-sectional view along the line A-A. As shown in FIG. 6C, a high dielectric constant (high-k) layer 615 is deposited over the portions of the dielectric layer 610 between the fin structures 345. The deposition tool 102 may deposit a high-k material such as a hafnium oxide (HfOₓ) and/or another high-k dielectric material to form the high-k dielectric layer 615 using a CVD technique, a PVD technique, an ALD technique, and/or another deposition technique. The combination of the portions of the dielectric layer 610 between the fin structures 345 and the high-k dielectric layer 615 between the fin structures 345 is referred to as a hybrid fin structure 620 (or dummy fin structure). In some implementations, the planarization tool 110 may perform a planarization operation to planarize the high-k dielectric layer 615 such that a height of a top surface of the high-k dielectric layer 615 and the height of the hard mask layer 320 are approximately equal.

Subsequently, and as shown in FIG. 6C, the hard mask layer 320 is removed. Removal of the hard mask layer 320 may include using an etch technique (e.g., a plasma etch technique, a wet chemical etch technique, and/or another type of etch technique) or another removal technique.

As indicated above, FIGS. 6A-6C are provided as an example. Other examples may differ from what is described with regard to FIGS. 6A-6C. Example implementation 600 may include additional operations, fewer operations, different operations, and/or a different order of operations than those described in connection with FIGS. 6A-6C.

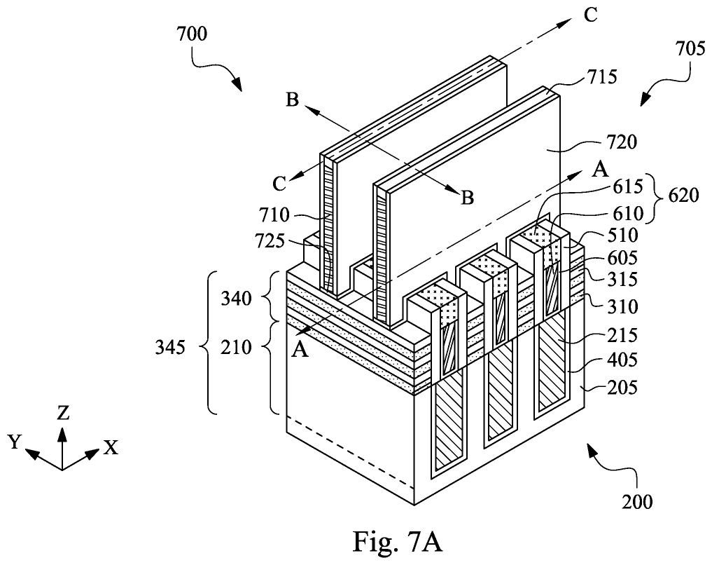

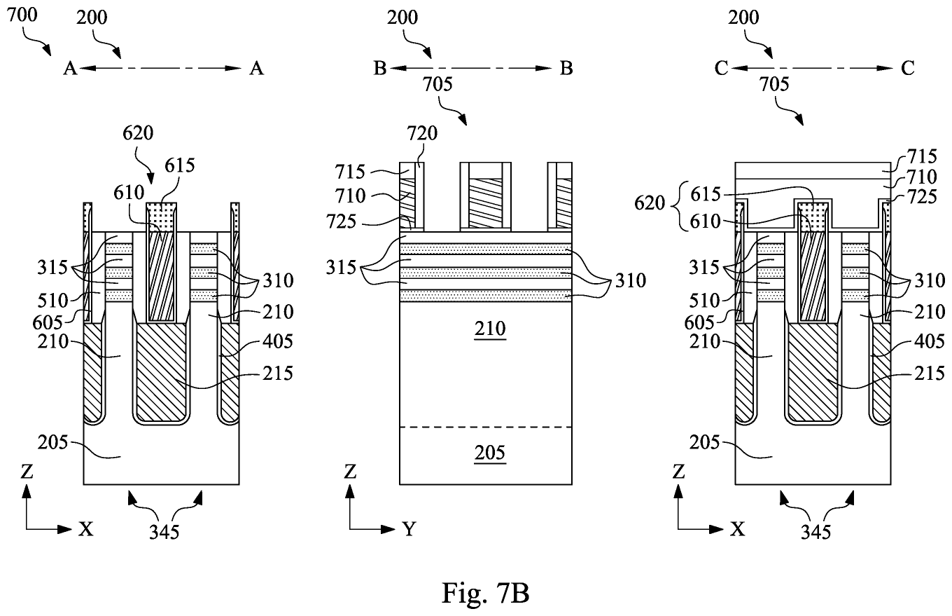

FIGS. 7A and 7B are diagrams of an example implementation 700 of a dummy gate formation process described herein. The example implementation 700 includes an example of forming dummy gate structures for the semiconductor device 200 or a portion thereof. The semiconductor device 200 may include one or more additional devices, structures, and/or layers not shown in FIGS. 7A and 7B. The semiconductor device 200 may include additional layers and/or dies formed on layers above and/or below the portion of the semiconductor device 200 shown in FIGS. 7A and 7B. Additionally, or alternatively, one or more additional semiconductor structures and/or semiconductor devices may be formed in a same layer of an electronic device that includes the semiconductor device 200. In some implementations, the operations described in connection with the example implementation 700 are performed after the processes described in connection with FIGS. 3A-6C.

FIG. 7A illustrates a perspective view of the semiconductor device 200. As shown in FIG. 7A, dummy gate structures 705 (also referred to as dummy gate stacks or temporary gate structures) are formed over the fin structures 345 and over the hybrid fin structures 620. The dummy gate structures 705 are sacrificial structures that are to be replaced by replacement gate structures or replacement gate stacks (e.g., the gate structures 240) at a subsequent processing stage for the semiconductor device 200. Portions of the fin structures 345 underlying the dummy gate structures 705 may be referred to as channel regions. The dummy gate structures 705 may also define source/drain (S/D) regions of the fin structures 345, such as the regions of the fin structures 345 adjacent and on opposing sides of the channel regions.

A dummy gate structure 705 may include agate electrode layer 710, a hard mask layer 715 over and/or on the gate electrode layer 710, and spacer layers 720 on opposing sides of the gate electrode layer 710 and on opposing sides of the hard mask layer 715. The dummy gate structures 705 may be formed on a gate dielectric layer 725 between the top-most second layer 315 and the dummy gate structures 705, and between the hybrid fin structures 620 and the dummy gate structures 705. The gate electrode layer 710 includes polycrystalline silicon (polysilicon or PO) or another material. The hard mask layer 715 includes one or more layers such as an oxide layer (e.g., a pad oxide layer that may include silicon dioxide (SiO₂) or another material) and a nitride layer (e.g., a pad nitride layer that may include a silicon nitride such as Si₃N₄ or another material) formed over the oxide layer. The spacer layers 720 include a silicon oxycarbide (SiOC), a nitrogen free SiOC, or another suitable material. The gate dielectric layer 725 may include a silicon oxide (e.g., SiOₓ such as SiO₂), a silicon nitride (e.g., SiₓN_{y} such as Si₃N₄), a high-K dielectric material and/or another suitable material.

The layers of the dummy gate structures 705 may be formed using various semiconductor processing techniques such as deposition (e.g., by the deposition tool 102), patterning (e.g., by the exposure tool 104 and the developer tool 106), and/or etching (e.g., by the etch tool 108), among other examples. Examples include CVD, PVD, ALD, thermal oxidation, e-beam evaporation, photolithography, e-beam lithography, photoresist coating (e.g., spin-on coating), soft baking, mask aligning, exposure, post-exposure baking, photoresist developing, rinsing, drying (e.g., spin-drying and/or hard baking), dry etching (e.g., reactive ion etching), and/or wet etching, among other examples.

In some implementations, the gate dielectric layer 725 is conformally deposited on the semiconductor device 200 and then selectively removed from portions of the semiconductor device 200 (e.g., the source/drain areas). The gate electrode layer 710 is then deposited onto the remaining portions of the gate dielectric layer 725. The hard mask layers 715 are then deposited onto the gate electrode layers 710. The spacer layers 720 may be conformally deposited in a similar manner as the gate dielectric layer 725 and etched back such that the spacer layers 720 remain on the sidewalls of the dummy gate structures 705. In some implementations, the spacer layers 720 include a plurality of types of spacer layers. For example, the spacer layers 720 may include a seal spacer layer that is formed on the sidewalls of the dummy gate structures 705 and a bulk spacer layer that is formed on the seal spacer layer. The seal spacer layer and the bulk spacer layer may be formed of similar materials or different materials. In some implementations, the bulk spacer layer is formed without plasma surface treatment that is used for the seal spacer layer. In some implementations, the bulk spacer layer is formed to a greater thickness relative to the thickness of the seal spacer layer. In some implementations, the gate dielectric layer 725 is omitted from the dummy gate structure formation process and is instead formed in the replacement gate process.

FIG. 7A further illustrates reference cross-sections that are used in subsequent figures described herein. Cross-section A-A is in an x-z plane (referred to as a y-cut) across the fin structures 345 and the hybrid fin structures 620 in source/drain areas of the semiconductor device 200. Cross-section B-B is in a y-z plane (referred to as an x-cut) perpendicular to the cross-section A-A, and is across the dummy gate structures 705 in the source/drain areas of the semiconductor device 200. Cross-section C-C is in the x-z plane parallel to the cross-section A-A and perpendicular to the cross-section B-B, and is along a dummy gate structures 705. Subsequent figures refer to these reference cross-sections for clarity. In some figures, some reference numbers of components or features illustrated therein may be omitted to avoid obscuring other components or features for ease of depicting the figures.

FIG. 7B includes cross-sectional views along the cross-sectional planes A-A, B-B, and C-C of FIG. 7A. As shown in the cross-sectional planes B-B and C-C in FIG. 7B, the dummy gate structures 705 are formed above the fin structures 345. As shown in the cross-sectional plane C-C in FIG. 7B, portions of the gate dielectric layer 725 and portions of the gate electrode layers 710 are formed in recesses above the fin structures 345 that are formed as a result of the removal of the hard mask layer 320.

As indicated above, FIGS. 7A and 7B are provided as an example. Other examples may differ from what is described with regard to FIGS. 7A and 7B. Example implementation 700 may include additional operations, fewer operations, different operations, and/or a different order of operations than those described in connection with FIGS. 7A and 7B.

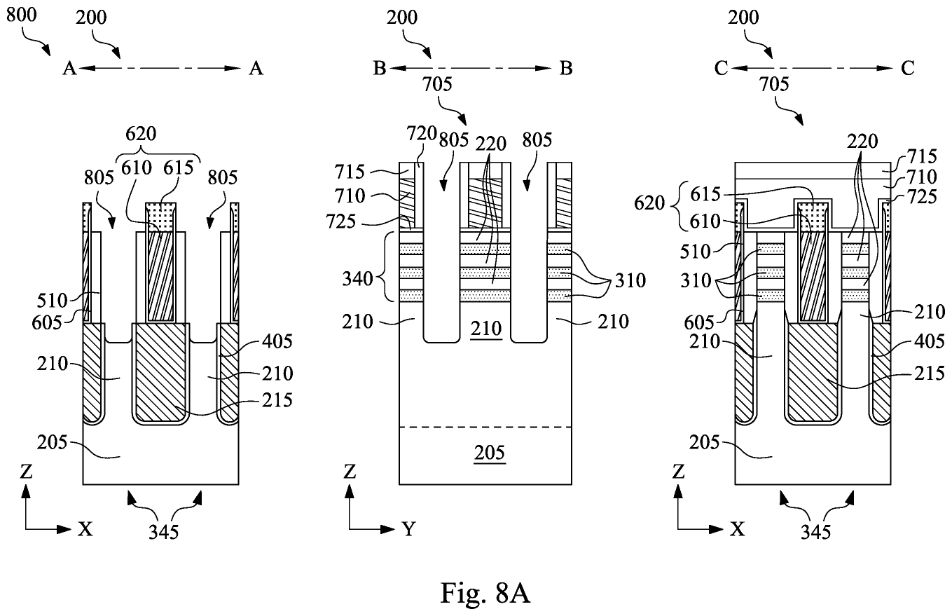

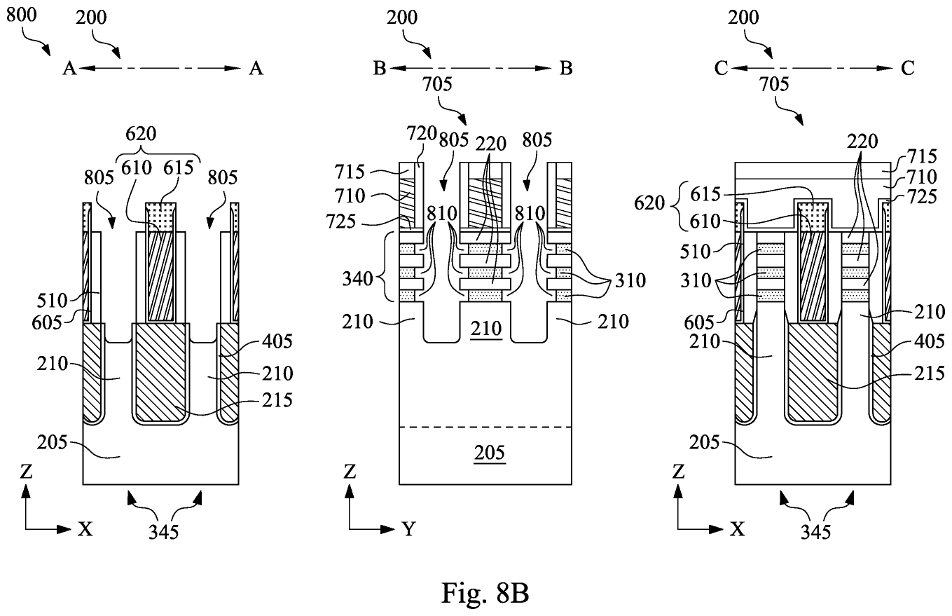

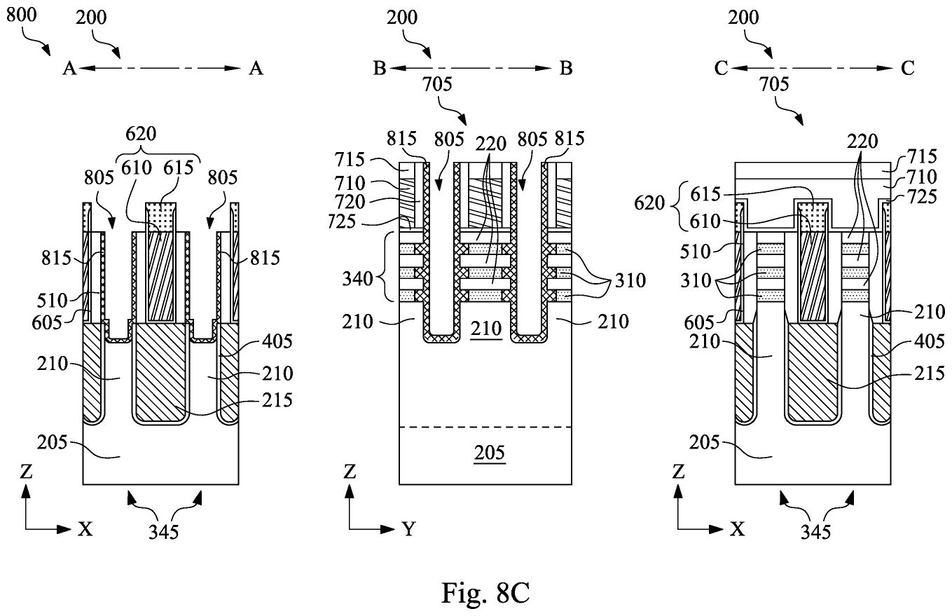

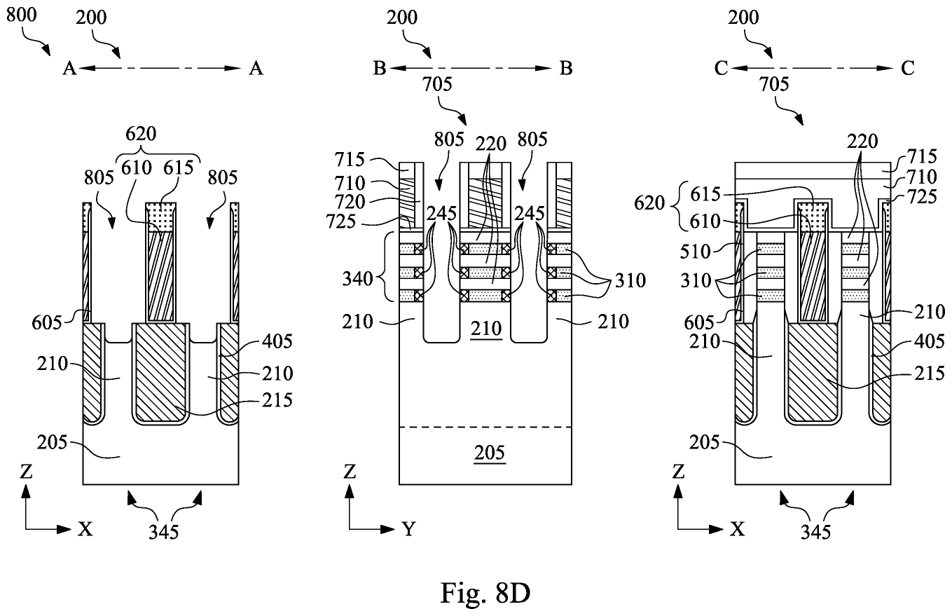

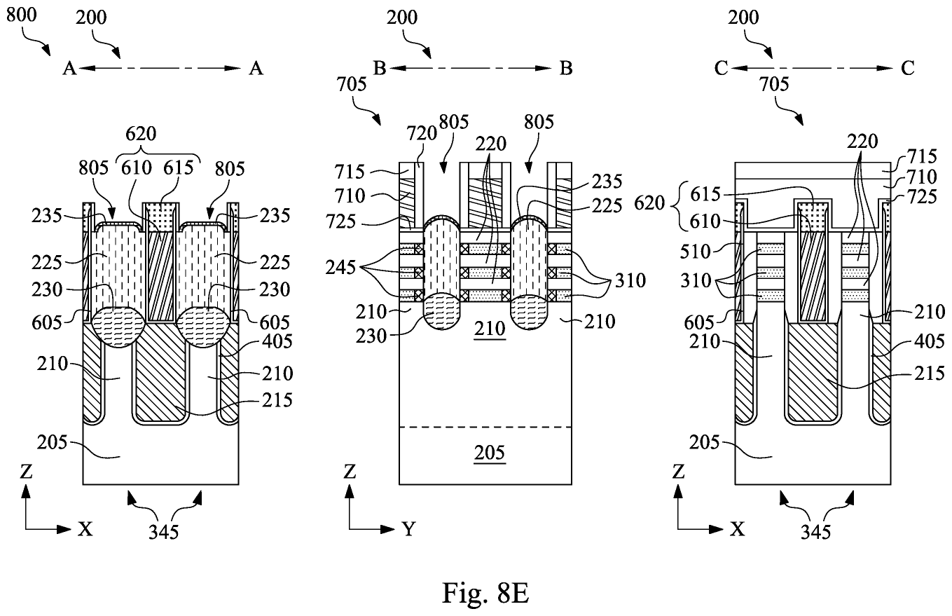

FIGS. 8A-8E are diagrams of an example implementation 800 of a source/drain region formation process described herein. The example implementation 800 includes an example of forming source/drain recesses and the inner spacers 245 for the semiconductor device 200. FIGS. 8A-8E are illustrated from a plurality of perspectives illustrated in FIG. 7A, including the perspective of the cross-sectional plane A-A in FIG. 7A, the perspective of the cross-sectional plane B-B in FIG. 7A, and the perspective of the cross-sectional plane C-C in FIG. 7A. In some implementations, the operations described in connection with the example implementation 800 are performed after the processes described in connection with FIGS. 3A-7B.

As shown in the cross-sectional plane A-A and cross-sectional plane B-B in FIG. 8A, source/drain recesses 805 are formed in the portions 340 of the fin structure 345 in an etch operation. The source/drain recesses 805 are formed to provide spaces in which source/drain regions 225 are to be formed on opposing sides of the dummy gate structures 705. The etch operation may be performed by the etch tool 108 and may be referred to a strained source/drain (SSD) etch operation. In some implementations, the etch operation includes a plasma etch technique, a wet chemical etch technique, and/or another type of etch technique.

The source/drain recesses 805 also extend into a portion of the mesa regions 210 of the fin structure 345. This results in the formation of a plurality of mesa regions 210 in each fin structure 345, where sidewalls of the portions of each source/drain recess 805 below the portions 340 correspond to sidewalls of mesa regions 210. The source/drain recesses 805 may penetrate into a well portion (e.g., a p-well, an n-well) of the fin structure 345. In implementations in which the semiconductor substrate 205 includes a silicon (Si) material having a (100) orientation, (111) faces are formed at bottoms of the source/drain recesses 805, resulting in formation of a V-shape or a triangular shape cross section at the bottoms of the source/drain recesses 805. In some implementations, a wet etching using tetramethylammonium hydroxide (TMAH) and/or a chemical dry etching using hydrochloric acid (HCl) are employed to form the V-shape profile. However, the cross section at the bottoms of the source/drain recesses 805 may include other shapes, such as round or semi-circular, among other examples.

As shown in the cross-sectional plane B-B and the cross-sectional plane C-C in FIG. 8A, portions of the first layers 310 and portions of the second layers 315 of the layer stack 305 remain under the dummy gate structures 705 after the etch operation to form the source/drain recesses 805. The portions of the second layers 315 under the dummy gate structures 705 form the nanostructure channels 220 of the nanostructure transistors of the semiconductor device 200. The nanostructure channels 220 extend between adjacent source/drain recesses 805 and between adjacent hybrid fin structures 620.

As shown in the cross-sectional plane B-B in FIG. 8B, the first layers 310 are laterally etched (e.g., in a direction that is approximately parallel to a length of the first layers 310) in an etch operation, thereby forming cavities 810 between portions of the nanostructure channels 220. In particular, the etch tool 108 laterally etches ends of the first layers 310 under the dummy gate structures 705 through the source/drain recesses 805 to form the cavities 810 between ends of the nanostructure channels 220. In implementations where the first layers 310 are silicon germanium (SiGe) and the second layers 315 are silicon (Si), the etch tool 108 may selectively etch the first layers 310 using a wet etchant such as, a mixed solution including hydrogen peroxide (H₂O₂), acetic acid (CH₃COOH), and/or hydrogen fluoride (HF), followed by cleaning with water (H₂O). The mixed solution and the water may be provided into the source/drain recesses 805 to etch the first layers 310 from the source/drain recesses 805. In some embodiments, the etching by the mixed solution and cleaning by water is repeated approximately 10 to approximately 20 times. The etching time by the mixed solution is in a range from about 1 minute to about 2 minutes in some implementations. The mixed solution may be used at a temperature in a range of approximately 600 Celsius to approximately 90° Celsius. However, other values for the parameters of the etch operation are within the scope of the present disclosure.

The cavities 810 may be formed to an approximately curved shape, an approximately concave shape, an approximately triangular shape, an approximately square shape, or to another shape. In some implementations, the depth of one or more of the cavities 810 (e.g., the dimension of the cavities extending into the first layers 310 from the source/drain recesses 805) is in a range of approximately 0.5 nanometers to about 5 nanometers. In some implementations, the depth of one or more of the cavities 810 is in a range of approximately 1 nanometer to approximately 3 nanometers. However, other values for the depth of the cavities 810 are within the scope of the present disclosure. In some implementations, the etch tool 108 forms the cavities 810 to a length (e.g., the dimension of the cavities extending from a nanostructure channel 220 below a first layer 310 to another nanostructure channel 220 above the first layer 310) such that the cavities 810 partially extend into the sides of the nanostructure channels 220 (e.g., such that the width or length of the cavities 810 are greater than the thickness of the first layers 310). In this way, the inner spacers that are to be formed in the cavities 810 may extend into a portion of the ends of the nanostructure channels 220. In some implementations, forming the cavities 810 results in thinning of the cladding sidewalls 510 in the source/drain recesses 805.

As shown in the cross-sectional plane A-A and in the cross-sectional plane B-B in FIG. 8C, an insulating layer 815 is conformally deposited along the bottom an along the sidewalls of the source/drain recesses 805. The insulating layer 815 further extends along the spacer layer 720. The deposition tool 102 may deposit the insulating layer 815 using a CVD technique, a PVD technique, and ALD technique, and/or another deposition technique. The insulating layer 815 includes a silicon nitride (SiₓN_{y}), a silicon oxide (SiOₓ), a silicon oxynitride (SiON), a silicon oxycarbide (SiOC), a silicon carbon nitride (SiCN), a silicon oxycarbonnitride (SiOCN), and/or another dielectric material. The insulating layer 815 may include a material that is different from the material of spacer layers 720.

The deposition tool 102 forms the insulating layer 815 to a thickness sufficient to fill in the cavities 810 between the nanostructure channels 220 with the insulating layer 815. For example, the insulating layer 815 may be formed to a thickness in a range of approximately 1 nanometer to approximately 10 nanometers. As another example, the insulating layer 815 may be formed to a thickness in a range of approximately 2 nanometers to approximately 5 nanometers. However, other values for the thickness of the insulating layer 815 are within the scope of the present disclosure.

As shown in the cross-sectional plane A-A and in the cross sectional plane B-B in FIG. 8D, the insulating layer 815 is partially removed such that remaining portions of the insulating layer 815 correspond to the inner spacers 245 in the cavities 810. The etch tool 108 may perform an etch operation to partially remove the insulating layer 815. As further shown in the cross-sectional plane A-A in FIG. 8D, the cladding sidewalls 510 may also be removed from the source/drain recesses 805 in the etch operation to partially remove the insulating layer 815.

In some implementations, the etch operation may result in the surfaces of the inner spacers 245 facing the source/drain recesses 805 being curved or recessed. The depth of the recesses in the inner spacers 245 may be in a range of approximately 0.2 nanometers to approximately 3 nanometers. As another example, the depth of the recesses in the inner spacers 245 may be in a range of approximately 0.5 nanometers to approximately 2 nanometers. As another example, the depth of the recesses in the inner spacers 245 may be in a range of less than approximately 0.5 nanometers. In some implementations, the surfaces of the inner spacers 245 facing the source/drain recesses 805 are approximately flat such that the surfaces of the inner spacers 245 and the surfaces of the ends of the nanostructure channels 220 are approximately even and flush.

As shown in the cross-sectional plane A-A and the cross-sectional plane B-B in FIG. 8E, the source/drain recesses 805 are filled with one or more layers to form the source/drain regions 225 in the source/drain recesses 805. For example, the deposition tool 102 may deposit a buffer region 230 at the bottom of the source/drain recesses 805, the deposition tool 102 may deposit the source/drain regions 225 on the buffer region 230, and the deposition tool 102 may deposit a capping layer 235 on the source/drain regions 225. The buffer region 230 may include silicon (Si), silicon doped with boron (SiB) or another dopant, and/or another material. The buffer region 230 may be included to reduce, minimize, and/or prevent dopant migration and/or current leakage from the source/drain regions 225 into the adjacent mesa regions 210, which might otherwise cause short channel effects in the semiconductor device 200. Accordingly, the buffer region 230 may increase the performance of the semiconductor device 200 and/or increase yield of the semiconductor device 200.

The source/drain regions 225 may include one or more layers of epitaxially grown material. For example, the deposition tool 102 may epitaxially grow a first layer of the source/drain regions 225 (referred to as an L1) over the buffer region 230, and may epitaxially grow a second layer of the source/drain regions 225 (referred to as an L2, an L2-1, and/or an L2-2) over the first layer. The first layer may include a lightly doped silicon (e.g., doped with boron (B), phosphorous (P), and/or another dopant), and may be included as shielding layer to reduce short channel effects in the semiconductor device 200 and to reduce dopant extrusion or migration into the nanostructure channels 220. The second layer may include a highly doped silicon or highly doped silicon germanium. The second layer may be included to provide a compressive stress in the source/drain regions 225 to reduce boron loss.

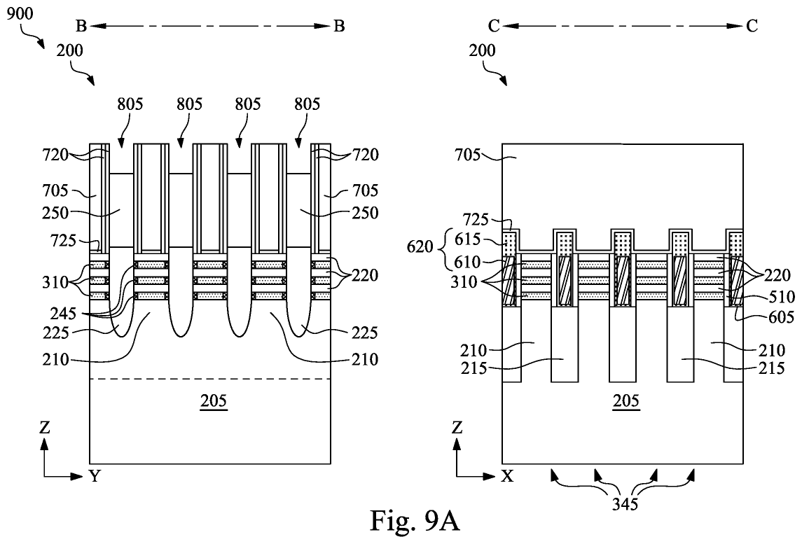

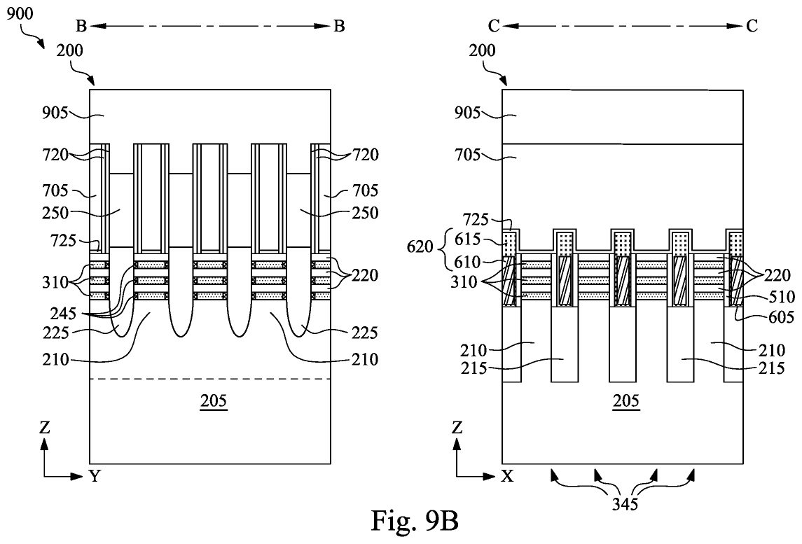

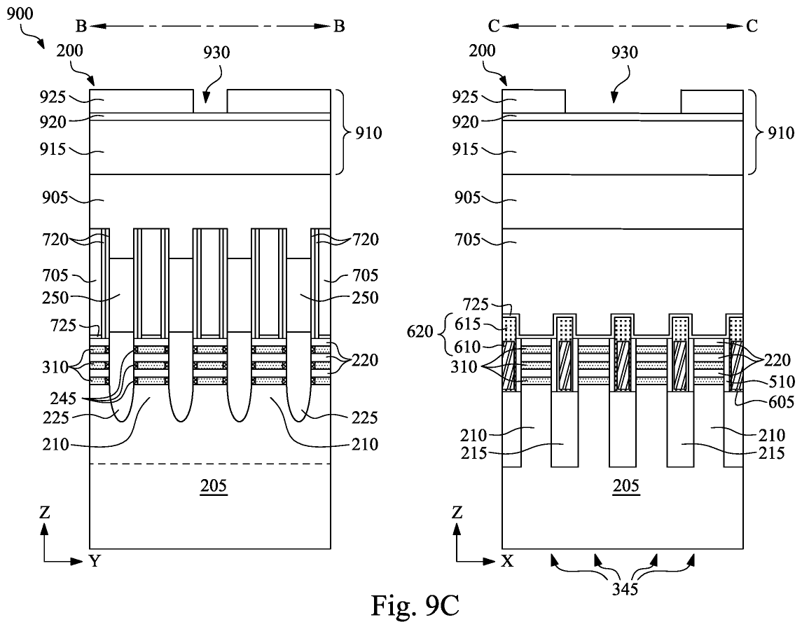

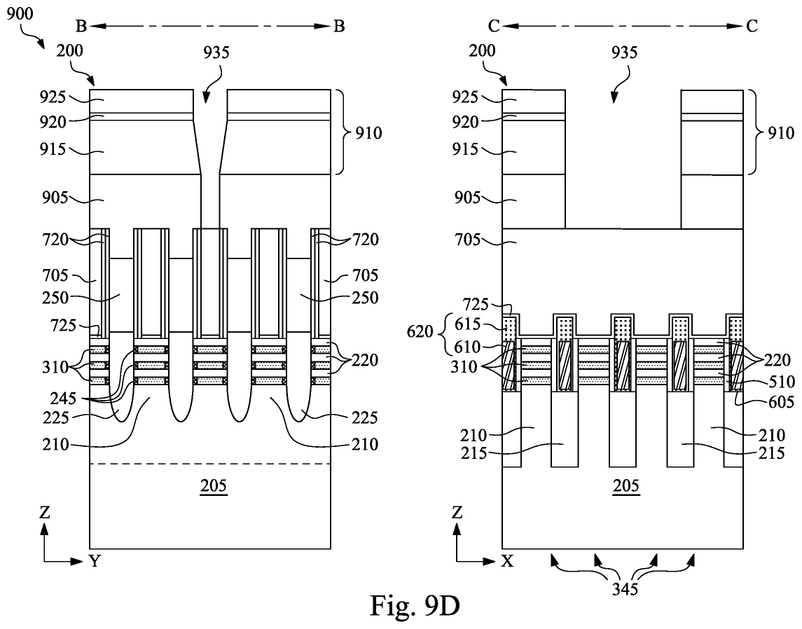

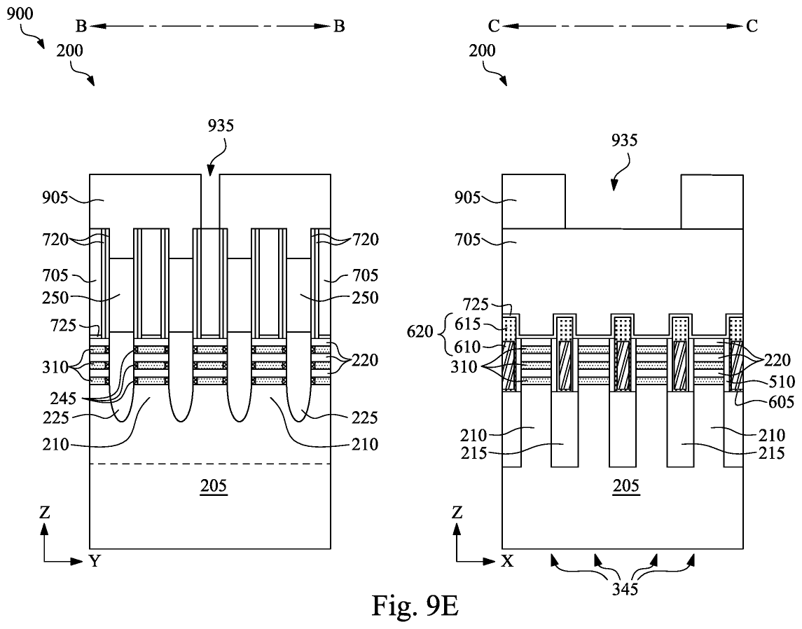

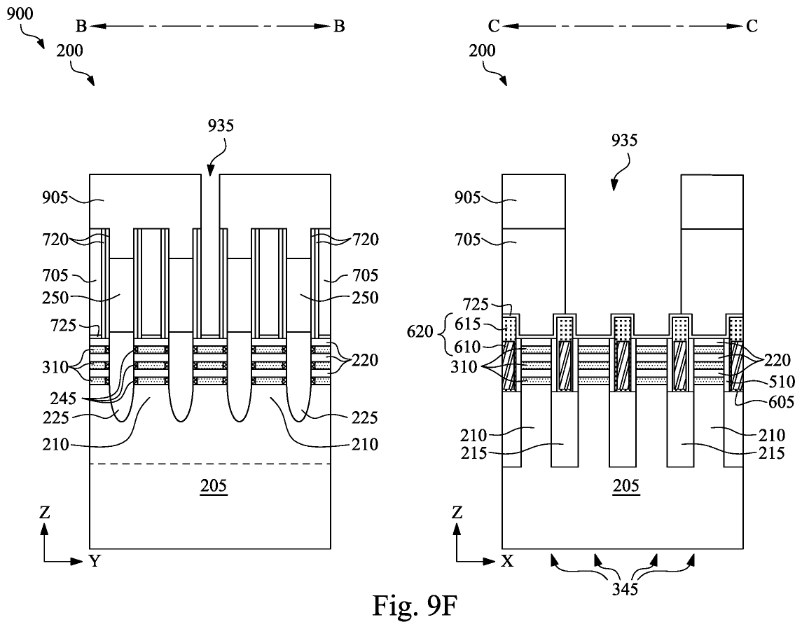

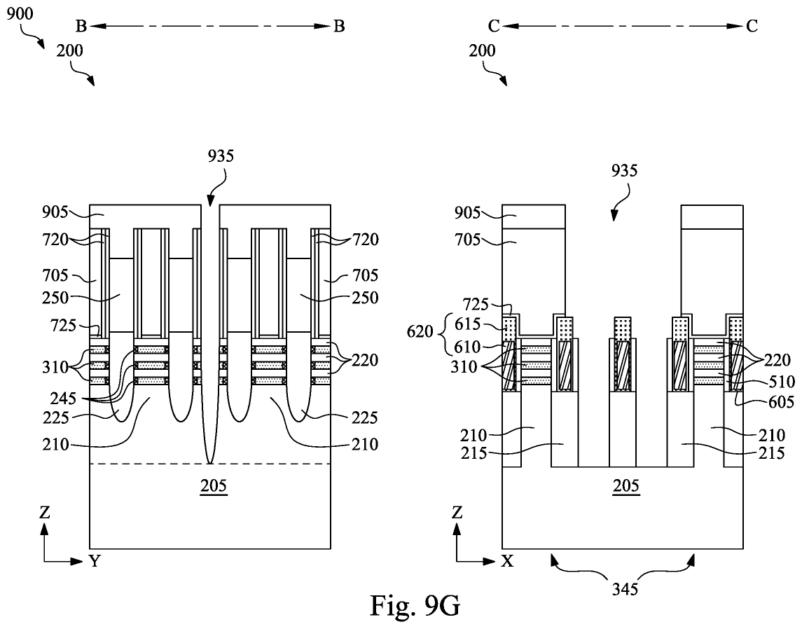

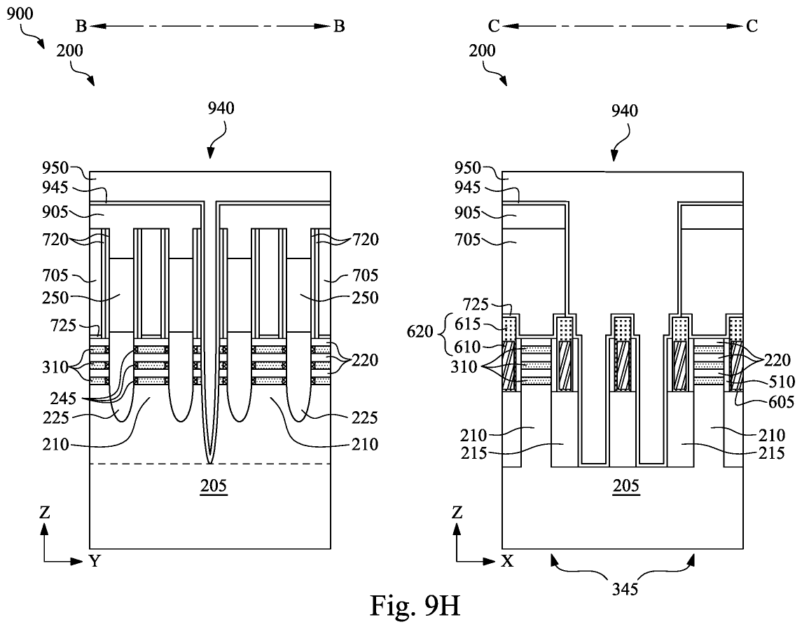

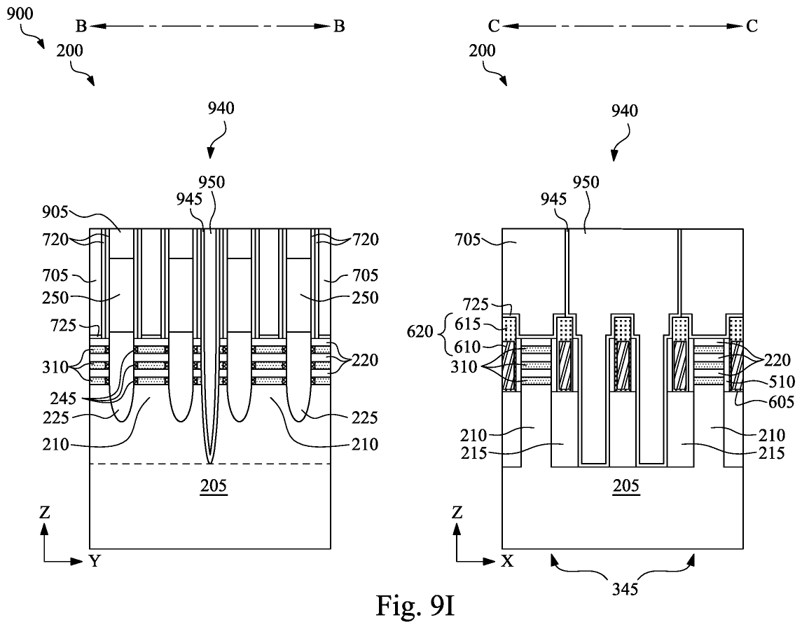

As further shown in FIG. 8E, the hybrid fin structures 620 are formed such that the hybrid fin structures 620 extend above the tops of the source/drain regions 225. In particular, the top surface of the high-k dielectric layers 615 of the hybrid fin structures 620 may be located at a greater height in the semiconductor device 200 than the tops of the source/drain regions. In some implementations, the bottom surface of the high-k dielectric layers 615 of the hybrid fin structures 620 may also be located at a greater height in the semiconductor device 200 than the tops of the source/drain regions 225. As described in greater detail in connection with FIG. 9G, the greater height of the hybrid fin structures 620 may reduce bowing of active region isolation recesses formed in between adjacent source/drain regions 225. Accordingly, the greater height of the hybrid fin structures 620 may reduce critical dimension loading and/or may reduce EPI damage to the source/drain region 225 on opposing sides of the active region isolation recess.

As indicated above, FIGS. 8A-8E are provided as examples. Other examples may differ from what is described with regard to FIGS. 8A-8E. Example implementation 800 may include additional operations, fewer operations, different operations, and/or a different order of operations than those described in connection with FIGS. 8A-8E.

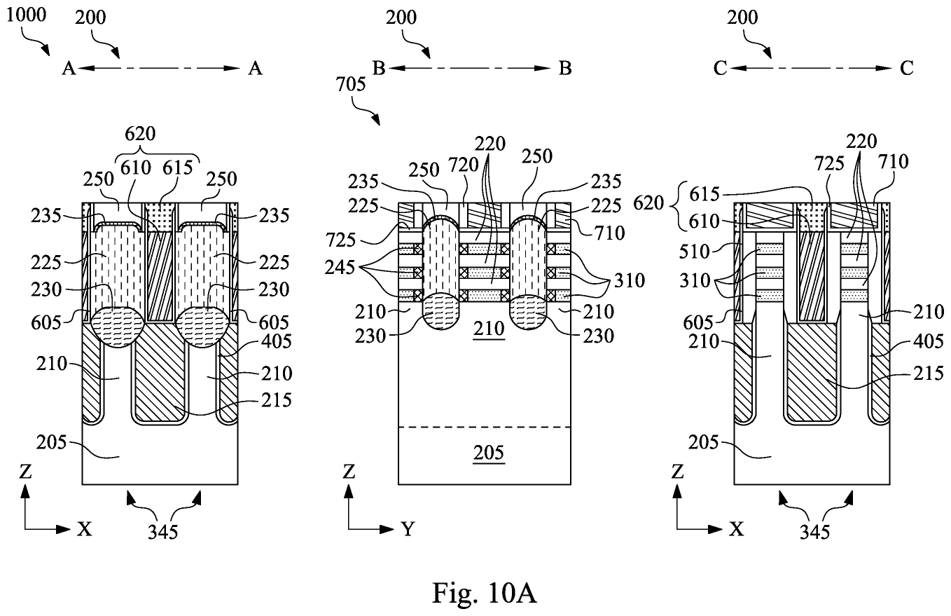

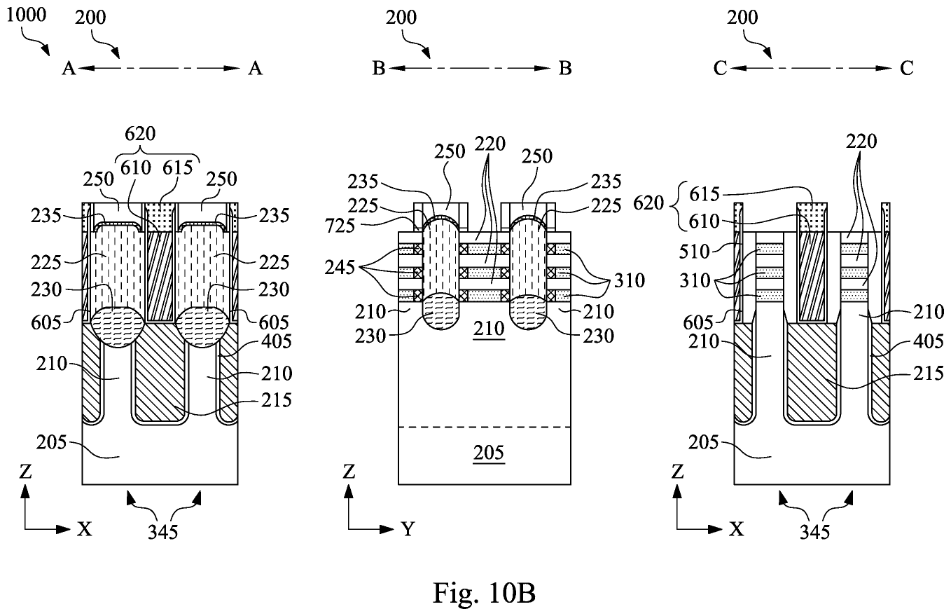

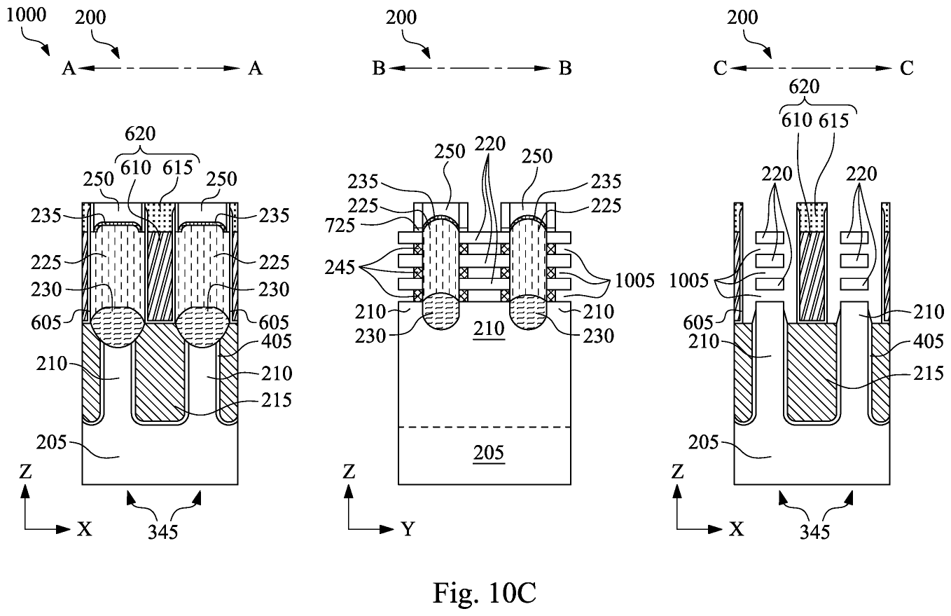

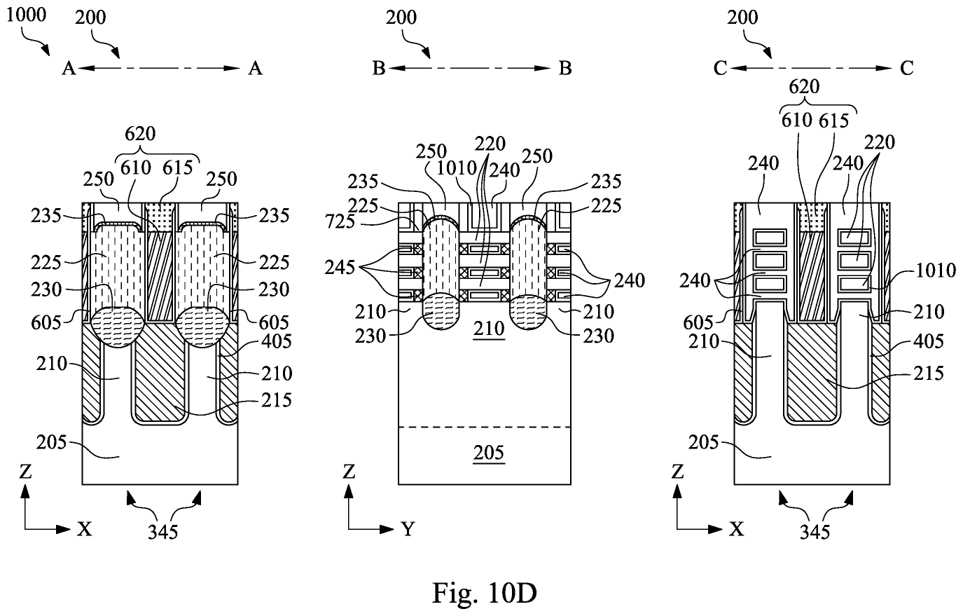

FIGS. 9A-9I are diagrams of an example implementation 900 of an active region isolation structure formation process described herein. The example implementation 900 includes an example of forming the active region isolation structure (e.g., a CPODE structure) in the semiconductor device 200 prior to the replacement gate process (which is described in connection with FIGS. 10A-10D) to replace the dummy gate structures 705 with the gate structures 240 (metal gate structures) of the semiconductor device 200. Therefore, the example implementation 900 may be referred to as a front end of line (FEOL) CPODE process. The active region isolation structure may be formed along a dummy gate structure 705 to create a region of electrical isolation in one or more mesa regions 210 and/or one or more stacks of nanostructure channels 220 under the gate structure 240. Thus, the active region isolation structure enables an underlying nanostructure channel 220 to be separated into multiple (electrically isolated) nanostructure channels 220.

FIGS. 9A-9I are illustrated from a plurality of perspectives illustrated in FIG. 7A, including the perspective of the cross-sectional plane A-A in FIG. 7A, the perspective of the cross-sectional plane B-B in FIG. 7A, and the perspective of the cross-sectional plane C-C in FIG. 7A. In some implementations, the operations described in connection with the example implementation 900 are performed after the operations described in connection with FIGS. 3A-8E. As shown in FIG. 9A, the FEOL CPODE process may be performed of the source/drain region formation process described in connection with FIGS. 8A-8E.

As shown in FIG. 9B, a hard mask layer 905 may be formed over and/or on the semiconductor device 200. The hard mask layer 905 may be formed to enable a pattern to be used to etch the dummy gate structure 705 to form a recess in which the active region isolation structure is to be formed. The hard mask layer 905 may include a dielectric material such as a silicon oxide (SiOₓ such as SiO₂), a silicon nitride (SiₓN_{y} such as a Si₃N₄), a silicon oxynitride (SiON), fluoride-doped silicate glass (FSG), a high-k dielectric material, and/or another suitable dielectric material. A deposition tool 102 may be used to deposit the hard mask layer 905 using a PVD technique, an ALD technique, a CVD technique, an oxidation technique, another type of deposition technique described in connection with FIG. 1, and/or another suitable deposition technique. In some implementations, the planarization tool 110 may be used to planarize the hard mask layer 905 after the hard mask layer 905 is deposited.

As shown in FIG. 9C, a patterning stack 910 may be formed over and/or on the hard mask layer 905. The patterning stack 910 may be used to pattern the hard mask layer 905 for forming an active region isolation recess through the dummy gate structure 705. The patterning stack 910 may include one or more masking layers, such as a bottom layer 915, a middle layer 920, and a top layer 925. The bottom layer 915 may include a carbon-containing material and/or another suitable material. The middle layer 920 may include an oxide-containing material and/or another suitable material. The top layer 925 may include a photoresist layer that is used to transfer a pattern 930 to the bottom layer 915 and middle layer 920. The different materials of the bottom layer 915 and middle layer 920 provide etch selectivity between the bottom layer 915 and middle layer 920, which enables the aspect ratio of the pattern 930 to be tightly controlled.

A deposition tool 102 may be used to deposit the bottom layer 915 and the middle layer 920 using a PVD technique, an ALD technique, a CVD technique, an oxidation technique, another type of deposition technique described in connection with FIG. 1, and/or another suitable deposition technique. In some implementations, the planarization tool 110 may be used to planarize the bottom layer 915 and/or the middle layer 920 after the bottom layer 915 and/or the middle layer 920 are deposited. A deposition tool 102 may be used to deposit the top layer 1135 using a spin coating technique and/or another suitable deposition technique.

As further shown in FIG. 9C, the pattern 930 may be formed in the top layer 925. In some implementations, a wet cleaning operation may be performed prior to forming the pattern 930. The pattern 930 may be formed using an exposure tool 104 to expose the top layer 925 to a radiation source to form the pattern 930, and a developer tool 106 to develop and remove portions of the top layer 925 to expose the pattern 930. The pattern 930 may be formed above a portion of the dummy gate structure 705.

As shown in FIG. 9D, the pattern 930 is transferred to the bottom layer 915 and the middle layer 920 of the patterning stack 910. An etch tool 108 may be used to etch the bottom layer 915 and the middle layer 920 based on the pattern 930 in the top layer 925 to transfer the pattern 930 to the bottom layer 915 and the middle layer 920. In some implementations, the etch operation includes dry etch (e.g., a plasma etch operation). In some implementations, the etch operation includes another type of etch operation such as a wet chemical etch operation.

As further shown in FIG. 9D, the pattern 930 in the bottom layer 915 and the middle layer 920 may be used to form an active region isolation recess 935 (e.g., a CPODE recess) in the hard mask layer 905. An etch tool 108 may be used to etch the hard mask layer 905 based on the pattern 930 in the bottom layer 915 and the middle layer 920 to form the active region isolation recess 935. In some implementations, the etch operation includes dry etch (e.g., a plasma etch operation). In some implementations, the etch operation includes another type of etch operation such as a wet chemical etch operation. The etch may stop on the dummy gate structure 705.

As shown in FIG. 9E, a photoresist removal tool may be used to remove the remaining portions of the patterning stack 910 (e.g., using a chemical stripper, plasma ashing, and/or another technique) after the active region isolation recess 935 is formed. In some implementations, a wet cleaning operation may be performed after the active region isolation recess 935 is formed.

As shown in FIG. 9F, the dummy gate structure 705 may be etched to extend the active region isolation recess 935 down to the STI regions 215 under the dummy gate structure 705. The etch may stop on the gate dielectric layer 725. The etch operation may expose the high-k dielectric layers 610 of the hybrid fin structures 620 through the active region isolation recess 935. An etch tool 108 may be used to etch the dummy gate structure 705. In some implementations, the etch operation includes dry etch (e.g., a plasma etch operation). In some implementations, the etch operation includes another type of etch operation such as a wet chemical etch operation.

As shown in FIG. 9G, the nanostructure channels 220 and first layers 310 (e.g., sacrificial silicon germanium (SiGe) layers) between adjacent source/drain regions 225 on opposing sides of the active region isolation recess 935 may be removed after the dummy gate structure 705 is etched. Moreover, the mesa regions 210 under the nanostructure channels 220 may be removed through the active region isolation recess 935. The STI regions 215 that are located under the hybrid fin structures 620 exposed in the active region isolation recess 935 may remain, along with the dielectric layers 610 of the hybrid fin structures 620 and the cladding sidewalls 510 exposed in the active region isolation recess 935.

The active region isolation recess 935 extends below the source/drain regions 255 into areas previously occupied by the mesa regions 210 that were removed. In some implementations, the bottom surface of the active region isolation recess 935 may be co-planar with the bottom surface of the STI regions 215. In some implementations, the bottom surface of the active region isolation recess 935 may extend below the bottom surface of the STI regions 215.

In some implementations, a remotely coupled plasma (RCP) is used in the etch tool 108 to remove the mesa regions 210, the nanostructure channels 220, and the first layers 310. The plasma may be a hydrogen bromide (HBr) based plasma etchant and/or another plasma based etchant with oxygen (O₂) and/or carbon dioxide (CO₂) added. The plasma may be generated using an inductively coupled plasma (ICP) generator, a resonant antenna plasma source driven by a radio frequency (RF) power generator, and/or another type of plasma based etch tool. A frequency of a multiple of 13.56 megahertz (MHz) (e.g., 13.56 MHz, 27 MHz) may be used for the RF power generator. The RF power generator may be operated to provide a source power that is included in a range of approximately 100 watts to approximately 2500 watts. However, other values for the range are within the scope of the present disclosure. In some implementations, a pulse plasma etch may be performed with a duty cycle that is included in a range of approximately 10% to approximately 100%. However, other values for the range are within the scope of the present disclosure. An RF bias power to a pedestal in the process chamber of the etch tool 108 may be included in a range of approximately 10 watts to approximately 2000 watts. However, other values for the range are within the scope of the present disclosure. The process chamber of the etch tool 108 may be operated at a pressure that is included in a range of approximately 3 milliTorr (mTorr) to approximately 150 mTorr. However, other values for the range are within the scope of the present disclosure. The process chamber of the etch tool 108 may be operated at a temperature that is included in a range of approximately 20 degrees Celsius to approximately 150 degrees Celsius. However, other values for the range are within the scope of the present disclosure.

In some implementations, one or more methane (CH₄)-based deposition operations may be performed to protect the hard mask layer 905 during etch operation to remove the mesa regions 210, the nanostructure channels 220, and the first layers 310. Passivation operations, such as silicon tetrachloride (SiCl₄) passivation and/or oxygen (O₂) passivation, may be performed to form a passivation layer to reduce the likelihood of and/or magnitude of etching of layers and/or structures other than the mesa regions 210, the nanostructure channels 220, and the first layers 310. After the passivation operations, a break-through operation utilizing tetrafluoromethane (CF₄), trifluoromethane (CHF₃), difluoromethane (CH₂F₂), and/or hexafluorobutadine (C₄F₆) may be performed to remove the passivation layer from the bottom surface of the active region isolation recess 935 to enable further etching of the active region isolation recess 935.

The hybrid fin structures 620 extending above the top surface of the source/drain regions 225 may reduce bowing of the active region isolation recess 935. Accordingly, removal of the hybrid fin structures 620 extending above the top surface of the source/drain regions 225 may reduce critical dimension loading and/or may reduce EPI damage to the source/drain region 225 on opposing sides of the active region isolation recess 935. In particular, hybrid fin structures 620 extending above the top surface of the source/drain regions 225 results in the width of the active region isolation recess 935 reducing at a height in the semiconductor device 200 that is greater than the height of the top surfaces of the source/drain regions 225. As shown in the cross-sectional plane C-C in FIG. 9G, the width of the active region isolation recess 935 reduces at the high-k dielectric layers 615 of the hybrid fin structures 620. Thus, the density of etchant flux (e.g., ions and radicals in the etchant) in the active region isolation recess 935, and the pressure in the active region isolation recess 935, increases at the height of the high-k dielectric layers 615 in the active region isolation recess 935. The increase in the density of etchant flux and the increase in the pressure might otherwise result in an increase etch rate at the width reduction in the active region isolation recess 935, particularly if the width reduction occurred at the height of the source/drain regions 225 (which would otherwise occur if the hybrid fin structures 620 were lower in the semiconductor device 200 than the source/drain regions 225) However, the high-k dielectric layers 615 are able to withstand the increased density of etchant flux and the increase in the pressure because the high-k dielectric materials of the high-k dielectric layers 615. In particular, high-k dielectric materials of the high-k dielectric layers 615 are able to withstand etching because the etchant that is used to etch the mesa regions 210, the first layers 310, and the nanostructure channels 220 is selected to etch silicon (or silicon-containing materials) and may not be effective in etching the high-k dielectric materials of the high-k dielectric layers 615 of the hybrid fin structures 620. Accordingly, the hybrid fin structures 620 extending above the top surface of the source/drain regions 225 enables the hybrid fin structures 620 to protect the source/drain regions 225 from etching (which may also be formed of silicon-containing materials), which may reduce critical dimension loading and/or may reduce EPI damage to the source/drain region 225

As shown in FIG. 9H, an active region isolation structure 940 may be formed in the active region isolation recess 935. In particular, the active region isolation structure 940 may be formed over the STI regions 215 and over the hybrid fin structures 620 that are exposed in the active region isolation recess 935.

Forming the active region isolation structure 940 may include forming a dielectric liner 945 of the active region isolation structure 940 in the active region isolation recess 935, and filling the remaining volume in the active region isolation recess 935 with a dielectric layer 950 on the dielectric liner 945. The dielectric liner 945 may be conformally deposited on the sidewalls of the active region isolation recess 935 (corresponding to sidewalls of the STI regions 215, the dielectric layers 610 of the hybrid fin structures 620, the high-k dielectric layers 615 of the hybrid fin structures 620, and the dummy gate structure 705 that are exposed in the active region isolation recess 935). The dielectric liner 945 may also be conformally deposited on bottom surfaces of the active region isolation recess 935 corresponding to the semiconductor substrate 205. A deposition tool 102 may be used to deposit the dielectric liner 945 using a PVD technique, an ALD technique, a CVD technique, an oxidation technique, another type of deposition technique described in connection with FIG. 1, and/or another suitable deposition technique. The dielectric liner 945 may include a dielectric material such as a silicon oxide (SiOₓ such as SiO₂), a silicon nitride (SiₓN_{y} such as a Si₃N₄), a silicon oxynitride (SiON), fluoride-doped silicate glass (FSG), a high-k dielectric material, and/or another suitable dielectric material.

The active region isolation recess 935 may be over-filled with the dielectric layer 950 to ensure that the active region isolation recess 935 is fully filled with the dielectric layer 950 and to minimize the formation of gaps or voids in the active region isolation structure 940. A deposition tool 102 may be used to deposit the dielectric layer 950 using a PVD technique, an ALD technique, a CVD technique, an oxidation technique, another type of deposition technique described in connection with FIG. 1, and/or another suitable deposition technique. The dielectric layer 950 may include a dielectric material such as a silicon oxide (SiOₓ such as SiO₂), a silicon nitride (SiₓN_{y} such as a Si₃N₄), a silicon oxynitride (SiON), fluoride-doped silicate glass (FSG), a high-k dielectric material, and/or another suitable dielectric material.

As shown in FIG. 9I, a planarization operation may be performed to planarize the semiconductor device 200 after the layers of the active region isolation structure 940 are formed. A planarization tool 110 may be used to planarize the semiconductor device 200 to remove the hard mask layer 905 (except for portions of the hard mask layer 905 below the top surfaces of the dummy gate structures 705), to remove excess material of the dielectric liner 945, and/or to remove excess material of the dielectric layer 950.

As indicated above, FIGS. 9A-9I are provided as an example. Other examples may differ from what is described with regard to FIGS. 9A-9I. Example implementation 900 may include additional operations, fewer operations, different operations, and/or a different order of operations than those described in connection with FIGS. 9A-9I.

FIGS. 10A-10D are diagrams of an example implementation 1000 of a replacement gate (RPG) process described herein. The example implementation 1000 includes an example of a replacement gate process for replacing the dummy gate structures 705 with the gate structures 240 (e.g., the replacement gate structures) of the semiconductor device 200. FIGS. 10A-10D are illustrated from a plurality of perspectives illustrated in FIG. 7A, including the perspective of the cross-sectional plane A-A in FIG. 7A, the perspective of the cross-sectional plane B-B in FIG. 7A, and the perspective of the cross-sectional plane C-C in FIG. 7A. In some implementations, the operations described in connection with the example implementation 1000 are performed after the operations described in connection with FIGS. 3A-9.

As shown in the cross-sectional plane A-A and the cross-sectional plane B-B in FIG. 10A, the ILD layer 250 is formed over the source/drain regions 225. The ILD layer 250 fills in areas between the dummy gate structures 705, between the hybrid fin structures 620, and over the source/drain regions 225. The ILD layer 250 is formed to reduce the likelihood of and/or prevent damage to the source/drain regions 225 during the replacement gate process. The ILD layer 250 may be referred to as an ILD zero (ILD0) layer or another ILD layer.

In some implementations, a contact etch stop layer (CESL) is conformally deposited (e.g., by the deposition tool 102) over the source/drain regions 225, over the dummy gate structures 705, and on the spacer layers 720 prior to formation of the ILD layer 250. The ILD layer 250 is then formed on the CESL. The CESL may provide a mechanism to stop an etch process when forming contacts or vias for the source/drain regions 225. The CESL may be formed of a dielectric material having a different etch selectivity from adjacent layers or components. The CESL may include or may be a nitrogen containing material, a silicon containing material, and/or a carbon containing material. Furthermore, the CESL may include or may be silicon nitride (SiₓN_{y}), silicon carbon nitride (SiCN), carbon nitride (CN), silicon oxynitride (SiON), silicon carbon oxide (SiCO), or a combination thereof, among other examples. The CESL may be deposited using a deposition process, such as ALD, CVD, or another deposition technique.

As shown in the cross-sectional plane B-B and the cross-sectional plane C-C in FIG. 10B, the replacement gate operation is performed (e.g., by one or more of the semiconductor processing tools 102-112) to remove the dummy gate structures 705 from the semiconductor device 200. The removal of the dummy gate structures 705 leaves behind openings (or recesses) 1005 between the ILD layer 250 over the source/drain regions 225, and between the hybrid fin structures 620. The dummy gate structures 705 may be removed in one or more etch operations. Such etch operations may include a plasma etch technique, a wet chemical etch technique, and/or another type of etch technique.

As shown in the cross-sectional plane B-B and the cross-sectional plane C-C in FIG. 10C, a nanostructure release operation (e.g., an SiGe release operation) is performed to remove the first layers 310 (e.g., the silicon germanium layers). This results in openings 1005 between the nanostructures channels 220 (e.g., the areas around the nanostructure channels 220). The nanostructure release operation may include the etch tool 108 performing an etch operation to remove the first layer 310 based on a difference in etch selectivity between the material of the first layers 310 and the material of the nanostructure channels 220, and between the material of the first layers 310 and the material of the inner spacers 245. The inner spacers 245 may function as etch stop layers in the etch operation to protect the source/drain regions 225 from being etched. As further shown in FIG. 10C, the cladding sidewalls 510 are removed in the nanostructure release operation. This provides access to the areas around the nanostructure channels 220, which enables replacement gate structures (e.g., the gate structures 240) to be formed fully around the nanostructure channels 220.

As shown in the cross-sectional plan B-B and the cross-sectional plane C-C in FIG. 10D, the replacement gate operation continues where deposition tool 102 and/or the plating tool 112 forms the gate structures (e.g., replacement gate structures) 240 in the openings 1005 between the source/drain regions 225 and between the hybrid fin structures 620. In particular, the gate structures 240 fill the areas between and around the nanostructure channels 220 that were previously occupied by the first layers 310 and the cladding sidewalls 510 such that the gate structures 240 fully wrap around the nanostructure channels 220 and surround the nanostructure channels 220. The gate structures 240 may include metal gate structures. A conformal high-k dielectric liner 1010 may be deposited onto the nanostructure channels 220 and on sidewalls prior to formation of the gate structures 240. The high-k dielectric liner 1010 may be a gate dielectric layer between the gate structures 240 and the nanostructure channels 220. The gate structures 240 may include additional layers such as an interfacial layer, a work function tuning layer, and/or a metal electrode structure, among other examples.

As further shown in the cross-sectional plane C-C in FIG. 10D, the removal of the cladding layer 505 from the tops of the STI regions 215 to prevent the cladding sidewalls 510 from including footings under the hybrid fin structures 620 between adjacent mesa regions 210 enables the gate structures 240 to be formed such that the gate structure 240 does not include a footing under the hybrid fin structures 620. In other words, since the gate structures 240 are formed in the areas that were previously occupied by the cladding sidewalls 510, the absence of a footing under the hybrid fin structures 620 for the cladding sidewalls 510 also results in an absence of a footing under the hybrid fin structures 620 for the gate structures 240. This reduces and/or prevents shorting between the gate structures 240 and the source/drain regions 225 under the hybrid fin structures.

As indicated above, the number and arrangement of operations and devices shown in FIGS. 10A-10D are provided as one or more examples. In practice, there may be additional operations and devices, fewer operations and devices, different operations and devices, or differently arranged operations and devices than those shown in FIGS. 10A-10D.

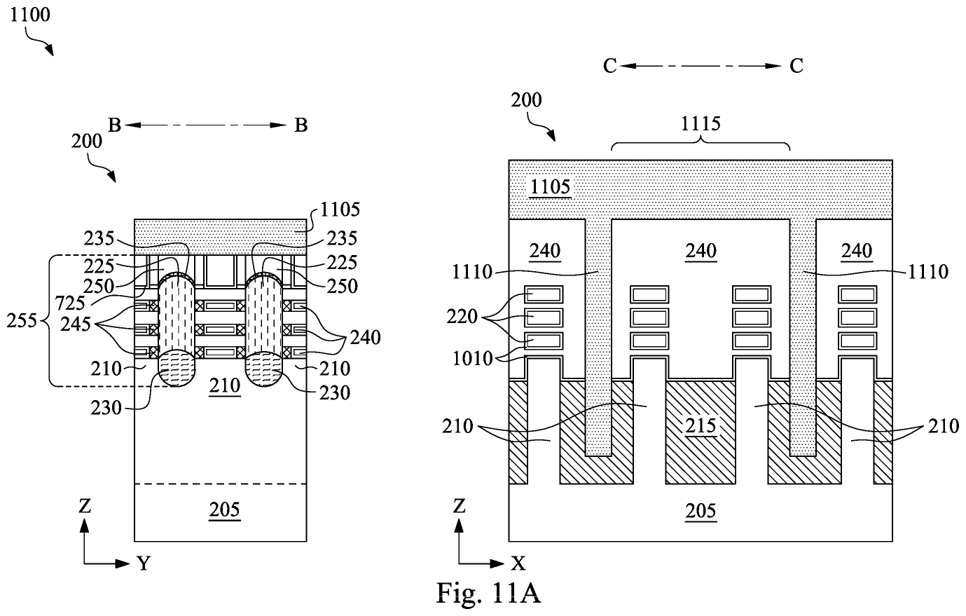

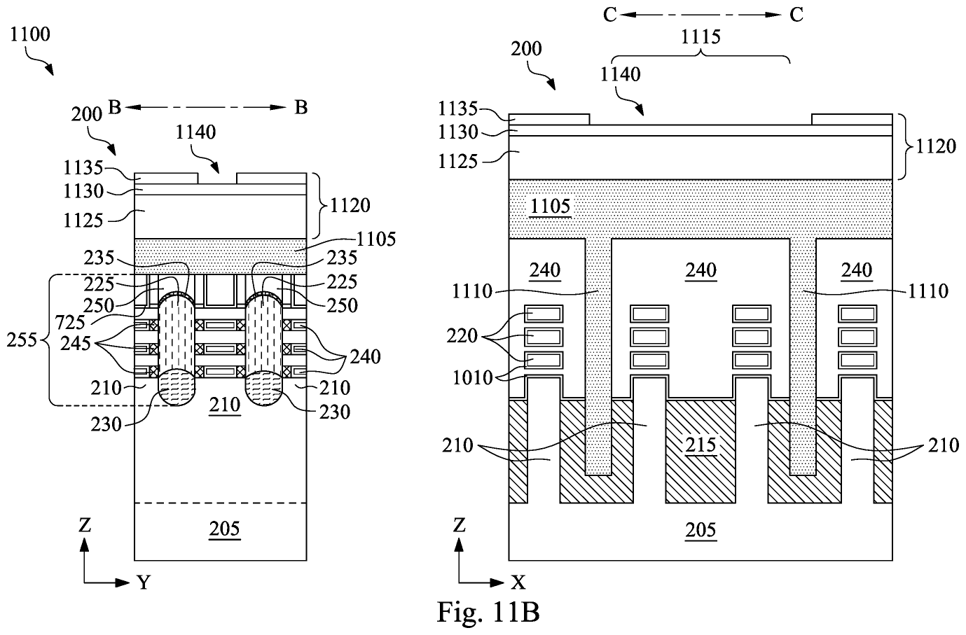

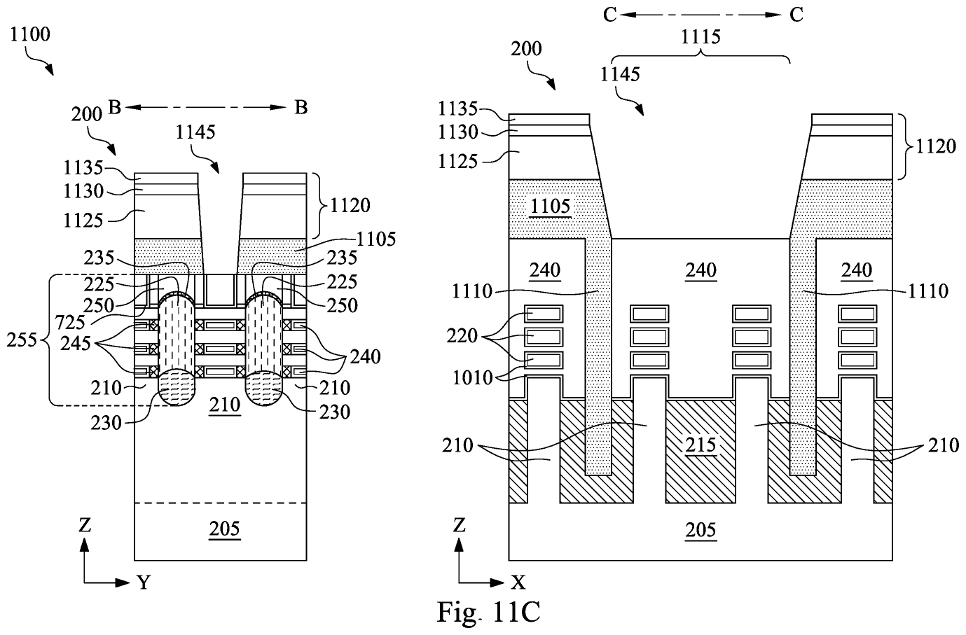

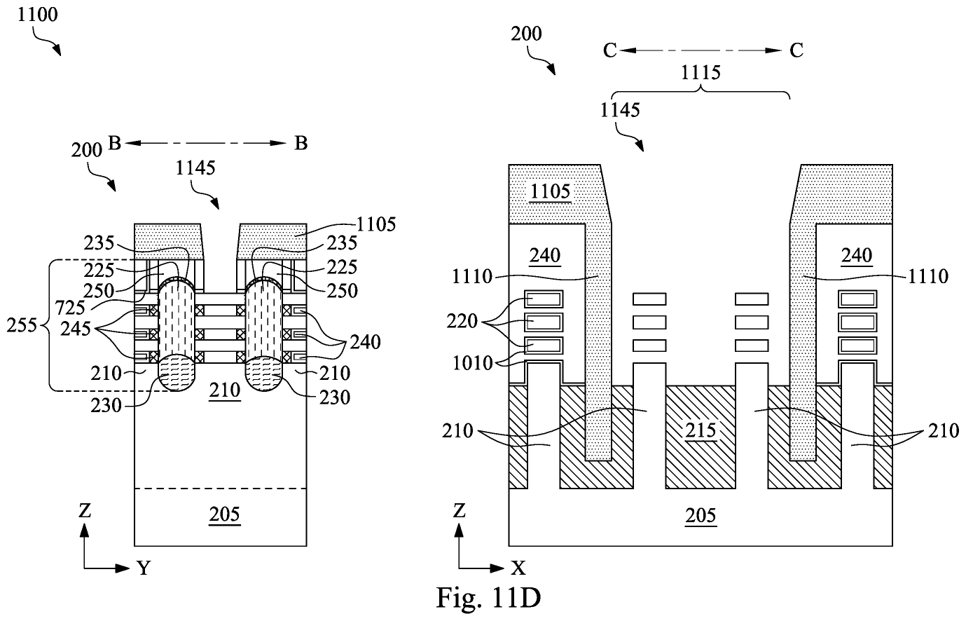

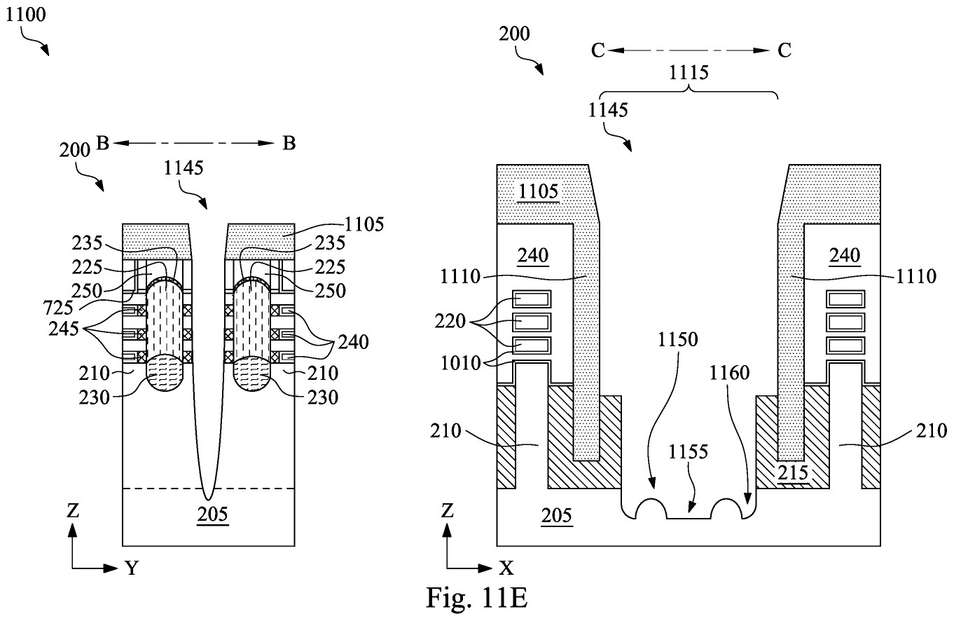

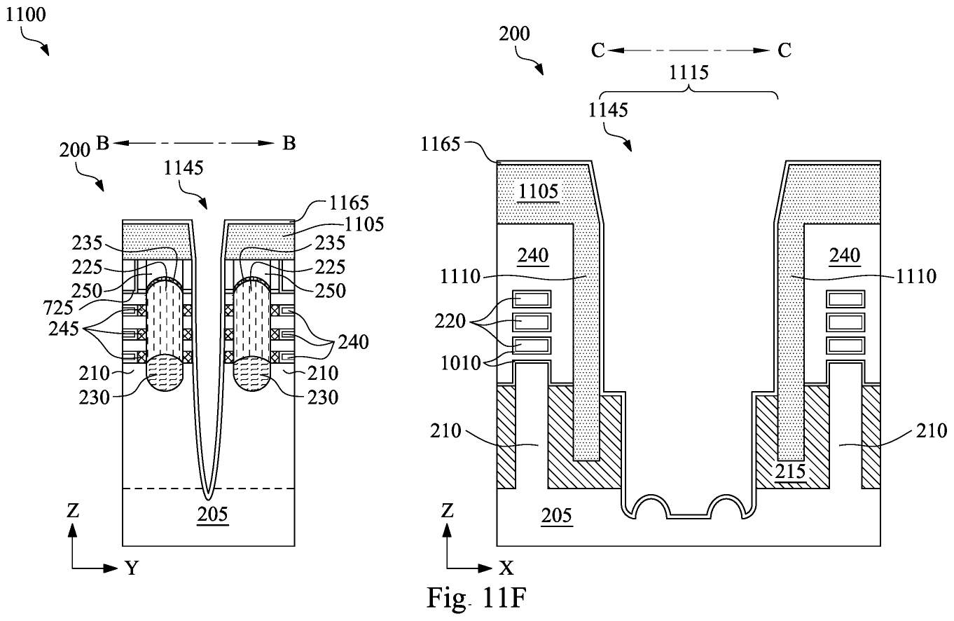

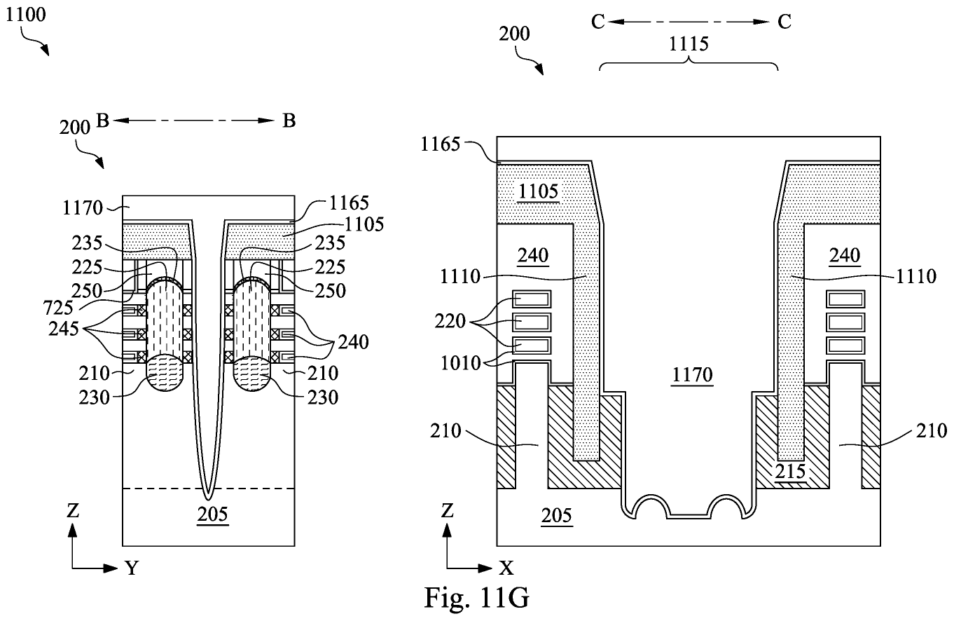

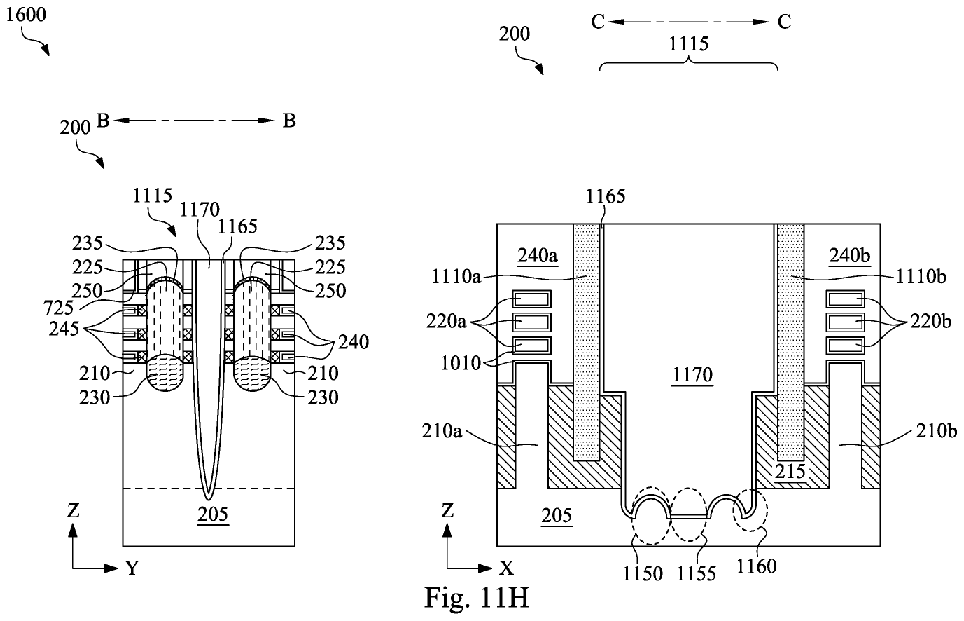

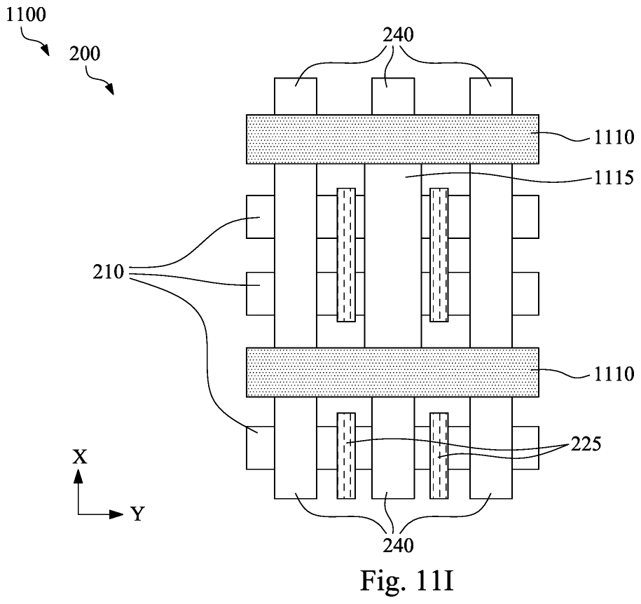

FIGS. 11A-11I are diagrams of an example implementation 1100 of forming an active region isolation structure described herein. The example implementation 1100 includes an example of forming the active region isolation structure (e.g., a CPODE structure) in the semiconductor device 200 after the replacement gate process to replace the dummy gate structures 705 with the gate structures 240 (metal gate structures) of the semiconductor device 200. Therefore, the example implementation 1100 may be referred to as an MEOL CPODE process. The active region isolation structure may be formed along a gate structure 240 to create a region of electrical isolation in one or more mesa regions 210 and/or one or more stacks of nanostructure channels 220 under the gate structure 240. Thus, the active region isolation structure enables an underlying nanostructure channel 220 to be separated into multiple (electrically isolated) nanostructure channels 220.

FIGS. 11A-11I are illustrated from a plurality of perspectives illustrated in FIG. 7A, including the perspective of the cross-sectional plane B-B in FIG. 7A (e.g., across a plurality of gate structures 240) and the perspective of the cross-sectional plane C-C in FIG. 7A (e.g., along a gate structure 240). In some implementations, the operations described in connection with the example implementation 1100 are performed after the operations described in connection with FIGS. 3A-10D.

As shown in FIG. 11A, a hard mask layer 1105 may be formed over and/or on the semiconductor device 200. The hard mask layer 1105 may be formed to enable a pattern to be used to etch the gate structure 240 to form a recess in which the active region isolation structure is to be formed. The hard mask layer 1105 may include a dielectric material such as a silicon oxide (SiOₓ such as SiO₂), a silicon nitride (SiₓN_{y} such as a Si₃N₄), a silicon oxynitride (SiON), fluoride-doped silicate glass (FSG), a high-k dielectric material, and/or another suitable dielectric material. A deposition tool 102 may be used to deposit the hard mask layer 1105 using a PVD technique, an ALD technique, a CVD technique, an oxidation technique, another type of deposition technique described in connection with FIG. 1, and/or another suitable deposition technique. In some implementations, the planarization tool 110 may be used to planarize the hard mask layer 1105 after the hard mask layer 1105 is deposited.

As further shown in FIG. 11A, gate isolation structures 1110 (e.g., cut metal gate (CMG) isolation structures or another type of gate isolation structures) may be formed through the gate structure 240 to segment or partition the gate structure 240 into a plurality of electrically isolated gate structures 240. The gate isolation structures 1110 enable the gate structures 240 to be operated independently, enabling multiple transistors to be formed along the gate structure 240. The gate isolation structures 1110 may extend in a direction (e.g., the Y direction) that is approximately perpendicular to the gate structure 240 (e.g., the X direction).

To form the gate isolation structures 1110, gate isolation recesses may be formed through the gate structure 240 and into one or more STI regions 215 under the gate structure 240. In some implementations, a pattern in a photoresist layer is used to etch the gate structure 240 and the STI regions 215 to form the gate isolation recesses. In these implementations, a deposition tool 102 may be used to form the photoresist layer on the gate structure 240. An exposure tool 104 may be used to expose the photoresist layer to a radiation source to pattern the photoresist layer. A developer tool 106 may be used to develop and remove portions of the photoresist layer to expose the pattern. An etch tool 108 may be used to etch the gate structure 240 and the STI regions 215 based on the pattern to form the gate isolation recesses in the gate structure 240 and the STI regions 215. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for forming the gate isolation recesses based on a pattern.

A deposition tool 102 may be used to deposit the material of the gate isolation structures 1110 in the gate isolation recesses using a PVD technique, an ALD technique, a CVD technique, an oxidation technique, another type of deposition technique described in connection with FIG. 1, and/or another suitable deposition technique. In some implementations, the gate isolation structures 1110 are formed in the same set of one or more deposition operations as the hard mask layer 1105, and therefore the gate isolation structures 1110 and the hard mask layer 1105 may be formed of the same material. For example, a deposition tool 102 may deposit the material of the gate isolation structures 1110 in the gate isolation recesses, and may continue to deposit excess material on the gate structure 240 after the gate isolation recesses are filled to form the hard mask layer 1105.

As shown in FIG. 11B, a patterning stack 1120 may be formed over and/or on the hard mask layer 1105. The patterning stack 1120 may be used to pattern the hard mask layer 1105 for forming an active region isolation recess between the gate isolation structures 1110. The patterning stack 1120 may include one or more masking layers, such as a bottom layer 1125, a middle layer 1130, and a top layer 1135. The bottom layer 1125 may include a carbon-containing material and/or another suitable material. The middle layer 1130 may include an oxide-containing material and/or another suitable material. The top layer 1135 may include a photoresist layer that is used to transfer a pattern 1140 to the bottom layer 1125 and middle layer 1130. The different materials of the bottom layer 1125 and middle layer 1130 provide etch selectivity between the bottom layer 1125 and middle layer 1130, which enables the aspect ratio of the pattern 1140 to be tightly controlled.

A deposition tool 102 may be used to deposit the bottom layer 1125 and the middle layer 1130 using a PVD technique, an ALD technique, a CVD technique, an oxidation technique, another type of deposition technique described in connection with FIG. 1, and/or another suitable deposition technique. In some implementations, the planarization tool 110 may be used to planarize the bottom layer 1125 and/or the middle layer 1130 after the bottom layer 1125 and/or the middle layer 1130 are deposited. A deposition tool 102 may be used to deposit the top layer 1135 using a spin coating technique and/or another suitable deposition technique.

As further shown in FIG. 11B, the pattern 1140 may be formed in the top layer 1135. In some implementations, a wet cleaning operation may be performed prior to forming the pattern 1140. The pattern 1140 may be formed using an exposure tool 104 to expose the top layer 1135 to a radiation source to form the pattern 1140, and a developer tool 106 to develop and remove portions of the top layer 1135 to expose the pattern 1140. The pattern 1140 may be formed above a portion of the gate structure 240 between the gate isolation structures 1110.

As shown in FIG. 11C, the pattern 1140 is transferred to the bottom layer 1125 and the middle layer 1130 of the patterning stack 1120. An etch tool 108 may be used to etch the bottom layer 1125 and the middle layer 1130 based on the pattern 1140 in the top layer 1135 to transfer the pattern 1140 to the bottom layer 1125 and the middle layer 1130. In some implementations, the etch operation includes dry etch (e.g., a plasma etch operation). In some implementations, the etch operation includes another type of etch operation such as a wet chemical etch operation.

As further shown in FIG. 11C, the pattern 1140 in the bottom layer 1125 and the middle layer 1130 may be used to form an active region isolation recess 1145 (e.g., a CPODE recess) in the hard mask layer 1105. An etch tool 108 may be used to etch the hard mask layer 1105 based on the pattern 1140 in the bottom layer 1125 and the middle layer 1130 to form the active region isolation recess 1145. In some implementations, the etch operation includes dry etch (e.g., a plasma etch operation). In some implementations, the etch operation includes another type of etch operation such as a wet chemical etch operation. The etch may stop on the gate structure 240. In some implementations, a photoresist removal tool may be used to remove the remaining portions of the patterning stack 1120 (e.g., using a chemical stripper, plasma ashing, and/or another technique) after the active region isolation recess 1145 is formed. In some implementations, a wet cleaning operation may be performed after the active region isolation recess 1145 is formed.

As shown in FIG. 11D, the gate structure 240 may be etched to extend the active region isolation recess 1145 down to the STI regions 215 under the gate structure 240. The active region isolation recess 1145 may be formed through the gate structure 240 between the gate isolation structures 1110. The etch operation may also remove portions of the high-k dielectric liner 1010 between the gate isolation structures 1110.

The gate structure 240 may be etched using the gate isolation structures 1110 and the hard mask layer 1105 as a self-aligned pattern based on the etch selectivity between the gate structure 240 and the gate isolation structures 1110 and the hard mask layer 1105. In other words, no additional masking/patterning layers are needed, and the hard mask layer 1105 and the gate isolation structures 1110 control the location of the etching of the gate structure 240. An etch tool 108 may be used to etch the gate structure 240 and the high-k dielectric liner 1010. In some implementations, the etch operation includes dry etch (e.g., a plasma etch operation). In some implementations, the etch operation includes another type of etch operation such as a wet chemical etch operation.

The nanostructure channels 220 between the gate isolation structures 1110 may be exposed in the active region isolation recess 1145 after the gate structure 240 and high-k dielectric liner 1010 are etched. Moreover, portions of the mesa regions 210 under the nanostructure channels 220 between the gate isolation structures 1110 may be exposed in the active region isolation recess 1145 after the gate structure 240 and high-k dielectric liner 1010 are etched. In some implementations, a wet cleaning operation may be performed after the gate structure 240 and high-k dielectric liner 1010 are etched.

As shown in FIG. 11E, the nanostructure channels 220 between the gate isolation structures 1110, that are exposed in the active region isolation recess 1145, may be removed after the gate structure 240 and high-k dielectric liner 1010 are etched. Moreover, the mesa regions 210 under the nanostructure channels 220 may be removed through the active region isolation recess 1145. The STI regions 215 that are located between the gate isolation structures 1110 are also removed. A low-selectivity etch technique may be used to remove the mesa regions 210, the STI regions 215, and the nanostructure channels 220. The low-selectivity etch technique may include using an etchant in an etch tool 108 that etches the materials of the mesa regions 210, the STI regions 215, and the nanostructure channels 220 at similar etch rates.

The active region isolation recess 1145 extends down to and into the semiconductor substrate 205. As shown in FIG. 11E, the bottom surface of the active region isolation recess 1145 may have areas with different contours or segments. For example, mesa region sections 1150 (e.g., sections where the mesa regions 210 were removed) may be raised above inner STI sections 1155 (sections where STI regions 215 were removed from near the sidewalls of the active region isolation recess 1145) and outer STI sections 1160 (sections where STI regions 215 were removed from between the mesa regions 210). This may occur due to the different etch rates of the mesa regions 210 and the STI regions 215. Moreover, the nanostructure channels 220 may impede the etchant from reaching the underlying mesa regions 210, resulting in delayed etching of the mesa regions 210 that may cause the mesa region sections 1150 to be taller than the inner STI sections 1155 and the outer STI region sections 1160.

In some implementations, a remotely coupled plasma (RCP) is used in the etch tool 108 to remove the mesa regions 210, the STI regions 215, and the nanostructure channels 220. The plasma may be a hydrogen bromide (HBr) based plasma etchant, a chlorine (Cl₂) based plasma etchant, a boron trichloride (BCl₃) based plasma etchant, and/or another plasma based etchant with oxygen (O₂) and/or carbon dioxide (CO₂) added. The greater the concentration of BCl₃ and/or Cl₂ in the plasma based etchant, the lesser the etch selectivity between the mesa regions 210 (e.g., silicon) and the STI regions 215 (e.g., silicon dioxide).

The plasma may be generated using an inductively coupled plasma (ICP) generator, a resonant antenna plasma source driven by a radio frequency (RF) power generator, and/or another type of plasma based etch tool. A frequency of a multiple of 13.56 megahertz (MHz) (e.g., 13.56 MHz, 27 MHz) may be used for the RF power generator. The RF power generator may be operated to provide a source power that is included in a range of approximately 100 watts to approximately 2500 watts. However, other values for the range are within the scope of the present disclosure. In some implementations, a pulse plasma etch may be performed with a duty cycle that is included in a range of approximately 10% to approximately 100%. However, other values for the range are within the scope of the present disclosure. An RF bias power to a pedestal in the process chamber of the etch tool 108 may be included in a range of approximately 10 watts to approximately 2000 watts. However, other values for the range are within the scope of the present disclosure. The process chamber of the etch tool 108 may be operated at a pressure that is included in a range of approximately 3 mTorr to approximately 150 mTorr. However, other values for the range are within the scope of the present disclosure. The process chamber of the etch tool 108 may be operated at a temperature that is included in a range of approximately 20 degrees Celsius to approximately 150 degrees Celsius. However, other values for the range are within the scope of the present disclosure.

In some implementations, one or more methane (CH₄)-based deposition operations may be performed to protect the hard mask layer 1105 during etch operation to remove the mesa regions 210, the STI regions 215, and the nanostructure channels 220. Passivation operations, such as silicon tetrachloride (SiCl₄) passivation and/or oxygen (O₂) passivation, may be performed to form a passivation layer to reduce the likelihood of and/or magnitude of etching of layers and/or structures other than the mesa regions 210, the STI regions 215, and the nanostructure channels 220. After the passivation operations, a break-through operation utilizing tetrafluoromethane (CF₄), trifluoromethane (CHF₃), difluoromethane (CH₂F₂), and/or hexafluorobutadine (C₄F₆) may be performed to remove the passivation layer from the bottom surface of the active region isolation recess 1145 to enable further etching of the active region isolation recess 1145.

Removal of the STI regions 215 from the active region isolation recess 1145 may reduce bowing of the active region isolation recess 1145. Accordingly, removal of the STI regions 215 from the active region isolation recess 1145 may reduce critical dimension loading and/or may reduce EPI damage to the source/drain region 225 on opposing sides of the active region isolation recess 1145. In particular, removal of the STI regions 215 from the active region isolation recess 1145 reduces the quantity of and/or severity of width transitions in the active region isolation recess 1145. In other words, removal of the STI regions 215 from the active region isolation recess 1145 results in a more uniform width between the top and the bottom of active region isolation recess 1145. The uniform width of the active region isolation recess 1145 reduces and/or minimizes the reduction of volume from the top to the bottom of the active region isolation recess 1145, which results in a more consistent and uniform density of etchant flux (e.g., ions and radicals in the etchant) and a more consistent and uniform pressure between the top and the bottom of the active region isolation recess 1145 (e.g., than if the STI regions 215 were not removed). The more consistent and uniform density of etchant flux and the more consistent and uniform pressure between the top and the bottom of the active region isolation recess 1145 enables a more consistent and uniform etch rate at the height of and just below the height of the source/drain regions 225, which may reduce critical dimension loading and/or may reduce EPI damage to the source/drain region 225

As shown in FIG. 11F, a dielectric liner 1165 of the active region isolation structure 1115 may be formed in the active region isolation recess 1145. The dielectric liner 1165 may be conformally deposited on the sidewalls of the active region isolation recess 1145 (corresponding to sidewalls of the gate isolation structures 1110 that are exposed in the active region isolation recess 1145). The dielectric liner 1165 may be conformally deposited on bottom surfaces of the active region isolation recess 1145, including the mesa region sections 1150, the inner STI sections 1155, and the outer STI sections 1160. A deposition tool 102 may be used to deposit the dielectric liner 1165 using a PVD technique, an ALD technique, a CVD technique, an oxidation technique, another type of deposition technique described in connection with FIG. 1, and/or another suitable deposition technique. The dielectric liner 1165 may include a dielectric material such as a silicon oxide (SiOₓ such as SiO₂), a silicon nitride (SiₓN_{y} such as a Si₃N₄), a silicon oxynitride (SiON), fluoride-doped silicate glass (FSG), a high-k dielectric material, and/or another suitable dielectric material.

As shown in FIG. 11G, the active region isolation recess 1145 may be filled with a dielectric layer 1170 over and/or on the dielectric liner 1165 of the active region isolation structure 1115. The active region isolation recess 1145 may be over-filled with the dielectric layer 1170 to ensure that the active region isolation recess 1145 is fully filled with the dielectric layer 1170 and to minimize the formation of gaps or voids in the active region isolation structure 1115. A deposition tool 102 may be used to deposit the dielectric layer 1170 using a PVD technique, an ALD technique, a CVD technique, an oxidation technique, another type of deposition technique described in connection with FIG. 1, and/or another suitable deposition technique. The dielectric layer 1170 may include a dielectric material such as a silicon oxide (SiOₓ such as SiO₂), a silicon nitride (SiₓN_{y} such as a Si₃N₄), a silicon oxynitride (SiON), fluoride-doped silicate glass (FSG), a high-k dielectric material, and/or another suitable dielectric material.

As shown in FIG. 11H, a planarization operation may be performed to planarize the semiconductor device 200 after the layers of the active region isolation structure 1115 are formed. A planarization tool 110 may be used to planarize the semiconductor device 200 to remove the hard mask layer 1105, to remove excess material of the dielectric liner 1165, and/or to remove excess material of the dielectric layer 1170.

The semiconductor device 200 may include a first plurality of nanostructure channels 220a over a first mesa region 210a that extends above a semiconductor substrate 205, and a second plurality of nanostructure channels 220b over a second mesa region 210b that extends above the semiconductor substrate 205. The first plurality of nanostructure channels 220a and the second plurality of nanostructure channels 220b are arranged in a direction that is perpendicular to the semiconductor substrate 205 (e.g., the Z direction). The semiconductor device 200 may include a first gate structure 240a wrapping around each of the first plurality of nanostructure channels 220a, and a second gate structure 240b wrapping around each of the second plurality of nanostructure channels 220b. The semiconductor device 200 may include a first gate isolation structure 1110a and a second gate isolation structure 1110b between the first gate structure 240a and the second gate structure 240b. The semiconductor device 200 may include an active region isolation structure 1115 (e.g., a CPODE structure) between the gate isolation structures 1110a and 1110b. The active region isolation structure 1115 may be located between the first gate structure 240a and the first gate isolation structure 1110a, and between the second gate structure 240b and the second gate isolation structure 1110b. A dielectric liner 1165 of the active region isolation structure 1115 is included directly on a sidewall of the first gate isolation structure 1110a and directly on a sidewall of the second gate isolation structure 1110b. The first gate structure 240a may be in direct contact with a sidewall of the first gate isolation structure 1110a, and the second gate structure 240b may be in direct contact with a sidewall of the second gate isolation structure 1110b. The dielectric liner 1165 may be located between the dielectric layer 1170 of the active region isolation structure 1115 and the gate isolation structures 1110a and 1110b. The bottom of the active region isolation structure 1115 may include a mesa region section 1150 that extends into the semiconductor substrate 205 and one or more STI sections (e.g., an inner STI section 1155, an outer STI section 1160) that are below the mesa region section 1150.

FIG. 11I illustrate a top-down view of the semiconductor device 200. As shown in FIG. 11I, the nanostructure channels 220 may extend in the Y direction in the semiconductor device 200, and the gate structures 240 may extend in the X direction in the semiconductor device 200. Source/drain regions 225 may be recessed in one or more of the nanostructure channels 220 such that a source/drain region 225 is adjacent to ends of one or more sets of nanostructure channels 220. The gate isolation structures 1110a and 1110b may extend in the Y direction and may extend across one or more gate structures 240. The gate isolation structures 1110a and 1110b may segment one or more of the gate structures 240 into a plurality of gate structures, such as a gate structure 240a and a gate structure 240b. The active region isolation structure 1115 may be included between the gate isolation structures 1110a and 1110b in place of where a portion of a gate structure 240 (and the underlying nanostructure channels and mesa regions 210) were removed. The active region isolation structure 1115 segments one or more of the nanostructure channels 220c into a plurality of portions on opposing sides of the active region isolation structure 1115.

As indicated above, the number and arrangement of operations and devices shown in FIGS. 11A-11I are provided as one or more examples. In practice, there may be additional operations and devices, fewer operations and devices, different operations and devices, or differently arranged operations and devices than those shown in FIGS. 11A-11I.

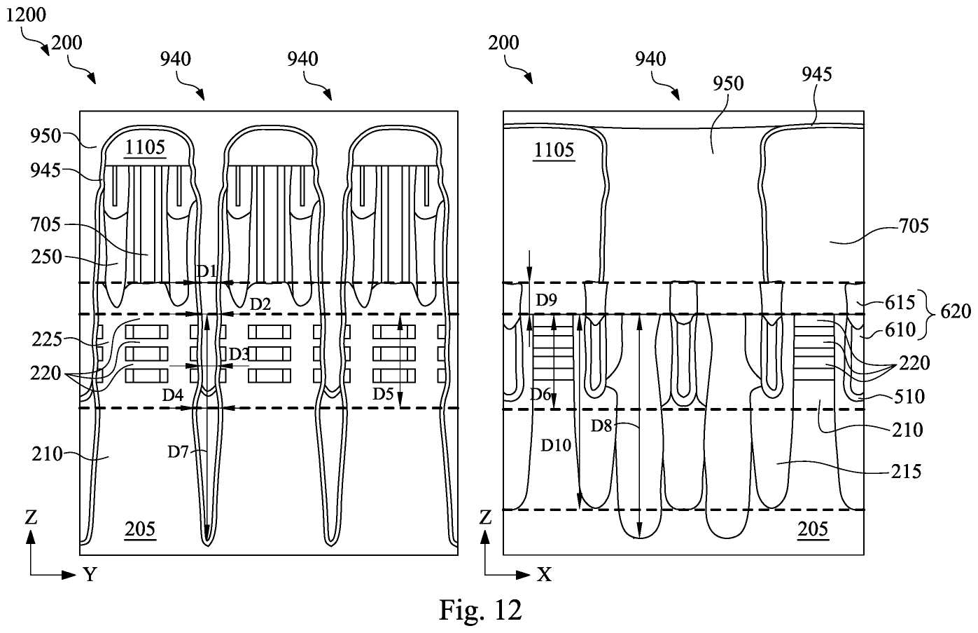

FIG. 12 is a diagram of an example implementation 1200 of the semiconductor device 200 described herein. FIG. 12 is an example implementation of the semiconductor device 200 in a region in which the FEOL CPODE process of FIGS. 9A-9I was performed to form the active region isolation structure 940. The left side of FIG. 12 illustrates the region the semiconductor device 200 in a Y-Z plane, and the right side of FIG. 12 illustrates the region of the semiconductor device 200 in a Z-X plane.

As shown in FIG. 12, the semiconductor device 200 may include one or more dimensions, such as a dimension D1, a dimension D2, a dimension D3, a dimension D4, a dimension D5, a dimension D6, a dimension D7, a dimension D8, a dimension D9, a dimension D10, a dimension D11, a dimension D12, and/or a dimension D13, among other examples.

The dimension D1 may correspond to a Y-direction width (sometimes referred to as a “critical dimension” or “CD”) of an active region isolation structure 940 at a height of the top of the hybrid fin structures 620 (e.g., at a height of the top surface of the high-k dielectric layer 615 of the hybrid fin structures 620) in the semiconductor device 200. In some implementations, the dimension D1 may be included in a range of approximately 22.9 nanometers to approximately 24.5 nanometers. However, other values and/or other ranges for the dimension D1 are within the scope of the present disclosure.

The dimension D2 may correspond to a Y-direction width of an active region isolation structure 940 at a height of the topmost nanostructure channels 220. In some implementations, the dimension D2 may be included in a range of approximately 17.1 nanometers to approximately 19.3 nanometers. However, other values and/or other ranges for the dimension D2 are within the scope of the present disclosure.

The dimension D3 may correspond to a Y-direction width of an active region isolation structure 940 at a height of the bottom nanostructure channels 220. In some implementations, the dimension D3 may be included in a range of approximately 15.7 nanometers to approximately 18.6 nanometers. However, other values and/or other ranges for the dimension D3 are within the scope of the present disclosure.

The dimension D4 may correspond to a Y-direction width of an active region isolation structure 940 at a height below the bottom nanostructure channels 220 and below the hybrid fin structures 620. In some implementations, the dimension D4 may be included in a range of approximately 18 nanometers to approximately 20 nanometers. However, other values and/or other ranges for the dimension D4 are within the scope of the present disclosure.

The dimensions D5 and D6 may correspond to a Z-direction depth, height, or thickness of an active region isolation structure 940 from the top of the STI regions 215 to the topmost nanostructure channels 220. In some implementations, the dimension D5 (in the Y-Z plane) may be included in a range of approximately 63.7 nanometers to approximately 73.3 nanometers. However, other values and/or other ranges for the dimension D5 are within the scope of the present disclosure. In some implementations, the dimension D6 (in the Y-X plane) may be included in a range of approximately 65.4 nanometers to approximately 72.8 nanometers. However, other values and/or other ranges for the dimension D6 are within the scope of the present disclosure.

The dimensions D7 and D8 may correspond to a Z-direction depth, height, or thickness of an active region isolation structure 940 to the topmost nanostructure channels 220. In some implementations, the dimension D7 (in the Y-Z plane) may be included in a range of approximately 153.3 nanometers to approximately 172.1 nanometers. However, other values and/or other ranges for the dimension D7 are within the scope of the present disclosure. In some implementations, the dimension D8 (in the Y-X plane) may be included in a range of approximately 157.7 nanometers to approximately 169.4 nanometers. However, other values and/or other ranges for the dimension D8 are within the scope of the present disclosure.

The dimension D9 may correspond to a Z-direction thickness of a high-k dielectric layer 615 of a hybrid fin structure 620. In some implementations, the dimension D9 may be included in a range of approximately 22.9 nanometers to approximately 34.5 nanometers. However, other values and/or other ranges for the dimension D9 are within the scope of the present disclosure.

The dimension D10 may correspond to a Z-direction combined height or a combined thickness of an STI region 215 and a dielectric layer 610 of a hybrid fin structure 620. In some implementations, the dimension D10 may be included in a range of approximately 143.1 nanometers to approximately 143.9 nanometers. However, other values and/or other ranges for the dimension D10 are within the scope of the present disclosure.

As indicated above, FIG. 12 is provided as an example. Other examples may differ from what is described with regard to FIG. 12.

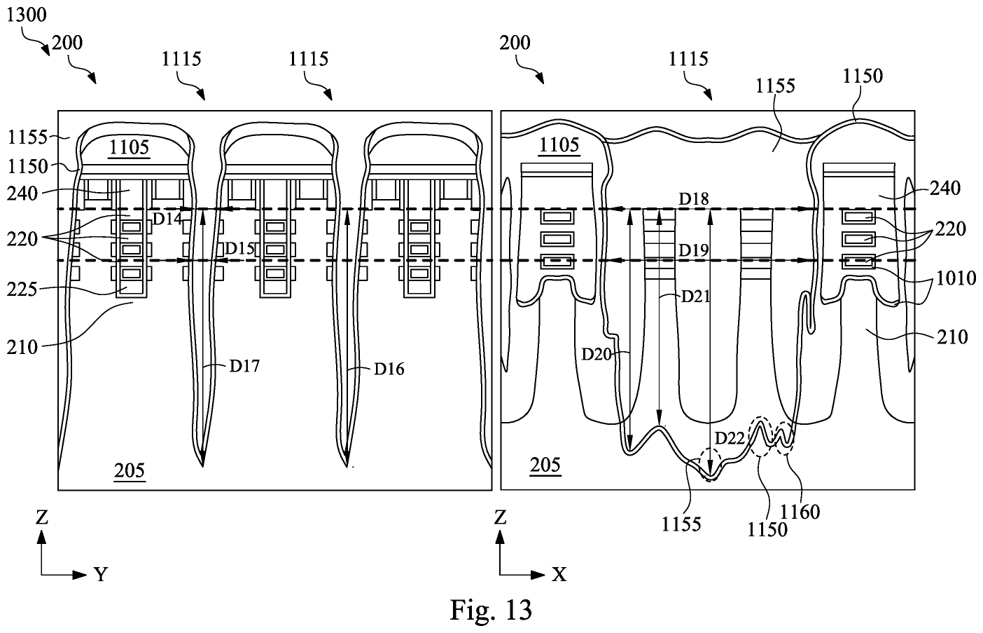

FIG. 13 is a diagram of an example implementation 1300 of the semiconductor device 200 described herein. FIG. 13 is an example implementation of the semiconductor device 200 in a region in which the MEOL CPODE process of FIGS. 11A-11I was performed to form the active region isolation structure 1115. The left side of FIG. 13 illustrates the region the semiconductor device 200 in a Y-Z plane, and the right side of FIG. 13 illustrates the region of the semiconductor device 200 in a Z-Xplane.

As shown in FIG. 13, the semiconductor device 200 may include one or more dimensions, such as a dimension D11, a dimension D12, a dimension D13, a dimension D14, a dimension D15, a dimension D16, a dimension D17, a dimension D18, and/or a dimension D19, among other examples.

The dimension D11 may correspond to a Y-direction width of an active region isolation structure 1115 at a height of the topmost nanostructure channels 220. In some implementations, the dimension D11 may be included in a range of approximately 17.4 nanometers to approximately 19.6 nanometers. However, other values and/or other ranges for the dimension D11 are within the scope of the present disclosure.

The dimension D12 may correspond to a Y-direction width of an active region isolation structure 1115 at a height of the bottom nanostructure channels 220. In some implementations, the dimension D12 may be included in a range of approximately 14.9 nanometers to approximately 18.7 nanometers. However, other values and/or other ranges for the dimension D12 are within the scope of the present disclosure.

The dimension D13 may correspond to a Z-direction depth, height, or thickness of an active region isolation structure 1115 to the topmost nanostructure channels 220. In some implementations, the dimension D13 may be included in a range of approximately 170.3 nanometers to approximately 178.3 nanometers. However, other values and/or other ranges for the dimension D13 are within the scope of the present disclosure.

The dimension D14 may correspond to an angle between the sidewalls of an active region isolation structure 1115. In some implementations, the dimension D14 may be included in a range of approximately 5.7 degrees to approximately 6.7 degrees. However, other values and/or other ranges for the dimension D14 are within the scope of the present disclosure.

The dimension D15 may correspond to an X-direction width of an active region isolation structure 1115 at a height of the topmost nanostructure channels 220. In some implementations, the dimension D15 may be included in a range of approximately 135.7 nanometers to approximately 138.5 nanometers. However, other values and/or other ranges for the dimension D7 are within the scope of the present disclosure.

The dimension D16 may correspond to an X-direction width of an active region isolation structure 1115 at a height of the bottom nanostructure channels 220. In some implementations, the dimension D16 may be included in a range of approximately 137.2 nanometers to approximately 138.3 nanometers. However, other values and/or other ranges for the dimension D16 are within the scope of the present disclosure.

The dimension D17 may correspond to a Z-direction depth, height, or thickness of an active region isolation structure 1115 from an outer STI section 1160 (e.g., a section of a removed STI region) to the topmost nanostructure channels 220. In some implementations, the dimension D17 may be included in a range of approximately 145.8 nanometers to approximately 155.0 nanometers. However, other values and/or other ranges for the dimension D17 are within the scope of the present disclosure.

The dimension D18 may correspond to a Z-direction depth, height, or thickness of an active region isolation structure 1115 from a mesa region section 1150 (e.g., a section of removed mesa region) to the topmost nanostructure channels 220. In some implementations, the dimension D18 may be included in a range of approximately 127.2 nanometers to approximately 138.8 nanometers. However, other values and/or other ranges for the dimension D18 are within the scope of the present disclosure.

The dimension D19 may correspond to a Z-direction depth, height, or thickness of an active region isolation structure 1115 from an inner STI section 1155 (e.g., a section of an inner STI region) to the topmost nanostructure channels 220. In some implementations, the dimension D19 may be included in a range of approximately 169.3 nanometers to approximately 178.6 nanometers. However, other values and/or other ranges for the dimension D19 are within the scope of the present disclosure.

As indicated above, FIG. 13 is provided as an example. Other examples may differ from what is described with regard to FIG. 13.

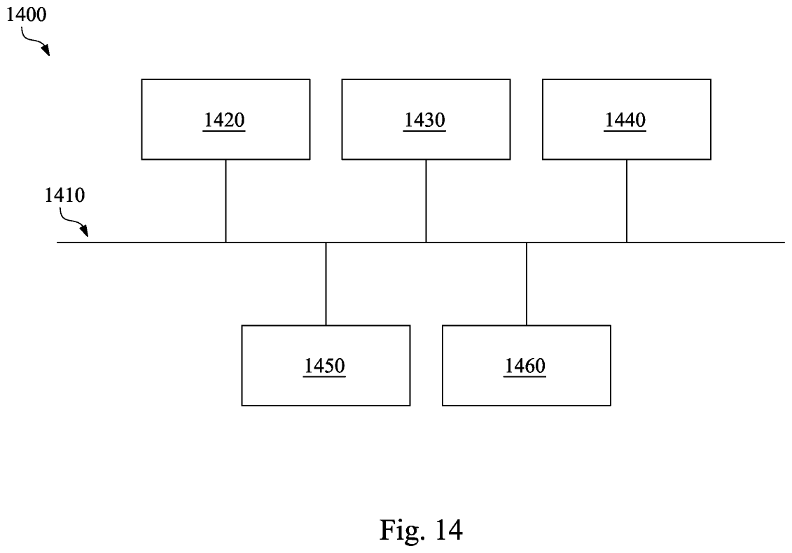

FIG. 14 is a diagram of example components of a device 1400 described herein. In some implementations, one or more of the semiconductor processing tools 102-112 and/or the wafer/die transport tool 114 may include one or more devices 1400 and/or one or more components of the device 1400. As shown in FIG. 14, the device 1400 may include a bus 1410, a processor 1420, a memory 1430, an input component 1440, an output component 1450, and/or a communication component 1460.

The bus 1410 may include one or more components that enable wired and/or wireless communication among the components of the device 1400. The bus 1410 may couple together two or more components of FIG. 14, such as via operative coupling, communicative coupling, electronic coupling, and/or electric coupling. For example, the bus 1410 may include an electrical connection (e.g., a wire, a trace, and/or a lead) and/or a wireless bus. The processor 1420 may include a central processing unit, a graphics processing unit, a microprocessor, a controller, a microcontroller, a digital signal processor, a field-programmable gate array, an application-specific integrated circuit, and/or another type of processing component. The processor 1420 may be implemented in hardware, firmware, or a combination of hardware and software. In some implementations, the processor 1420 may include one or more processors capable of being programmed to perform one or more operations or processes described elsewhere herein.

The memory 1430 may include volatile and/or nonvolatile memory. For example, the memory 1430 may include random access memory (RAM), read only memory (ROM), a hard disk drive, and/or another type of memory (e.g., a flash memory, a magnetic memory, and/or an optical memory). The memory 1430 may include internal memory (e.g., RAM, ROM, or a hard disk drive) and/or removable memory (e.g., removable via a universal serial bus connection). The memory 1430 may be a non-transitory computer-readable medium. The memory 1430 may store information, one or more instructions, and/or software (e.g., one or more software applications) related to the operation of the device 1400. In some implementations, the memory 1430 may include one or more memories that are coupled (e.g., communicatively coupled) to one or more processors (e.g., processor 1420), such as via the bus 1410. Communicative coupling between a processor 1420 and a memory 1430 may enable the processor 1420 to read and/or process information stored in the memory 1430 and/or to store information in the memory 1430.

The input component 1440 may enable the device 1400 to receive input, such as user input and/or sensed input. For example, the input component 1440 may include a touch screen, a keyboard, a keypad, a mouse, a button, a microphone, a switch, a sensor, a global positioning system sensor, a global navigation satellite system sensor, an accelerometer, a gyroscope, and/or an actuator. The output component 1450 may enable the device 1400 to provide output, such as via a display, a speaker, and/or a light-emitting diode. The communication component 1460 may enable the device 1400 to communicate with other devices via a wired connection and/or a wireless connection. For example, the communication component 1460 may include a receiver, a transmitter, a transceiver, a modem, a network interface card, and/or an antenna.

The device 1400 may perform one or more operations or processes described herein. For example, a non-transitory computer-readable medium (e.g., memory 1430) may store a set of instructions (e.g., one or more instructions or code) for execution by the processor 1420. The processor 1420 may execute the set of instructions to perform one or more operations or processes described herein. In some implementations, execution of the set of instructions, by one or more processors 1420, causes the one or more processors 1420 and/or the device 1400 to perform one or more operations or processes described herein. In some implementations, hardwired circuitry may be used instead of or in combination with the instructions to perform one or more operations or processes described herein. Additionally, or alternatively, the processor 1420 may be configured to perform one or more operations or processes described herein. Thus, implementations described herein are not limited to any specific combination of hardware circuitry and software.

The number and arrangement of components shown in FIG. 14 are provided as an example. The device 1400 may include additional components, fewer components, different components, or differently arranged components than those shown in FIG. 14. Additionally, or alternatively, a set of components (e.g., one or more components) of the device 1400 may perform one or more functions described as being performed by another set of components of the device 1400.

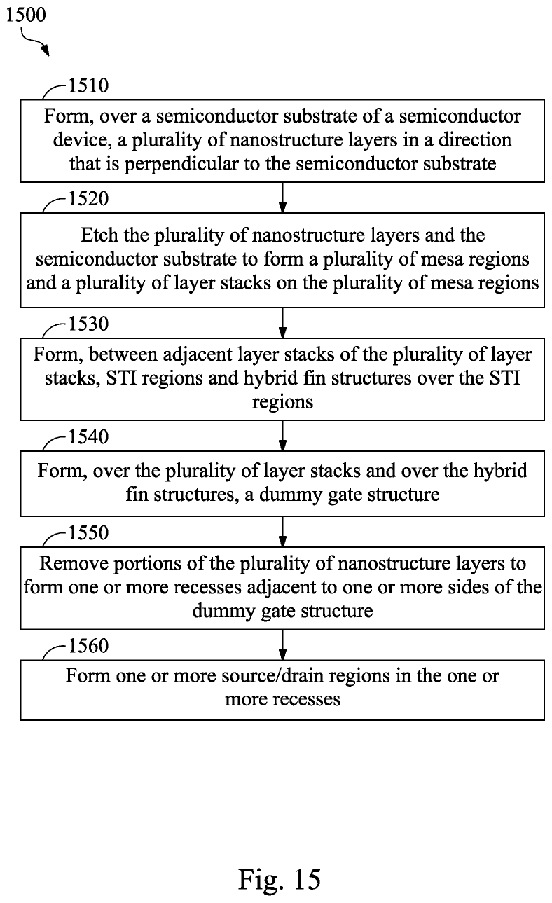

FIG. 15 is a flowchart of an example process 1500 associated with forming a semiconductor device described herein. In some implementations, one or more process blocks of FIG. 15 are performed using one or more semiconductor processing tools (e.g., one or more of the semiconductor processing tools 102-112). Additionally, or alternatively, one or more process blocks of FIG. 15 may be performed using one or more components of device 1400, such as processor 1420, memory 1430, input component 1440, output component 1450, and/or communication component 1460.

As shown in FIG. 15, process 1500 may include forming, over a semiconductor substrate of a semiconductor device, a plurality of nanostructure layers in a direction that is perpendicular to the semiconductor substrate (block 1510). For example, one or more of the semiconductor processing tools 102-112 may be used to form, over a semiconductor substrate 205 of a semiconductor device 200, a plurality of nanostructure layers (e.g., a layer stack 305) in a direction that is perpendicular to the semiconductor substrate 205, as described herein. In some implementations, the plurality of nanostructure layers includes a plurality of sacrificial layers (e.g., first layers 310) alternating with a plurality of channel layers (e.g., second layers 315).

As further shown in FIG. 15, process 1500 may include etching the plurality of nanostructure layers and the semiconductor substrate to form a plurality of mesa regions and a plurality of layer stacks on the plurality of mesa regions (block 1520). For example, one or more of the semiconductor processing tools 102-112 may be used to etch the plurality of nanostructure layers and the semiconductor substrate 205 to form a plurality of mesa regions 210 and a plurality of layer stacks (e.g., portions 340 of the layer stacks 305) on the plurality of mesa regions 210, as described herein. In some implementations, the plurality of layer stacks include respective portions of the plurality of sacrificial layers and respective portions of the plurality of channel layers.

As further shown in FIG. 15, process 1500 may include forming, between adjacent layer stacks of the plurality of layer stacks, STI regions and hybrid fin structures over the STI regions (block 1530). For example, one or more of the semiconductor processing tools 102-112 may be used to form, between adjacent layer stacks of the plurality of layer stacks, STI regions 215 and hybrid fin structures 620 over the STI regions 215, as described herein.

As further shown in FIG. 15, process 1500 may include forming, over the plurality of layer stacks and over the hybrid fin structures, a dummy gate structure (block 1540). For example, one or more of the semiconductor processing tools 102-112 may be used to form, over the plurality of layer stacks and over the hybrid fin structures 620, a dummy gate structure 705, as described herein.

As further shown in FIG. 15, process 1500 may include removing portions of the plurality of nanostructure layers to form one or more recesses adjacent to one or more sides of the dummy gate structure (block 1550). For example, one or more of the semiconductor processing tools 102-112 may be used to remove portions of the plurality of nanostructure layers to form one or more recesses (e.g., source/drain recesses 805) adjacent to one or more sides of the dummy gate structure 705, as described herein.

As further shown in FIG. 15, process 1500 may include forming one or more source/drain regions in the one or more recesses (block 1560). For example, one or more of the semiconductor processing tools 102-112 may be used to form one or more source/drain regions 225 in the one or more recesses, as described herein. In some implementations, a top surface of a hybrid fin structure 620 of the hybrid fin structures 620 is located at a greater height in the semiconductor device 200 than a top surface of a source/drain region 225 of the one or more source/drain regions 225.

Process 1500 may include additional implementations, such as any single implementation or any combination of implementations described below and/or in connection with one or more other processes described elsewhere herein.

In a first implementation, process 1500 includes removing, to form an active region isolation recess 935 a portion of the dummy gate structure 705, a portion of a layer stack, of the plurality of layer stacks, under the portion of the dummy gate structure 705, and a portion of a mesa region 210, of the plurality of mesa regions 210, under the portion of the layer stack, and forming an active region isolation structure 940 in the active region isolation recess 935.

In a second implementation, alone or in combination with the first implementation, removing the portion of the dummy gate structure 705, the portion of the layer stack, and the portion of the mesa region 210 includes performing a first etch operation to remove the portion of the dummy gate structure 705, and performing, after the first etch operation, a second etch operation to remove the portion of the layer stack and the portion of the mesa region 210.

In a third implementation, alone or in combination with one or more of the first and second implementations, process 1500 includes performing, prior to the first etch operation, a third etch operation to remove a portion of a hard mask layer (905) over the portion of the dummy gate structure.

In a fourth implementation, alone or in combination with one or more of the first through third implementations, high-k dielectric layers 615, of a subset of the hybrid fin structures 620, are exposed in the active region isolation recess 935 after the first etch operation.

In a fifth implementation, alone or in combination with one or more of the first through fourth implementations, low-k dielectric layers (e.g., dielectric layers 610), of the subset of the hybrid fin structures 620, are exposed in the active region isolation recess 935 after the second etch operation.

In a sixth implementation, alone or in combination with one or more of the first through fifth implementations, the active region isolation recess 935 extends below bottom surfaces of the hybrid fin structures 620.

Although FIG. 15 shows example blocks of process 1500, in some implementations, process 1500 includes additional blocks, fewer blocks, different blocks, or differently arranged blocks than those depicted in FIG. 15. Additionally, or alternatively, two or more of the blocks of process 1500 may be performed in parallel.

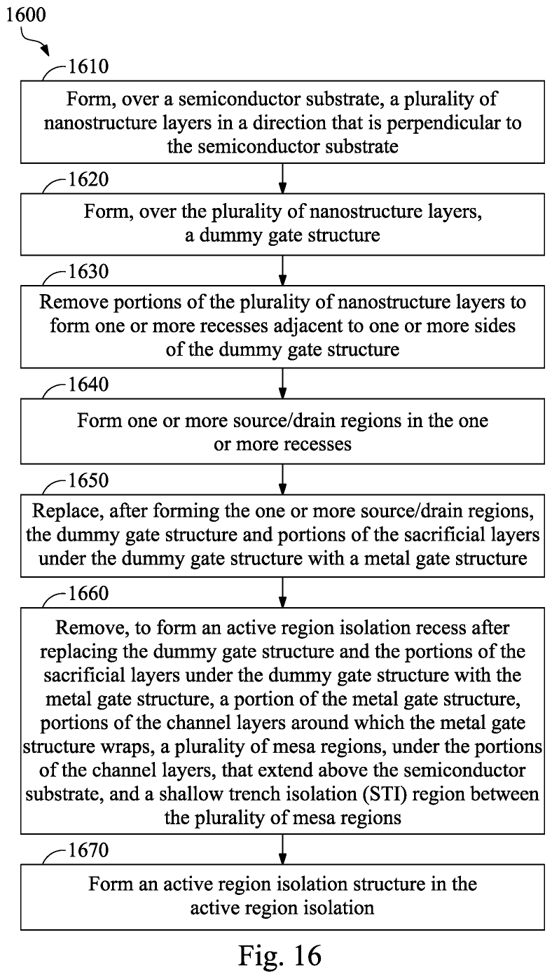

FIG. 16 is a flowchart of an example process 1600 associated with forming a semiconductor device. In some implementations, one or more process blocks of FIG. 16 are performed using one or more semiconductor processing tools (e.g., one or more of the semiconductor processing tools 102-112). Additionally, or alternatively, one or more process blocks of FIG. 16 may be performed using one or more components of device 1400, such as processor 1420, memory 1430, input component 1440, output component 1450, and/or communication component 1460.

As shown in FIG. 16, process 1600 may include forming, over a semiconductor substrate, a plurality of nanostructure layers in a direction that is perpendicular to the semiconductor substrate (block 1610). For example, one or more of the semiconductor processing tools 102-112 may be used to form, over a semiconductor substrate 205, a plurality of nanostructure layers (e.g., a layer stack 305) in a direction that is perpendicular to the semiconductor substrate 205, as described herein. In some implementations, the plurality of nanostructure layers includes a plurality of sacrificial layers (e.g., first layers 310) alternating with a plurality of channel layers (e.g., second layers 315), as described herein.

As further shown in FIG. 16, process 1600 may include forming, over the plurality of nanostructure layers, a dummy gate structure (block 1620). For example, one or more of the semiconductor processing tools 102-112 may be used to form, over the plurality of nanostructure layers, a dummy gate structure 705, as described herein.

As further shown in FIG. 16, process 1600 may include removing portions of the plurality of nanostructure layers to form one or more recesses adjacent to one or more sides of the dummy gate structure (block 1630). For example, one or more of the semiconductor processing tools 102-112 may be used to remove portions of the plurality of nanostructure layers to form one or more recesses (e.g., source/drain recesses 805) adjacent to one or more sides of the dummy gate structure 705, as described herein.

As further shown in FIG. 16, process 1600 may include forming one or more source/drain regions in the one or more recesses (block 1640). For example, one or more of the semiconductor processing tools 102-112 may be used to form one or more source/drain regions 225 in the one or more recesses, as described herein.

As further shown in FIG. 16, process 1600 may include replacing, after forming the one or more source/drain regions, the dummy gate structure and portions of the sacrificial layers under the dummy gate structure with a metal gate structure (block 1650). For example, one or more of the semiconductor processing tools 102-112 may be used to replace, after forming the one or more source/drain regions 225, the dummy gate structure 705 and portions of the sacrificial layers under the dummy gate structure 705 with a metal gate structure (e.g., a gate structure 240), as described herein. In some implementations, the metal gate structure wraps around at least four sides of the channel layers.

As further shown in FIG. 16, process 1600 may include removing, to form an active region isolation recess after replacing the dummy gate structure and the portions of the sacrificial layers under the dummy gate structure with the metal gate structure, a portion of the metal gate structure, portions of the channel layers around which the metal gate structure wraps, a plurality of mesa regions, under the portions of the channel layers, that extend above the semiconductor substrate, and an STI region between the plurality of mesa regions (block 1660). For example, one or more of the semiconductor processing tools 102-112 may be used to remove, to form an active region isolation recess 1145 after replacing the dummy gate structure 705 and the portions of the sacrificial layers under the dummy gate structure 705 with the metal gate structure, a portion of the metal gate structure, portions of the channel layers around which the metal gate structure wraps, a plurality of mesa regions 210, under the portions of the channel layers, that extend above the semiconductor substrate 205, and an STI region 215 between the plurality of mesa regions 210, as described herein.

As further shown in FIG. 16, process 1600 may include forming an active region isolation structure in the active region isolation recess (block 1670). For example, one or more of the semiconductor processing tools 102-112 may be used to form an active region isolation structure 1115 in the active region isolation recess 1145, as described herein.

Process 1600 may include additional implementations, such as any single implementation or any combination of implementations described below and/or in connection with one or more other processes described elsewhere herein.

In a first implementation, process 1600 includes removing, prior to removing the portion of the metal gate structure to form the active region isolation recess, another portion of the metal gate structure to form a gate isolation recess in the metal gate structure, and forming, prior to removing the portion of the metal gate structure to form the active region isolation recess 1145, a gate isolation structure 1110 in the gate isolation recess.

In a second implementation, alone or in combination with the first implementation, removing the portion of the metal gate structure, the portions of the channel layers around which the metal gate structure wraps, the plurality of mesa regions 210, and the STI region 215 includes removing, based on the gate isolation structure 1110, the portion of the metal gate structure, the portions of the channel layers around which the metal gate structure wraps, the plurality of mesa regions 210, and the STI region 215.

In a third implementation, alone or in combination with one or more of the first and second implementations, process 1600 includes removing, prior to removing the portion of the metal gate structure to form the active region isolation recess 1145, a plurality of other portions of the metal gate structure to form a plurality of gate isolation recesses in the metal gate structure, and forming, prior to removing the portion of the metal gate structure to form the active region isolation recess 1145, a plurality of gate isolation structures 1110 in the plurality of gate isolation recesses.

In a fourth implementation, alone or in combination with one or more of the first through third implementations, removing the portion of the metal gate structure, the portions of the channel layers around which the metal gate structure wraps, the plurality of mesa regions 210, and the STI region 215 includes removing, from between the plurality of gate isolation structures 1110, the portion of the metal gate structure, the portions of the channel layers around which the metal gate structure wraps, the plurality of mesa regions 210, and the STI region 215.

In a fifth implementation, alone or in combination with one or more of the first through fourth implementations, forming the active region isolation structure includes forming a dielectric liner 1165 on sidewalls of the plurality of gate isolation structures 1110 in the active region isolation recess 1145, and filling the active region isolation recess with a dielectric layer 1170 over the dielectric liner 1165.

In a sixth implementation, alone or in combination with one or more of the first through fifth implementations, forming the plurality of gate isolation structures 1110 includes forming the plurality of gate isolation structures 1110 such that the plurality of gate isolation structures 1110 extend in a first direction across the metal gate, and where forming the active region isolation structure 1115 includes forming the active region isolation structure 1115 such that the active region isolation structure 1115 extends in a second direction in which the metal gate structure extends.

Although FIG. 16 shows example blocks of process 1600, in some implementations, process 1600 includes additional blocks, fewer blocks, different blocks, or differently arranged blocks than those depicted in FIG. 16. Additionally, or alternatively, two or more of the blocks of process 1600 may be performed in parallel.

In this way, the CPODE processes are described herein in which one or more semiconductor device parameters are tuned to reduce the likelihood of etching of source/drain regions on opposing sides of CPODE structures formed in a semiconductor device, to reduce the likelihood of depth loading in the semiconductor device, and/or to reduce the likelihood of gate deformation in the semiconductor device, among other examples. Thus, the CPODE processes described herein may reduce the likelihood of epitaxial damage to the source/drain regions, may reduce current leakage between the source/drain regions, and/or may reduce the likelihood of threshold voltage shifting for transistors of the semiconductor device. The reduced likelihood of threshold voltage shifting may provide more uniform and/or faster switching speeds for the transistors, more uniform and/or lower power consumption for the transistors, and/or increased device performance for the transistors, among other examples.

As described in greater detail above, some implementations described herein provide a method. The method includes forming, over a semiconductor substrate of a semiconductor device, a plurality of nanostructure layers in a direction that is perpendicular to the semiconductor substrate, where the plurality of nanostructure layers includes a plurality of sacrificial layers alternating with a plurality of channel layers. The method includes etching the plurality of nanostructure layers and the semiconductor substrate to form a plurality of mesa regions and a plurality of layer stacks on the plurality of mesa regions, where the plurality of layer stacks include respective portions of the plurality of sacrificial layers and respective portions of the plurality of channel layers. The method includes forming, between adjacent layer stacks of the plurality of layer stacks, STI regions, and hybrid fin structures over the STI regions. The method includes forming, over the plurality of layer stacks and over the hybrid fin structures, a dummy gate structure. The method includes removing portions of the plurality of nanostructure layers to form one or more recesses adjacent to one or more sides of the dummy gate structure. The method includes forming one or more source/drain regions in the one or more recesses, where a top surface of a hybrid fin structure of the hybrid fin structures is located at a greater height in the semiconductor device than a top surface of a source/drain region of the one or more source/drain regions.

As described in greater detail above, some implementations described herein provide a method. The method includes forming, over a semiconductor substrate, a plurality of nanostructure layers in a direction that is perpendicular to the semiconductor substrate, where the plurality of nanostructure layers includes a plurality of sacrificial layers alternating with a plurality of channel layers. The method includes forming, over the plurality of nanostructure layers, a dummy gate structure. The method includes removing portions of the plurality of nanostructure layers to form one or more recesses adjacent to one or more sides of the dummy gate structure. The method includes forming one or more source/drain regions in the one or more recesses. The method includes replacing, after forming the one or more source/drain regions, the dummy gate structure and portions of the sacrificial layers under the dummy gate structure with a metal gate structure, where the metal gate structure wraps around at least four sides of the channel layers. The method includes removing, to form an active region isolation recess after replacing the dummy gate structure and the portions of the sacrificial layers under the dummy gate structure with the metal gate structure, a portion of the metal gate structure, portions of the channel layers around which the metal gate structure wraps, a plurality of mesa regions, under the portions of the channel layers, that extend above the semiconductor substrate, and a STI region between the plurality of mesa regions. The method includes forming an active region isolation structure in the active region isolation recess.

As described in greater detail above, some implementations described herein provide a semiconductor device. The semiconductor device includes a first plurality of nanostructure channels over a first mesa region that extends above a semiconductor substrate, where the first plurality of nanostructure channels are arranged in a direction that is perpendicular to the semiconductor substrate. The semiconductor device includes a second plurality of nanostructure channels over a second mesa region that extends above the semiconductor substrate, where the second plurality of nanostructure channels are arranged in the direction that is perpendicular to the semiconductor substrate. The semiconductor device includes a first metal gate structure wrapping around each of the first plurality of nanostructure channels. The semiconductor device includes a second metal gate structure wrapping around each of the second plurality of nanostructure channels. The semiconductor device includes a gate isolation structure between the first metal gate structure and the second metal gate structure. The semiconductor device includes an active region isolation structure between the gate isolation structure and the second metal gate structure, where a dielectric liner of the active region isolation structure is included directly on a sidewall of the gate isolation structure, and where a bottom of the active region isolation structure includes: a mesa region section that extends into the semiconductor substrate one or more STI sections that are below the mesa region section.

As used herein, “satisfying a threshold” may, depending on the context, refer to a value being greater than the threshold, greater than or equal to the threshold, less than the threshold, less than or equal to the threshold, equal to the threshold, not equal to the threshold, or the like.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming, over a semiconductor substrate of a semiconductor device, a plurality of nanostructure layers in a direction that is perpendicular to the semiconductor substrate,
wherein the plurality of nanostructure layers comprises a plurality of sacrificial layers alternating with a plurality of channel layers;
etching the plurality of nanostructure layers and the semiconductor substrate to form a plurality of mesa regions and a plurality of layer stacks on the plurality of mesa regions,
wherein the plurality of layer stacks comprise respective portions of the plurality of sacrificial layers and respective portions of the plurality of channel layers;
forming, between adjacent layer stacks of the plurality of layer stacks:
shallow trench isolation (STI) regions, and
hybrid fin structures over the STI regions;
forming, over the plurality of layer stacks and over the hybrid fin structures, a dummy gate structure;
removing portions of the plurality of nanostructure layers to form one or more recesses adjacent to one or more sides of the dummy gate structure; and
forming one or more source/drain regions in the one or more recesses,
wherein a top surface of a hybrid fin structure of the hybrid fin structures is located at a greater height in the semiconductor device than a top surface of a source/drain region of the one or more source/drain regions.

2. The method of claim 1, further comprising:
removing, to form an active region isolation recess:
a portion of the dummy gate structure,
a portion of a layer stack, of the plurality of layer stacks, under the portion of the dummy gate structure, and
a portion of a mesa region, of the plurality of mesa regions, under the portion of the layer stack; and
forming an active region isolation structure in the active region isolation recess.

3. The method of claim 2, wherein removing the portion of the dummy gate structure, the portion of the layer stack, and the portion of the mesa region comprises:
performing a first etch operation to remove the portion of the dummy gate structure; and
performing, after the first etch operation, a second etch operation to remove the portion of the layer stack and the portion of the mesa region.

4. The method of claim 3, further comprising:
performing, prior to the first etch operation, a third etch operation to remove a portion of a hard mask layer over the portion of the dummy gate structure.

5. The method of claim 3, wherein high dielectric constant (high-k) layers, of a subset of the hybrid fin structures, are exposed in the active region isolation recess after the first etch operation.

6. The method of claim 5, wherein low dielectric constant (low-k) layers, of the subset of the hybrid fin structures, are exposed in the active region isolation recess after the second etch operation.

7. The method of claim 2, wherein the active region isolation recess extends below bottom surfaces of the hybrid fin structures.

8. A method, comprising:
forming, over a semiconductor substrate, a plurality of nanostructure layers in a direction that is perpendicular to the semiconductor substrate,
wherein the plurality of nanostructure layers comprises a plurality of sacrificial layers alternating with a plurality of channel layers;
forming, over the plurality of nanostructure layers, a dummy gate structure;
removing portions of the plurality of nanostructure layers to form one or more recesses adjacent to one or more sides of the dummy gate structure;
forming one or more source/drain regions in the one or more recesses;
replacing, after forming the one or more source/drain regions, the dummy gate structure and portions of the sacrificial layers under the dummy gate structure with a metal gate structure,
wherein the metal gate structure wraps around at least four sides of the channel layers;
removing, to form an active region isolation recess after replacing the dummy gate structure and the portions of the sacrificial layers under the dummy gate structure with the metal gate structure:
a portion of the metal gate structure,
portions of the channel layers around which the metal gate structure wraps,
a plurality of mesa regions, under the portions of the channel layers, that extend above the semiconductor substrate, and
a shallow trench isolation (STI) region between the plurality of mesa regions; and
forming an active region isolation structure in the active region isolation recess.

9. The method of claim 8, further comprising:
removing, prior to removing the portion of the metal gate structure to form the active region isolation recess, another portion of the metal gate structure to form a gate isolation recess in the metal gate structure; and
forming, prior to removing the portion of the metal gate structure to form the active region isolation recess, a gate isolation structure in the gate isolation recess.

10. The method of claim 9, wherein removing the portion of the metal gate structure, the portions of the channel layers around which the metal gate structure wraps, the plurality of mesa regions, and the STI region comprises:
removing, based on the gate isolation structure, the portion of the metal gate structure, the portions of the channel layers around which the metal gate structure wraps, the plurality of mesa regions, and the STI region.

11. The method of claim 8, further comprising:
removing, prior to removing the portion of the metal gate structure to form the active region isolation recess, a plurality of other portions of the metal gate structure to form a plurality of gate isolation recesses in the metal gate structure; and
forming, prior to removing the portion of the metal gate structure to form the active region isolation recess, a plurality of gate isolation structures in the plurality of gate isolation recesses.

12. The method of claim 11, wherein removing the portion of the metal gate structure, the portions of the channel layers around which the metal gate structure wraps, the plurality of mesa regions, and the STI region comprises:
removing, from between the plurality of gate isolation structures, the portion of the metal gate structure, the portions of the channel layers around which the metal gate structure wraps, the plurality of mesa regions, and the STI region.

13. The method of claim 12, wherein forming the active region isolation structure comprises:
forming a dielectric liner on sidewalls of the plurality of gate isolation structures in the active region isolation recess; and
filling the active region isolation recess with a dielectric layer over the dielectric liner.

14. The method of claim 13, wherein forming the plurality of gate isolation structures comprises:
forming the plurality of gate isolation structures such that the plurality of gate isolation structures extend in a first direction across the metal gate; and
wherein forming the active region isolation structure comprises:
forming the active region isolation structure such that the active region isolation structure extends in a second direction in which the metal gate structure extends.

15. A semiconductor device, comprising:
a first plurality of nanostructure channels over a first mesa region that extends above a semiconductor substrate,
wherein the first plurality of nanostructure channels are arranged in a direction that is perpendicular to the semiconductor substrate;
a second plurality of nanostructure channels over a second mesa region that extends above the semiconductor substrate,
wherein the second plurality of nanostructure channels are arranged in the direction that is perpendicular to the semiconductor substrate;
a first metal gate structure wrapping around each of the first plurality of nanostructure channels;
a second metal gate structure wrapping around each of the second plurality of nanostructure channels;
a gate isolation structure between the first metal gate structure and the second metal gate structure; and
an active region isolation structure between the gate isolation structure and the second metal gate structure,
wherein a dielectric liner of the active region isolation structure is included directly on a sidewall of the gate isolation structure, and
wherein a bottom of the active region isolation structure includes:
a mesa region section that extends into the semiconductor substrate; and
one or more shallow trench isolation (STI) sections that are below the mesa region section.

16. The semiconductor device of claim 15, further comprising:
a source/drain region adjacent to the first plurality of nanostructure channels; and
a hybrid fin structure between the first plurality of nanostructure channels and the second plurality of nanostructure channels,
wherein a top surface of the hybrid fin structure is located at a greater height in the semiconductor device than a top surface of the source/drain region.

17. The semiconductor device of claim 15, wherein the first metal gate structure is in direct contact with another sidewall of the gate isolation structure.

18. The semiconductor device of claim 15, further comprising:
another gate isolation structure between the active region isolation structure and the second metal gate structure.

19. The semiconductor device of claim 18, wherein the second metal gate structure is in direct contact with a sidewall of the other gate isolation structure.

20. The semiconductor device of claim 19, wherein the dielectric liner of the active region isolation structure is in direct contact with another sidewall of the other gate isolation structure.
